(19) United States
(12) Patent Application Publication
(10) Pub. No.: US 2024/0284666 A1
(43) Pub. Date: Aug. 22, 2024

(54) 3D MEMORY CELLS AND ARRAY ARCHITECTURES

(71) Applicant: NEO Semiconductor, Inc., San Jose, CA (US)

(72) Inventor: Fu-Chang Hsu, San Jose, CA (US)

(21) Appl. No.: 18/649,897

(22) Filed: Apr. 29, 2024

Related U.S. Application Data
(63) Continuation-in-part of application No. 17/937,432, filed on Sep. 30, 2022.
(60) Provisional application No. 63/462,796, filed on Apr. 28, 2023.
(60) Provisional application No. 63/569,734, filed on Mar. 26, 2024.
(60) Provisional application No. 63/398,807, filed on Aug. 17, 2022.
(60) Provisional application No. 63/295,874, filed on Jan. 1, 2022.
(60) Provisional application No. 63/291,380, filed on Dec. 18, 2021.
(60) Provisional application No. 63/254,841, filed on Oct. 12, 2021.
(60) Provisional application No. 63/251,583, filed on Oct. 1, 2021.

(51) Int. Cl. H10B 41/27; G11C 16/04; H10B 41/10; H10B 43/10; H10B 43/27

(52) U.S. Cl. CPC H10B 41/27; G11C 16/0483; H10B 41/10; H10B 43/10; H10B 43/27

(57) ABSTRACT

Various 3D memory cells, array architectures, and processes are disclosed. In an embodiment, a cell structure is provided that includes a first material forming a bit line, a second material forming a storage region that is coupled to a first portion of the bit line, and a third material forming a channel that is connected to the storage region and to second and third portions of the bit line. The cell structure also includes a fourth material forming a source line that is connected to the channel, a fifth material forming a front gate coupled to a first portion of the channel and a first portion of the source line, and a sixth material forming a back gate coupled to a second portion of the channel and a second portion of the source line.

### CROSS-REFERENCE TO RELATED APPLICATIONS

This application is a continuation-in-part (CIP) of U.S. patent application having application Ser. No. 17/937,432 filed on Sep. 30, 2022, and entitled “3D Memory Cells and Array Architectures.”

This application claims the benefit of priority under 35 U.S.C. 119(e) based upon U.S. Provisional Patent Application having Application No. 63/462,796 filed on Apr. 28, 2023, and entitled “3D Cell and Array Structures and Processes,” and U.S. Provisional Patent Application having Application No. 63/569,734 filed on Mar. 26, 2024, and entitled “3D Cell and Array Structures and Processes,” all of which are hereby incorporated herein by reference in their entireties.

The application Ser. No. 17/937,432 claims the benefit of priority under 35 U.S.C. 119(e) based upon U.S. Provisional Patent Application having Application No. 63/398,807 filed on Aug. 17, 2022, and entitled “Memory Cell and Array Architectures and Operation Conditions,” and U.S. Provisional Patent Application having Application No. 63/295,874 filed on Jan. 1, 2022, and entitled “Alpha-RAM (a-RAM) or Alpha-DRAM (a-DRAM) Technology,” and U.S. Provisional Patent Application having Application No. 63/291,380 filed on Dec. 18, 2021 and entitled “3D DRAM-replacement Technologies,” and U.S. Provisional Patent Application having Application No. 63/254,841, filed on Oct. 12, 2021 and entitled “3D DRAM-replacement Technologies,” and U.S. Provisional Patent Application having Application No. 63/251,583 filed on Oct. 1, 2021 and entitled “3D DRAM-replacement Technologies,” all of which are hereby incorporated herein by reference in their entireties.

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use three-dimensional (3D) array structure. The 3D array structure has been successfully used in NAND flash memory today. However, for dynamic random-access memory (DRAM), due to its special one-transistor-one-capacitor (1T1C) cell structure, a cost-effective 3D array structure has not been realized.

### SUMMARY

In various exemplary embodiments, three-dimensional (3D) memory cells, array structures, and associated processes are disclosed. In one embodiment, a novel 3D array structure using floating-body cells to implement DRAM is disclosed. The array structure is formed using a deep trench process similar to 3D NAND flash memory. Therefore, ultra-high-density DRAM can be realized. In one embodiment, 3D NOR-type memory cells and array structures are provided. The disclosed memory cells and array structures are applicable to many technologies. For example, the inventive memory cells and array structures are applicable to dynamic random-access memory (DRAM), floating-body cell (FBC) memory, NOR-type flash memory, and thyristors.

In an exemplary embodiment, a memory cell structure is provided that includes a first semiconductor material, a floating body semiconductor material having an internal side surface that surrounds and connects to the first semiconductor material, and a second semiconductor material having an internal side surface that surrounds and connects to the floating body semiconductor material. The memory cell structure also includes a first dielectric layer connected to a top surface of the floating body material, a second dielectric layer connected to a bottom surface of the floating body material, a front gate connected to the first dielectric layer, and a back gate connected to the second dielectric layer.

In an exemplary embodiment, a three-dimensional (3D) memory array is provided that comprises a plurality of memory cells separated by a dielectric layer to form a stack of memory cells. Each memory cell in the stack of memory cells comprises a bit line formed from one of a first semiconductor material and a first conductor material, a floating body semiconductor material having an internal side surface that surrounds and connects to the bit line, a source line formed from one of a second semiconductor material and a second conductor material having an internal side surface that surrounds and connects to the floating body semiconductor material, and a word line formed from a third conductor material that is coupled to the floating body semiconductor through the dielectric layer to form a gate of the memory cell. Additionally, the bit lines of the stack of memory cells are connected to form a vertical bit line.

In an embodiment, a cell structure is provided that includes a first material forming a bit line, a second material forming a storage region that is coupled to a first portion of the bit line, and a third material forming a channel that is connected to the storage region and to second and third portions of the bit line. The cell structure also includes a fourth material forming a source line that is connected to the channel, a fifth material forming a front gate coupled to a first portion of the channel and a first portion of the source line, and a sixth material forming a back gate coupled to a second portion of the channel and a second portion of the source line.

In an embodiment, a cell structure is provided that comprises a first material forming a bit line, an insulator connected to a first portion of the bit line, a second material forming a channel that is connected to the insulator and to second and third portions of the bit line, and a third material forming a first storage region that is coupled to a first portion of the channel. The cell structure also comprises a fourth material forming a second storage region that is coupled to a second portion of the channel, a fifth material forming a source line that is connected to the channel, a sixth material forming a front gate coupled to the channel and a first portion of the source line, and a seventh material forming a back gate coupled to the channel and a second portion of the source line.

In an embodiment, a cell structure is provided that comprises a first material forming a bit line, a second material forming a channel that is connected to a first portion of the bit line, a third material forming a first storage region that is coupled to a first portion of the channel and a second portion of the bit line, a fourth material forming a second storage region that is coupled to a second portion of the channel and a third portion of the bit line. The cell structure also comprises a fifth material forming a source line that is connected to the channel, a sixth material forming a front gate coupled to the channel and a first portion of the source line, and a seventh material forming a back gate coupled to the channel and a second portion of the source line.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A show an exemplary embodiment of a three-dimensional (3D) NOR-type memory cell structure using a floating body cell (FBC) configuration in accordance with the invention.

FIG. 1B shows the cell structure shown in FIG. 1A with a front gate and a gate dielectric layer removed.

FIG. 1C shows a cell formed using a PMOS transistor.

FIG. 1D shows an embodiment of an array structure based on the cell structure shown in FIG. 1A.

FIG. 1E shows another embodiment of an array structure according to the invention.

FIG. 1F shows an equivalent circuit diagram for the array structure shown in FIG. 1D.

FIG. 1G shows another embodiment of an equivalent circuit diagram of the array structure shown in FIG. 1D.

FIGS. 1H-I show embodiments of a junction-less transistor cell structure according to the invention.

FIGS. 1J-K show embodiments of a tunnel field-effect transistor (T-FET) cell structure according to the invention.

FIG. 1L shows another embodiment of the cell structure according to the invention that uses a metal bit line and source line.

FIG. 1M shows embodiments of a thin-film structure and an indium-gallium-zinc-oxide (IGZO) transistor cell structure according to the invention.

FIG. 2A shows an embodiment of a write data ‘1’ condition of the cell according to the invention.

FIG. 2B shows another embodiment of a write data ‘1’ condition of the cell according to the invention.

FIG. 2C shows an embodiment of a write data ‘0’ condition of the cell according to the invention.

FIG. 2D shows an exemplary waveform of the write data ‘0’ condition according to the invention.

FIG. 3A shows a threshold voltage (Vt) of the cell data ‘0’ and data ‘1’.

FIG. 3B shows how a threshold voltage of the cell transistors to become negative.

FIG. 3C shows a special read condition to address issues illustrated in FIG. 3B.

FIG. 3D shows a table that summarizes the bias conditions of write data ‘1’, write data ‘0’, and read operations.

FIGS. 4A-F show simplified process steps for constructing the array structure shown in FIG. 3.

FIGS. 4G-H show additional embodiments of array structures according to the invention.

FIGS. 4I-J show another embodiment of process steps to form the body of the transistors.

FIG. 4K shows an embodiment of the bit line connection of the array structure shown in FIG. 4F.

FIG. 4L shows another embodiment of the array structure according to the invention to solve the previously mentioned issue with using many word line decoders.

FIG. 4M shows the bit line connections of the array embodiment shown in FIG. 4L.

FIG. 4N shows another embodiment of an array architecture according to the invention.

FIG. 4O shows an embodiment of a non-volatile program operation to write data stored in floating bodies and to a charge-trapping layer.

FIG. 4P shows another embodiment of a 3D floating body cell array structure according to the invention.

FIG. 4Q shows a write ‘0’ condition of the array structure embodiment shown in FIG. 4P.

FIG. 4R shows an embodiment of write ‘0’ waveforms.

FIG. 4S shows bias conditions of write data ‘1’, write data ‘0’, and read operations for the array embodiment shown in FIG. 4P.

FIGS. 4T-Z show an embodiment of process steps to form the cell array structure shown in FIG. 4P.

FIG. 5A shows another embodiment of a cell structure according to the invention.

FIG. 5B shows the cell structure of FIG. 5A with a front gate and a gate dielectric layer removed.

FIGS. 5C-D show another embodiment of a cell structure according to the invention.

FIG. 6A shows another embodiment of a cell structure according to the invention.

FIG. 6B shows the cell structure shown in FIG. 6A with a front gate and gate dielectric layer removed.

FIGS. 6C-D show another embodiment of a cell structure according to the invention.

FIG. 7 shows an embodiment of an array structure based on the cell structure shown in FIG. 6A.

FIGS. 8A-F show simplified process steps for forming the array structure shown in FIG. 7.

FIG. 9A shows another embodiment of a cell structure according to the invention.

FIG. 9B shows an embodiment of an array structure based on the cell structure shown in FIG. 9A.

FIGS. 10A-D show simplified process steps for constructing the cell structure shown in FIG. 9A.

FIG. 11A shows another embodiment of a cell structure according to the invention.

FIG. 11B shows an embodiment of an array structure based on the cell structure shown in FIG. 11A.

FIGS. 12A-D shows simplified process steps for constructing the cell structure shown in FIG. 11A.

FIG. 13A shows another embodiment of a DRAM-replacement technology according to the invention.

FIG. 13B shows the cell structure of FIG. 13A with a front gate and a gate dielectric layer removed.

FIG. 13C shows another embodiment of a 3D thyristor cell structure according to the invention.

FIG. 14A shows a circuit diagram in which two bipolar transistors form a gate-assisted thyristor cell.

FIG. 14B shows a circuit diagram that forms a non-gate-assisted thyristor cell.

FIG. 14C shows a current to voltage (I-V) curve of the thyristor cell shown in FIG. 13A.

FIG. 15A shows an embodiment of a 3D array structure based on the cell structure shown in FIG. 13A.

FIG. 15B shows an embodiment of a 3D array structure based on the cell structure shown in FIG. 13C.

FIG. 16A shows another embodiment of a thyristor cell structure according to the invention.

FIG. 16B shows the cell structure shown in FIG. 16A with a front gate and a gate dielectric layer removed.

FIG. 16C shows another embodiment of a thyristor cell structure according to the invention.

FIG. 17A shows an embodiment of a 3D array structure based on the cell structure shown in FIG. 16A.

FIG. 17B shows an embodiment of a 3D array structure based on the cell structure shown in FIG. 16C.

FIG. 18A shows another embodiment of a thyristor cell structure according to the invention.

FIG. 18B shows an embodiment of a 3D array structure based on the cell structure shown in FIG. 16C.

FIG. 19A shows another embodiment of a 3D array structure according to the invention that uses ‘tunnel field-effect transistor (TFET)’ technology.

FIG. 19B shows a cross-section of the array structure shown in FIG. 19A that is taken at cross-section indicator A-A′ to reveal the structure of an insulating layer.

FIG. 20A shows a vertical cross section view of the 3D array structure shown in FIG. 19A.

FIG. 20B shows another embodiment of the vertical cross section view of the 3D array structure shown in FIG. 19A.

FIG. 20C shows another embodiment of the vertical cross section view of the 3D array structure according to the invention.

FIG. 21A shows another embodiment of the 3D array structure according to the invention.

FIG. 21B shows another embodiment of the 3D array structure according to the invention.

FIG. 21C shows another embodiment of a 3D array structure according to the invention.

FIG. 21D shows another embodiment of a 3D array structure according to the invention.

FIG. 22A shows another embodiment of a 3D cell structure according to the invention.

FIG. 22B shows an inner structure of the 3D cell structure shown in FIG. 22A.

FIG. 23A shows another embodiment of a 3D cell structure according to the invention.

FIG. 23B shows the inner structure of the 3D cell structure shown in FIG. 23A.

FIG. 24A shows another embodiment of the 3D cell structure according to the invention.

FIG. 24B shows the inner structure of the 3D cell structure shown in FIG. 24A.

FIG. 25A shows another embodiment of 3D cell structure according to the invention.

FIG. 25B shows an inner structure of the 3D cell structure shown in FIG. 25A.

FIGS. 26A-G shows simplified key process steps of another embodiment of a floating body cell “AND” array according to the invention.

FIGS. 27A-D show embodiments of cell structures according to the invention.

FIGS. 28A-P show embodiments of 3D floating body cell structures according to the invention.

FIGS. 29A-K show embodiments of 3D floating body cell structures according to the invention.

FIG. 30A-C show embodiments of cell structures according to the invention.

FIG. 31A-C show embodiments of cell structures according to the invention.

FIG. 32A-C show embodiments of cell structures according to the invention.

FIG. 33A-D show embodiments of cell structures according to the invention.

FIG. 34A-D show embodiments of cell structures according to the invention.

FIG. 35A-F show embodiments of cell structures according to the invention.

FIG. 36A-D show embodiments of cell structures according to the invention.

FIG. 37A-B show embodiments of cell structures according to the invention.

FIG. 38A-B show embodiments of cell structures according to the invention.

FIG. 39A-C show embodiments of cell structures according to the invention.

FIG. 40A-C show embodiments of cell structures according to the invention.

FIG. 41A-J show embodiments of cell structures according to the invention.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, three-dimensional (3D) memory cells, array structures, and associated processes are disclosed. The disclosed memory cells and array structures are applicable to many technologies. For example, the inventive memory cells and array structures are applicable to dynamic random-access memory (DRAM), floating-body cell (FBC) memory, NOR-type flash memory, and thyristors.

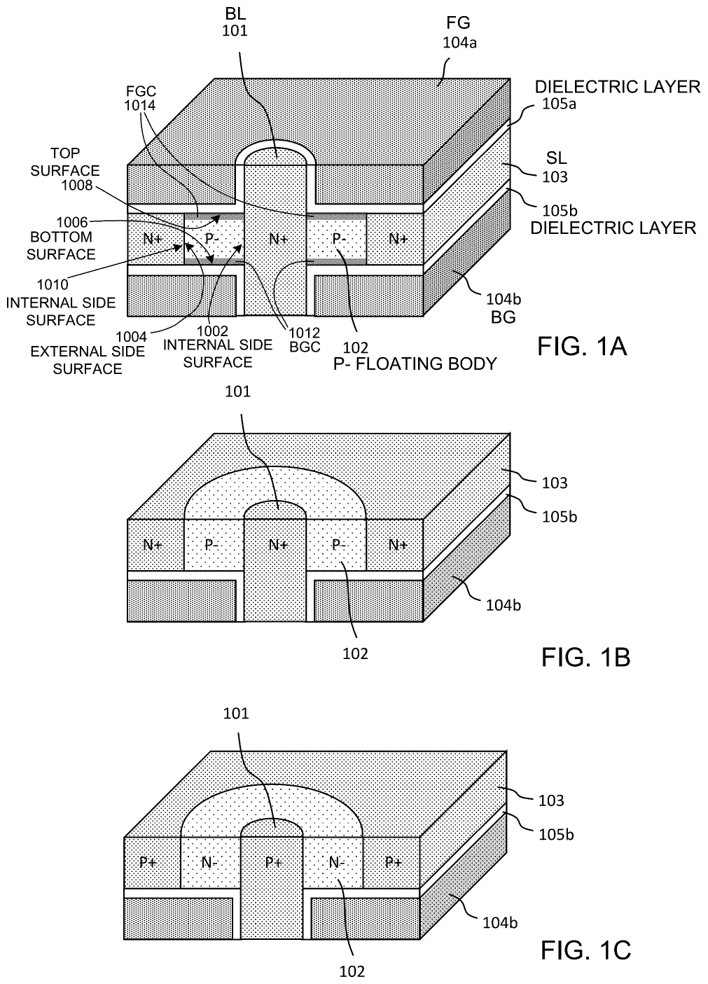

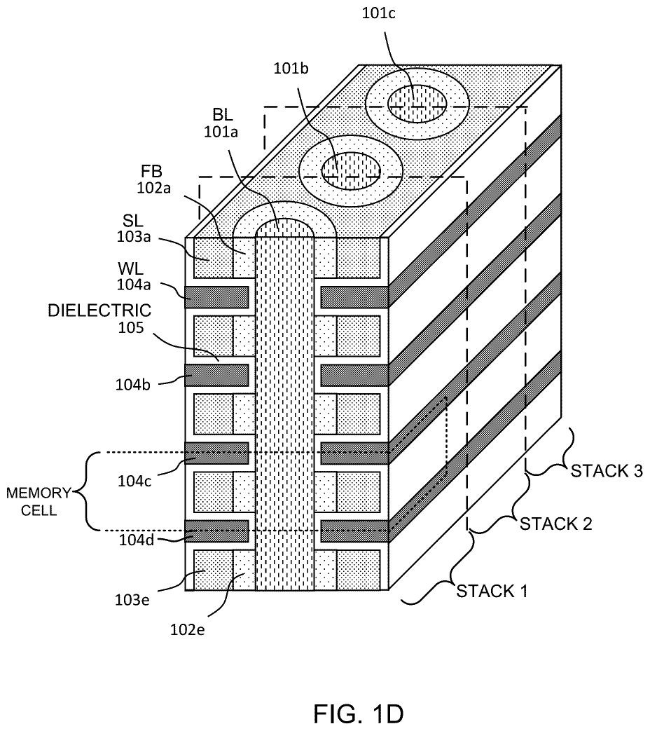

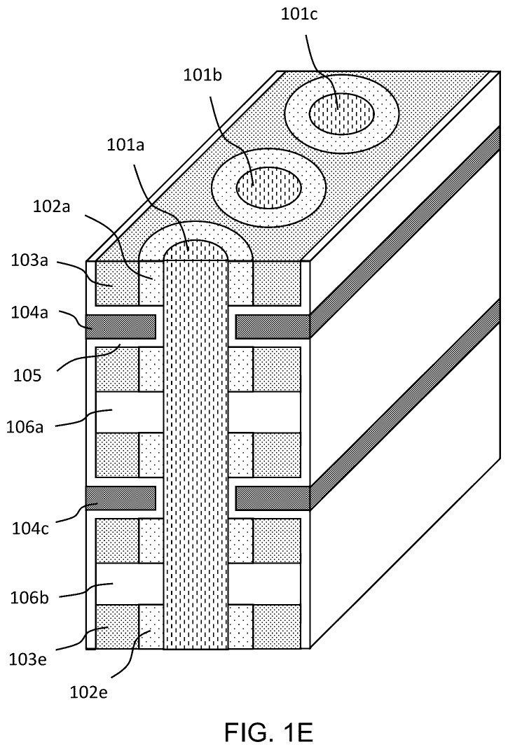

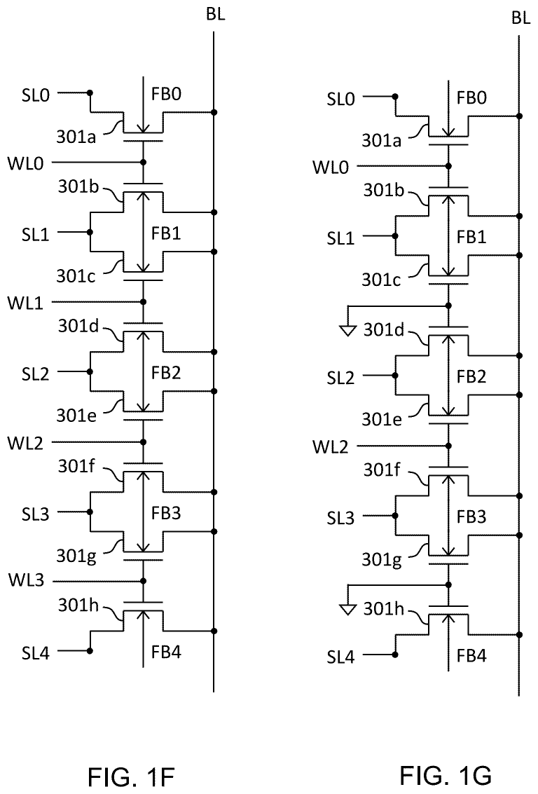

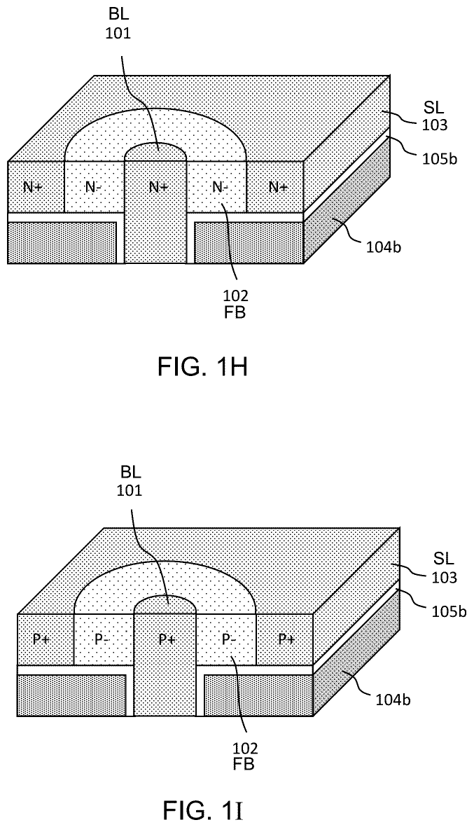

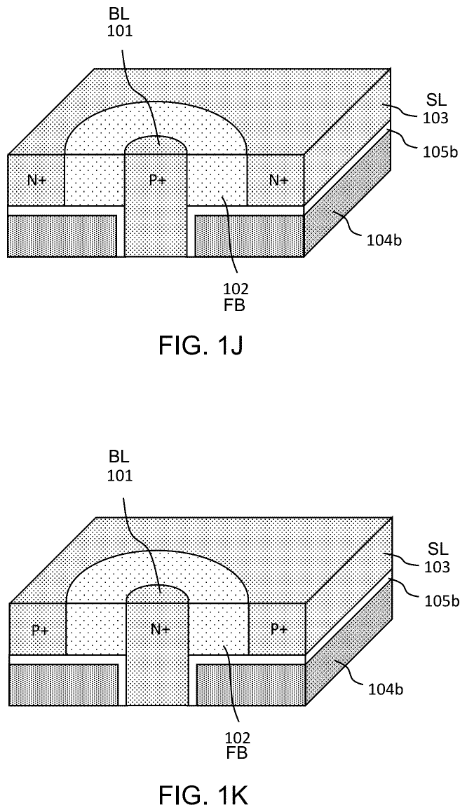

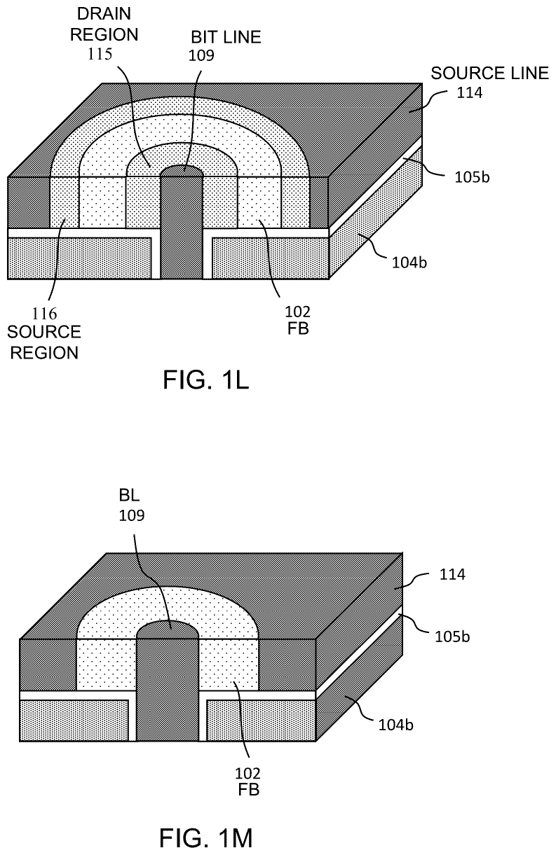

FIG. 1A show an exemplary embodiment of a three-dimensional (3D) NOR-type memory cell structure using a floating body cell (FBC) configuration in accordance with the invention. The 3D NOR-type array may comprise multiple layers of floating-body cell arrays to increase the memory capacity. A floating-body cell is basically a transistor with floating body. The floating body may store electric charges such as electrons or holes to represent the data. The cell structure may comprise a control gate, a drain, a source, and a floating body. In the 3D memory array, the control gate, drain, and source of the cells are connected to word line (WL), bit line (BL), and source line (SL), respectively.

In the cell structure, an N+ silicon or polysilicon forms a bit line (BL) 101 and a P− floating body 102 is used for charge storage. An N+ silicon or polysilicon forms a source line (SL) 103. The cell may be formed as a dual-gate transistor shown in FIG. 1A or a single-gate transistor shown in FIG. 1B. For the dual-gate transistor shown in FIG. 1A, the cell structure comprises two control gates called a front gate 104a and a back gate 104b, respectively. Both the front gate 104a and the back gate 104b are coupled to the floating body 102 through gate dielectric layers 105a and 105b, respectively. The gate dielectric layer is an insulating layer between the gate and the body of the transistor. When a proper voltage is applied to the front gate 104a or the back gate 104b, a front gate channel (FGC) 1014 or a back gate channel (BGC) 1012 are formed in the surface of the floating body 102 under the gate dielectric layer 105a and 105b to conduct current between the bit line 101 and source line 103. In an embodiment, the front gate 104a and back gate 104b are connected to different word lines (WL).

In an embodiment, the P− floating body 102 comprises multiple surfaces as shown in FIG. 1A. An internal side surface 1002 surrounds and connects to the BL 101. An external side surface 1004 connects to the source line 103. A top surface 1008 connects to the dielectric layer 105a, and a bottom surface 1006 connects to the dielectric layer 105b. Thus, in one embodiment, a memory cell structure is provided that includes a first semiconductor material BL 101, a floating body semiconductor material 102 having an internal side surface 1002 that surrounds and connects to the first semiconductor material BL 101, and a second semiconductor material SL 103 having an internal side surface 1010 that surrounds and connects to the floating body semiconductor material 102. The memory cell structure also includes a first dielectric layer 105a connected to a top surface 1008 of the floating body material 102, a second dielectric layer 105b connected to a bottom surface 1006 of the floating body material 102, a front gate 104a connected to the first dielectric layer 105a, and a back gate 104b connected to the second dielectric layer 105b. In various embodiments, minor modifications are made to the disclosed structures, such as adding a lightly doped drain (LDD), halo implantation, pocket implantation, or channel implantation that are all included within the scope of the invention.

FIG. 1B shows the cell structure shown in FIG. 1A with the front gate 104a and the gate dielectric layer 105a removed. The P− floating body 102 forms a donut shape as shown. Please notice, although this embodiment shows that the shapes for the bit line 101 and floating body 102 are circular, it is obvious that they have any desired shape, such as square, rectangle, triangle, hexagon, etc. These variations shall remain in the scope of the invention.

In one embodiment, the cell structure comprises only one single gate, as shown in FIG. 1B. The floating body 102 is coupled to only one gate 104b as shown. An embodiment of a 3D array structure using this cell structure embodiment is shown in FIG. 1D.

The embodiment shown in FIG. 1A uses an NMOS transistor as the cell. In another embodiment, shown in FIG. 1C, the cell is formed using a PMOS transistor. The bit line 101, floating body 102, and source line 103 are formed by P+, N−, and P+ materials, respectively.

FIG. 1D shows an embodiment of an array structure based on the cell structure shown in FIG. 1A. The array structure comprises vertical bit lines 101a to 101c and floating bodies 102a to 102e. The array structure also comprises source lines 103a to 103e and word lines 104a to 104d. The array structure also includes dielectric layer 105 comprising a gate oxide or high-K material, such as HfOx.

In an embodiment, a three-dimensional (3D) memory array comprises a plurality of memory cells separated by a dielectric layer to form a stack of memory cells. For example, FIG. 1D shows a 3D array having three stacks of memory cells and a particular “memory cell” is identified. Each memory cell in the stack of memory cells comprises a bit line 101 formed from one of a first semiconductor material and a first conductor material, a floating body semiconductor material 102 having an internal side surface that surrounds and connects to the bit line, a source line 103 formed from one of a second semiconductor material and a second conductor material having an internal side surface that surrounds and connects to the floating body semiconductor material 102, and a word line 104 formed from a third conductor material that is coupled to the floating body semiconductor 102 through a dielectric layer 105 to form a gate of the memory cell. Additionally, the bit lines of the stack of memory cells are connected to form a vertical bit line (e.g., 101a).

FIG. 1E shows another embodiment of an array structure according to the invention. This embodiment is similar to the embodiment shown in FIG. 1D except that the cells are single-gate transistors. Also shown in FIG. 1E are insulating layers 106a and 106b that are formed from material, such as oxide.

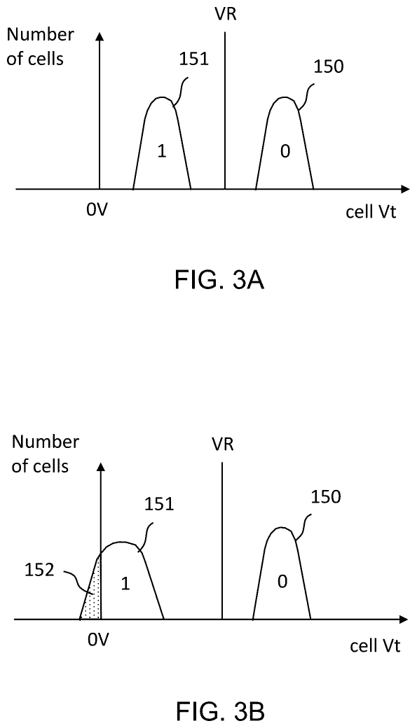

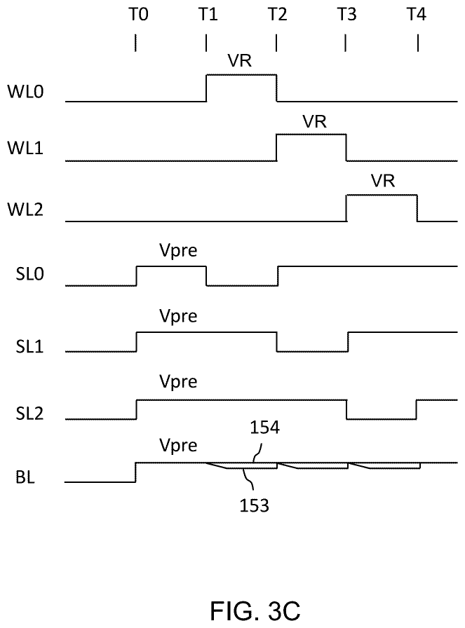

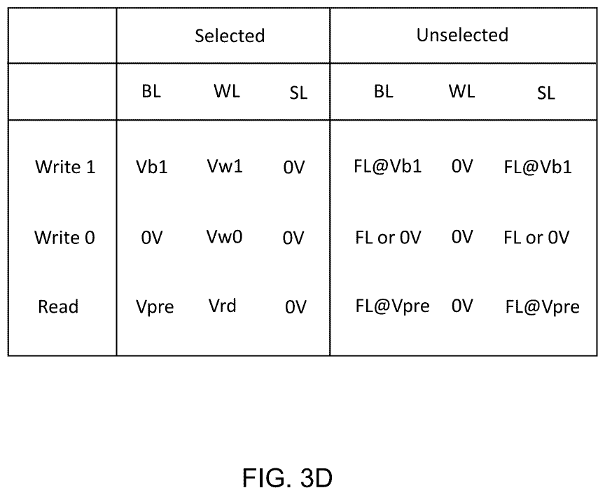

FIG. 1F shows an equivalent circuit diagram for the array structure shown in FIG. 1D. Referring again to the array structure in FIG. 1D, the word line structures 104a to 104d are connected to word lines WL0-WL3. The floating bodies structures 102a to 102e are the floating bodies FB0-FB4. The source line structures 103a to 103e are connected to the source lines SL0-SL4, and the bit line structure 101a is a vertical bit line (BL). In this embodiment, each floating body (e.g., FB0-FB4) is coupled to two word lines. This array requires special bias conditions for read and write operations to avoid two cells being selected at the same time. The detailed bias conditions of this embodiment are described with reference to FIG. 3D.

FIG. 1G shows another embodiment of an equivalent circuit diagram of the array structure shown in FIG. 1D. This embodiment is similar to the embodiment shown in FIG. 1F except that the odd word lines, WL1, WL3, and so on, are connected to ground. This turns off the transistors 301c, 301d, 301g, and 301h. In this embodiment, each floating body is coupled to one word line only. However, the storage capacity of this embodiment is reduced to one half when compared with the embodiment shown in FIG. 1F.

FIGS. 1H-I show embodiments of a junction-less transistor cell structure according to the invention.

FIG. 1H shows an N-channel junction-less transistor cell. The bit line 101 and source line 103 comprise N+ semiconductors, such as silicon, and the floating body 102 comprises an N− semiconductor, such as silicon.

FIG. 1I shows a P-channel junction-less transistor cell. The bit line 101 and source line 103 comprise P+ semiconductors, such as silicon, and the floating body 102 comprises a P− semiconductor, such as silicon.

FIGS. 1J-K show embodiments of a tunnel field-effect transistor (T-FET) cell structure according to the invention. For these embodiments, the bit line 101 and the source line 103 comprise semiconductors, such as silicon, that have the opposite type of doping.

FIG. 1J illustrates how the bit line 101 and source line 103 have P+ type of doping and N+ type of doping, respectively.

FIG. 1K illustrates how the bit line 101 and source line 103 have N+ type of doping and P+ type of doping, respectively. The floating body 102 is an intrinsic semiconductor, such as silicon. In another embodiment, the floating body 102 is lightly doped with P-type or N-type impurity. The tunnel FET behaves like a gated diode. It has an advantage of very low off-state leakage current.

FIG. 1L shows another embodiment of the cell structure according to the invention that uses a metal bit line 109 and a metal source line 114. In this embodiment, the drain region 115 and source region 116 of the cell are connected to conductor layers, such as a metal bit line 109 and a metal source line 114, respectively. This reduces the resistance of the bit line and source line. The source region 116 is formed as a donut shape surrounding the floating body 102 as shown.

FIG. 1M shows embodiments of a thin-film structure and an indium-gallium-zinc-oxide (IGZO) transistor cell structure according to the invention. For the thin-film structure, the bit line 109 and the source line 114 comprise conductors, such as metal or polysilicon. The floating body 102 comprises a thin semiconductor layer, such as silicon. The floating body 102 is either an intrinsic semiconductor or doped with P-type or N-type impurity. This structure forms a junction-less thin-film transistor. In another embodiment, the floating body 102 comprises a semiconductor layer with an oxygen tunnel, such as indium-gallium-zinc-oxide (IGZO). Compared with the traditional silicon-based transistor, this embodiment has the advantages of very low off-state leakage current and higher on-cell current.

For all the embodiments for the cell structures shown above in FIGS. 1H-M, the cell may use the double-gate structure shown in FIG. 1A or single-gate structure shown in FIG. 1B. In addition, the cell structure may use a combination of multiple embodiments disclosed herein.

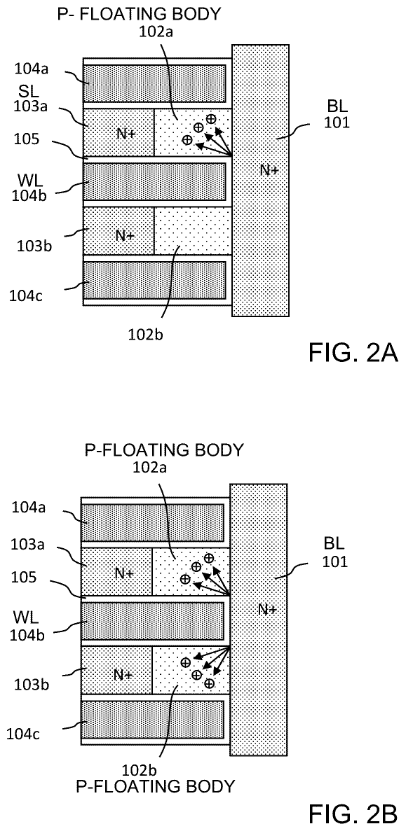

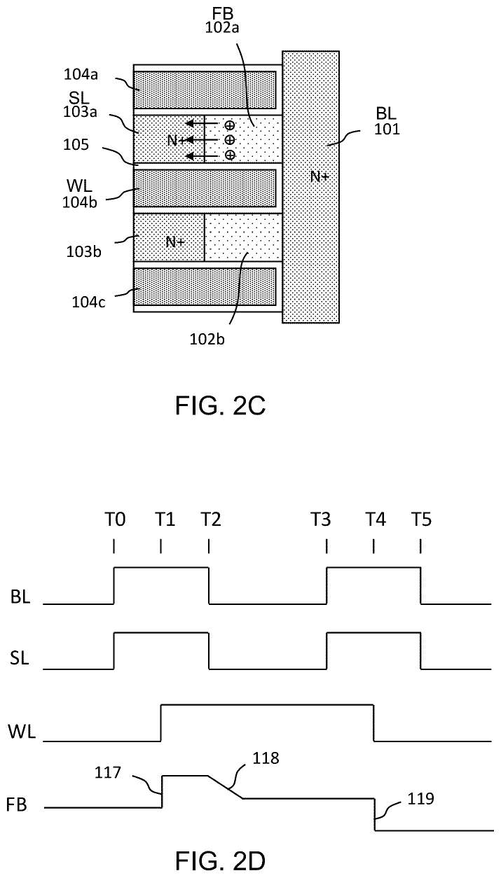

FIG. 2A shows an embodiment of a write data ‘1’ condition of the cell according to the invention. The selected bit line 101 is supplied with a voltage that is high enough to cause impact-ionization to occur. The level of this voltage is dependent on the process technology. In one embodiment, the voltage level is in the range of 1.5V to 2.5V. The selected word line 104b is supplied with a voltage level that is lower than the bit line voltage, such as 0.5V to 1V. The selected source line (SL) 103a is supplied with 0V. This condition turns on the cell transistor in saturation mode and causes impact ionization to occur in the bit line junction to generate electron-hole pairs and inject holes into the P− floating body 102a as shown. The holes trapped in the floating body 102a will reduce the threshold voltage (Vt) of the cell transistor to represent the data ‘1’ state.

In one embodiment, the unselected source line 103b is supplied with an inhibit voltage, such as 0.5V to 1V. This condition turns off the channel under the gate 104b in the floating body 102b, thus the hole injection may not occur in the floating body 102b.

FIG. 2B shows another embodiment of a write data ‘1’ condition of the cell according to the invention. This embodiment uses a band-to-band tunneling mechanism to write the cell. The selected bit line 101 is supplied with a voltage high enough to cause band-to-band tunneling to occur. The level of this voltage is dependent on the process technology. In one embodiment, the voltage level may be 1.5V to 2.5V. The selected word line 104b is supplied with 0V to turn off the cell transistor and cause band-to-band tunneling to occur in the bit line junction to generate electron-hole pairs and inject holes into the P− floating bodies 102a and 102b as shown. The holes trapped in the floating bodies 102a and 102b will reduce the threshold voltage (Vt) of the cell transistor to represent the data ‘1’ state. It should be noted that in this embodiment, the same data ‘1’ will be written into two floating bodies, such as 102a and 102b that are coupled to the same word line 104b.

FIG. 2C shows an embodiment of a write data ‘0’ condition of the cell according to the invention. FIG. 2D shows an exemplary waveform of the write data ‘0’ condition according to the invention.

At time T0, the selected bit line 101 and selected source line 103a are supplied with a positive voltage. The selected word line 104b is supplied with 0V. This will turn off the channel of the cell transistors.

At time T1, the selected word line 104b is supplied with a positive voltage. Because the channel is turned off, the word line voltage will couple up the voltage of the floating body 102a, as shown at indicator 117. The word line voltage is selected so that the coupled floating body voltage is higher than the threshold voltage of the P-N junction diode, such as 0.5V to 0.7V, to cause forward bias from the floating body 102a to the bit line 101 and source line 103a.

At time T2, the selected bit line 101 and source line 103a are supplied with a low voltage, such as 0V. This will cause forward bias current to flow from the floating body 102a to the bit line 101 and source line 103a to evacuate the holes stored in the floating body 102a, as shown at indicator 118. This will increase the threshold voltage (Vt) of the cell transistor to represent the data ‘0’ state.

At time T3, the selected bit line 101 and source line 103a are supplied with a positive voltage again to turn off the channel of the cell transistor.

At time T4, the selected word line 104b supplied with 0V. This will couple low the floating body 102a as shown at indicator 119.

At time T5, the bit line 101 and source line 103a are supplied with 0V and the write ‘0’ operation is completed.

FIG. 3A shows a threshold voltage (Vt) of the cell data ‘0’ 150 and data ‘1’ 151. During a read operation, the selected word line is supplied with a read voltage (VR) between the Vt of data ‘0’ and ‘1’. This will turn on the data ‘1’ cell and turn off the data ‘0’ cell. A sensing circuit is coupled to the bit line to sense the current to determine the read data.

It should be noted that under the write ‘1’ condition, if more than a desired number of holes are injected into the floating body, it may cause the threshold voltage of the cell transistors to become negative, as shown at indicator 152 in FIG. 3B. These cells may leak current even when they are not selected, and their word lines are supplied with the unselected voltage 0V. If many unselected cells have negative Vt, the sum of the leakage current may cause read errors.

FIG. 3C shows a special read condition to address the issues illustrated in FIG. 3B. It will be assumed that three word lines, WL0-WL2 are selected to read.

At time T0, all the bit lines and source lines SL0-SL2 are pre-charged to a voltage Vpre. The voltage Vpre is lower than the bit line voltage during the write mode to avoid accidentally writing. In one embodiment, Vpre is in the range of 0.5V to 1V. All the word lines WL0-WL2 are supplied with 0V.

At time T1, the selected word line WL0 is supplied with the read voltage VR, which is between the Vt of the data ‘1’ and ‘0’. The selected source line SL0 is supplied with 0V. If the selected cell stores data ‘1’, the cell will be turned on and conduct current from the selected bit line to the selected source line to pull low the bit line voltage, as shown at indicator 153. If the selected cell stores data ‘0’, the cell will be turned off, thus the selected bit line will maintain the pre-charged voltage level, as shown at indicator 154. A sense circuit coupled to the selected bit line will sense the current or voltage of the selected bit line to determine the data. Since the unselected bit lines and unselected source lines are pre-charged to the same voltage as the selected bit line, there is no leakage current even if the unselected cells have a negative Vt.

At time T2, the word line WL0 is supplied with 0V. The source line SL0 is pre-charged to Vpre again. The next selected word line WL1 is supplied with the read voltage VR, and the next selected source line SL1 is supplied with 0V. This will read the next cell selected by WL1 and SL1.

Similarly, at time T3, the word line WL1 is supplied with 0V. The source line SL1 is pre-charged to Vpre again. The next selected word line WL2 and source line SL2 are supplied with VR and 0V, respectively, to read the next selected cell.

FIG. 3D shows a table that summarizes the bias conditions of write data ‘1’, write data ‘0’, and read operations. Vb1 is the bit line voltage during write operation. Vw1 and Vw0 are the word line voltages during write ‘1’ and write ‘0’ operations, respectively. Vpre is the pre-charge voltage during read operation. The term “FL” means the indicated line is floating or floating at an indicated value.

The operation conditions shown in FIG. 3D are for an NMOS embodiment. For a PMOS embodiment, the voltages and polarity are adjusted according to the PMOS transistor's characteristics. For example, during the read and write operations, the selected word line is supplied with a low voltage, such as 0V, to turn on the channel. Moreover, during write ‘0’ operation, the bit line 101 is supplied with a positive voltage to cause P-N junction forward bias current to flow from the bit line 101 to the floating body to evacuate the electrons stored in the floating body. These variations and modifications shall be remained within the scope of the invention.

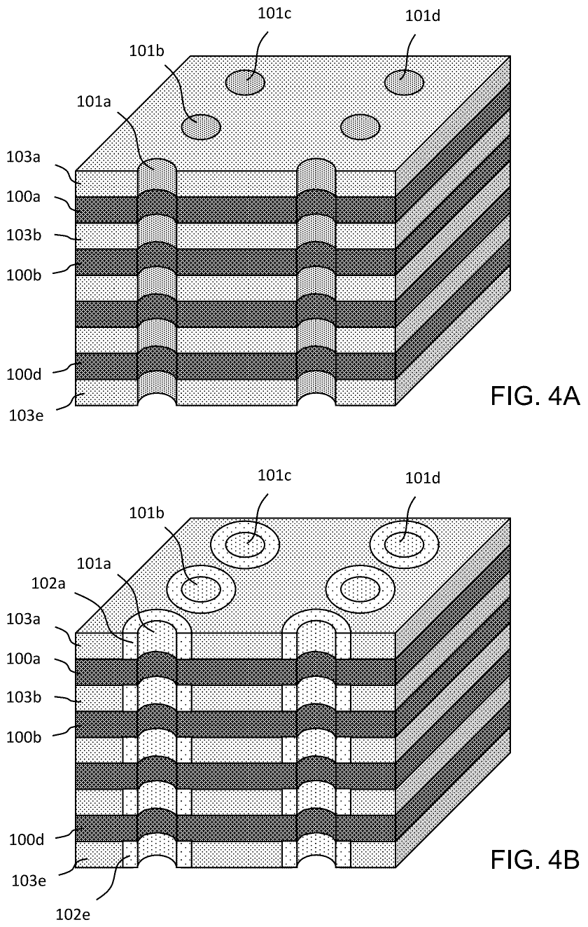

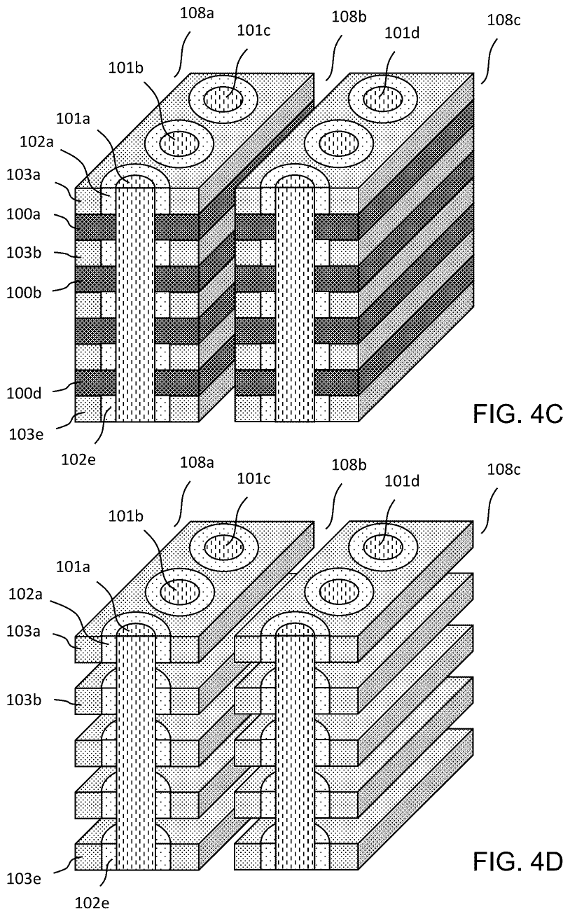

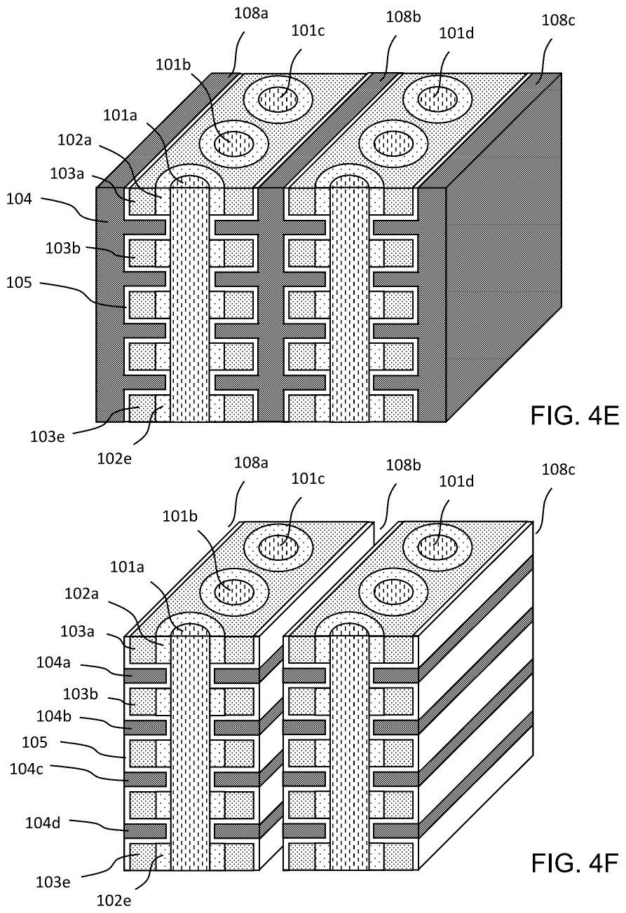

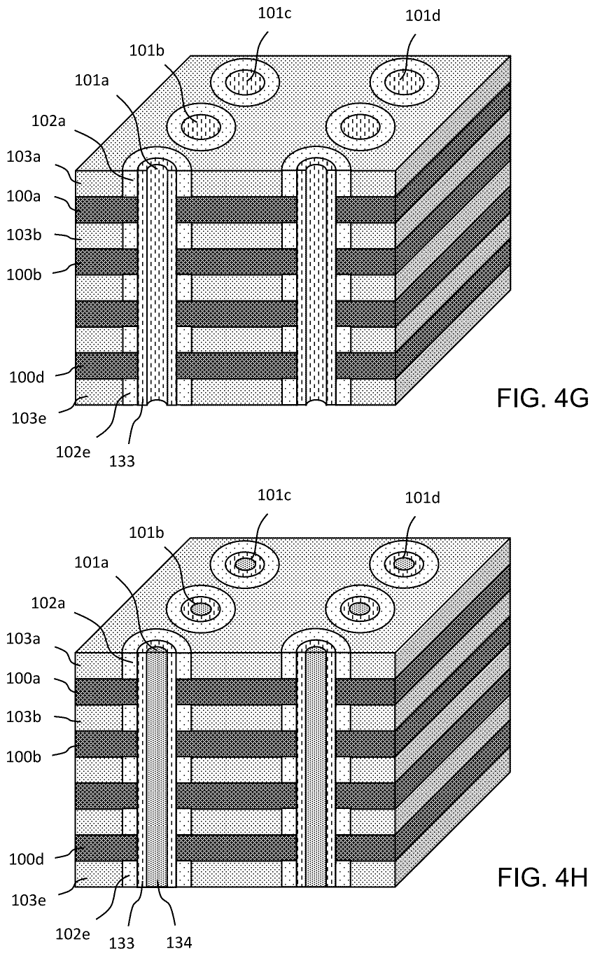

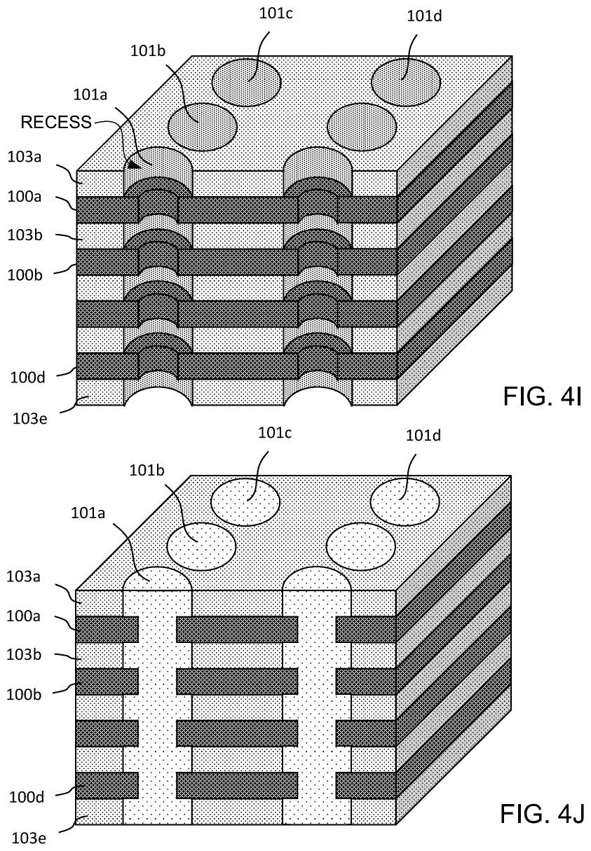

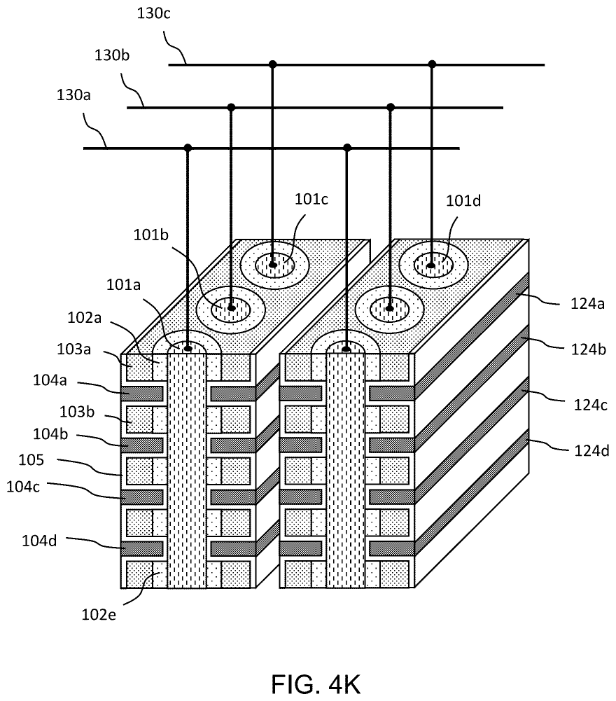

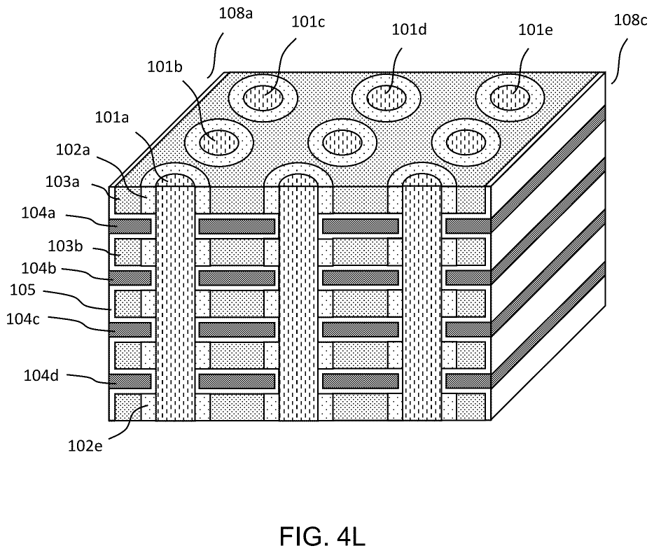

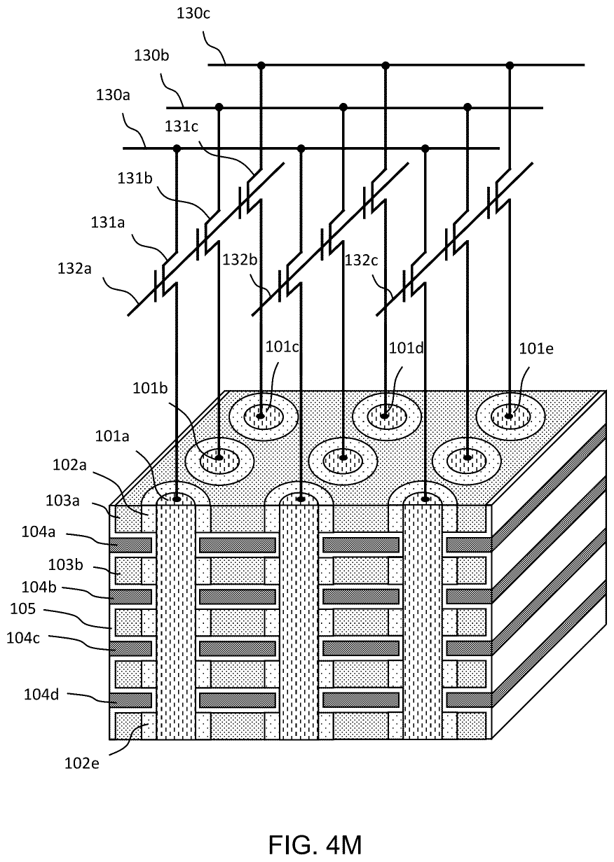

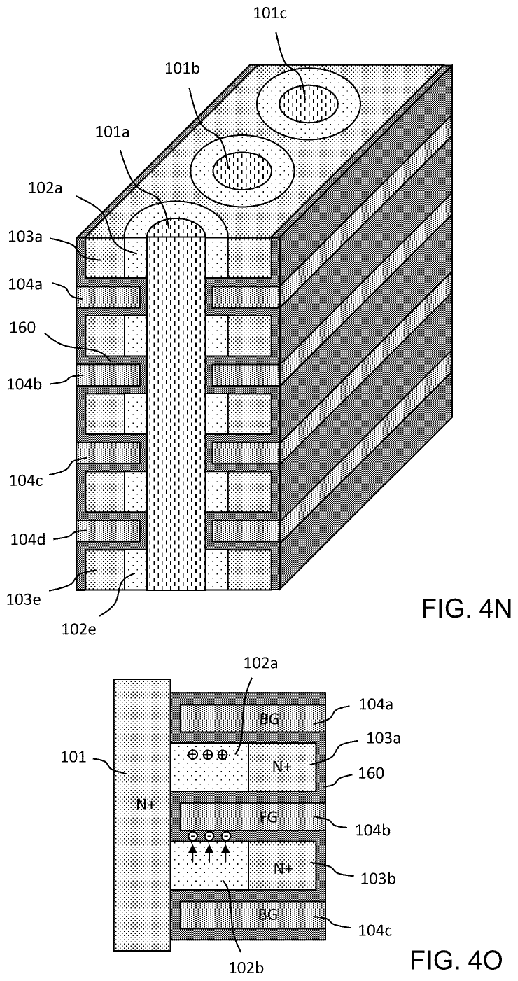

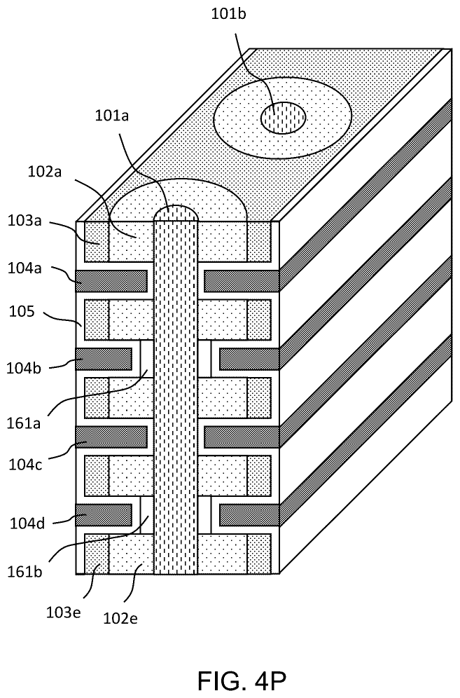

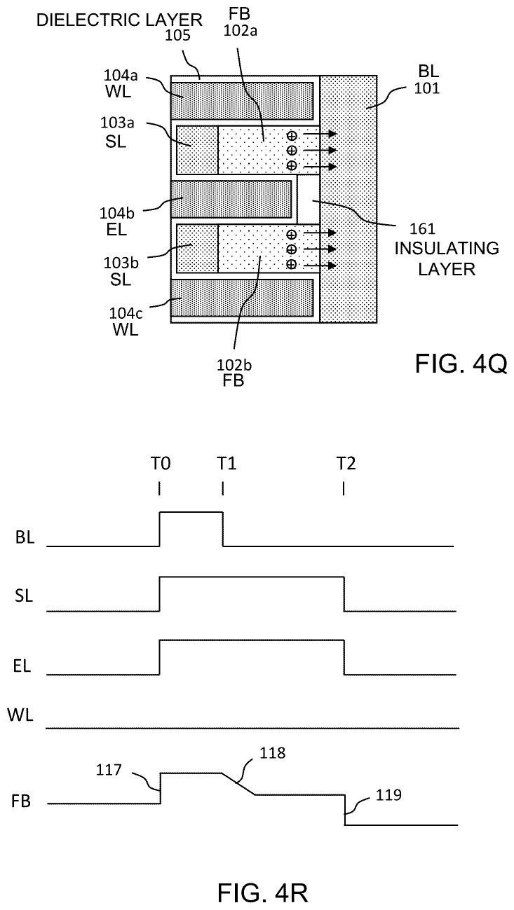

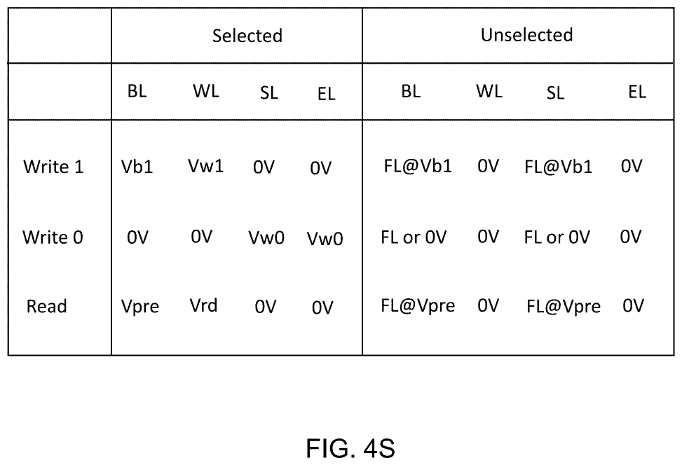

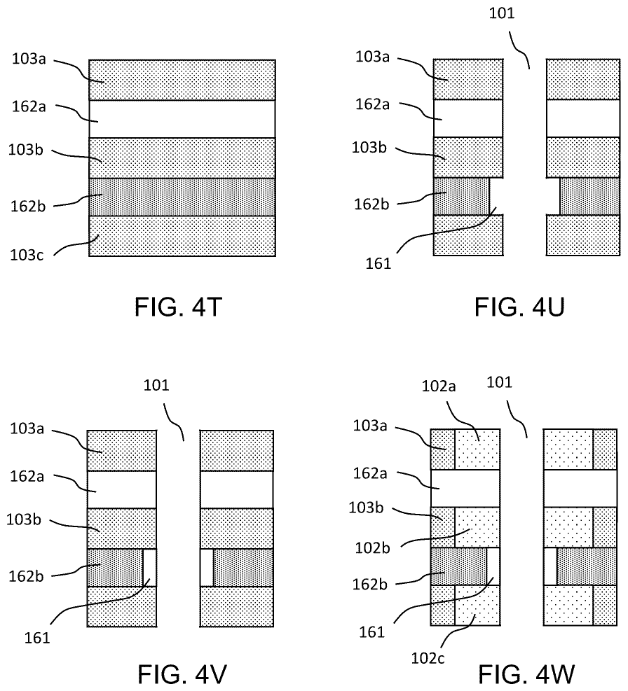

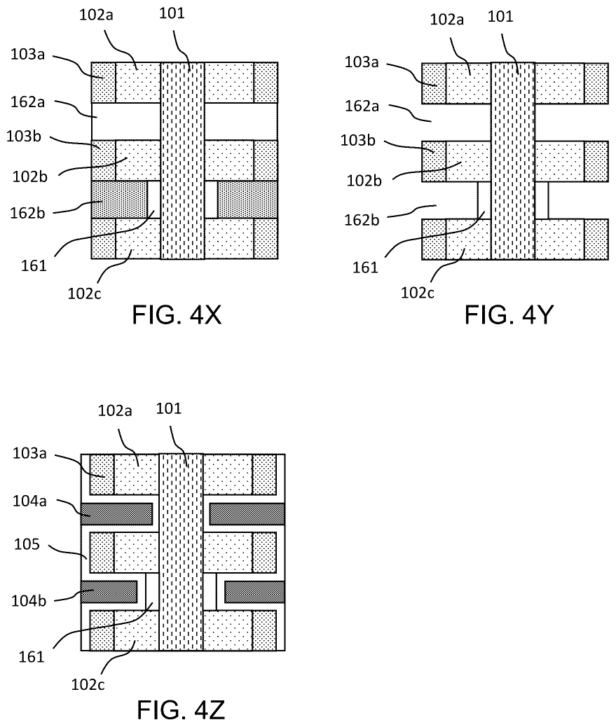

FIGS. 4A-F show simplified process steps for constructing the array structure shown in FIG. 1D.

FIG. 4A shows how multiple sacrificial layers, such as layers 100a to 100d and multiple semiconductor layers, such as silicon or polysilicon layers, forming source lines 103a to 103e, are alternatively deposited to form a stack. The semiconductor source line layers 103a to 103e, have N+ or P+ type of the doping to form NMOS or PMOS transistors, respectively. The sacrificial layers 100a to 100d have different selectivity from the silicon or polysilicon layers for etching solutions. For example, the sacrificial layers 100a to 100d can be oxide or nitride. Then, multiple vertical bit line holes, such as holes for bit lines 101a to 101d are formed by using an anisotropic etching process, such as a deep trench process, to etch through the multiple layers.

FIG. 4B shows how the body of the transistors, such as floating bodies 102a to 102e are formed by using a diffusion process to diffuse the opposite type of impurity of the semiconductor source line layers 103a to 103e through the vertical bit line holes, such as holes 101a to 101d. For example, if the semiconductor source line layers 103a to 103e have N+ type of doping, the body of the transistors, such as floating bodies 102a to 102e are diffused with P− type of doping, such as boron. If the semiconductor source line layers 103a to 103e have P+ type of doping, the body of the transistors, such as floating bodies 102a to 102e are diffused with N− type of doping, such as phosphorus. This forms donut-shape transistor floating bodies 102a to 102e, etc. as shown.

FIG. 4C shows how the vertical bit line holes, such as holes for bit lines 101a to 101d are filled with semiconductor material, such as silicon or polysilicon to form vertical bit lines. The semiconductor layer may have the opposite type of doping as the floating bodies 102a to 102e. For example, if the floating bodies 102a to 102e has P− or N− type of doping, the vertical bit lines 101a to 101d have N+ or P+ type of doping, respectively. Then, vertical slits, such as slits 108a to 108c are formed by using deep trench process to etch through the multiple sacrificial layers 100a to 100d and silicon or polysilicon layers for source lines 103a to 103e. The vertical slits 108a to 108b cut the stack into multiple stacks.

FIG. 4D shows how the sacrificial layers 100a to 100d are selectively removed by using an isotropic etch process, such as wet etch or plasma etch through the slits 108a to 108c.

FIG. 4E shows how a thin-gate dielectric layer 105 is deposited on the surface of the semiconductor source line layers 103a to 103b and the sidewall of the bit lines 101a to 101d through the slits 108a to 108c by using thin-film deposition to form the gate dielectric layer of the transistors. The gate dielectric layer 105 may be oxide or high-K material, such HfOx. After that, a material of the front gate and back gate 104, such as metal or silicon or polysilicon is deposited through the vertical slits 108a to 108c to fill the slits 108a to 108c and the space between the semiconductor source line layers 103a to 103e.

FIG. 4F shows how an anisotropic etch process is performed to vertically etch the gate material in the slits 108a to 108c and form the individual word lines, such as word lines 104a to 104d. As a result, the array structure shown in FIG. 1D is realized. It should be noted that simplified process steps shown in FIGS. 4A-F are used to demonstrate the fundamental process steps according to the invention. Extra steps and minor variations may be applied, and these variations shall remain in the scope of the invention.

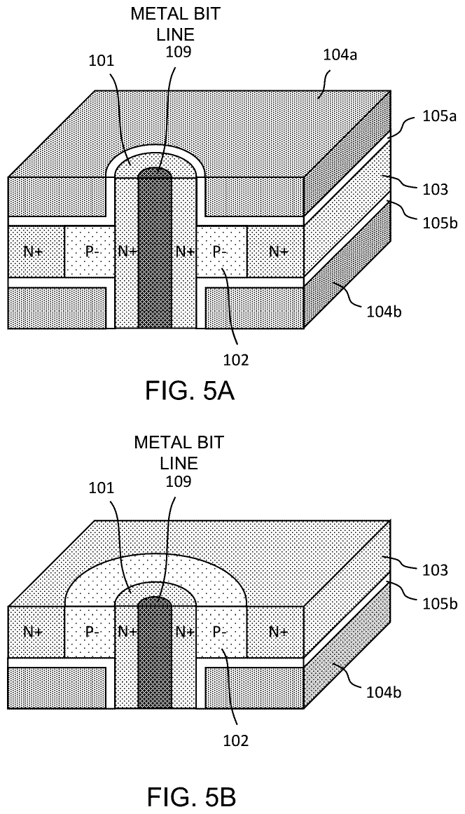

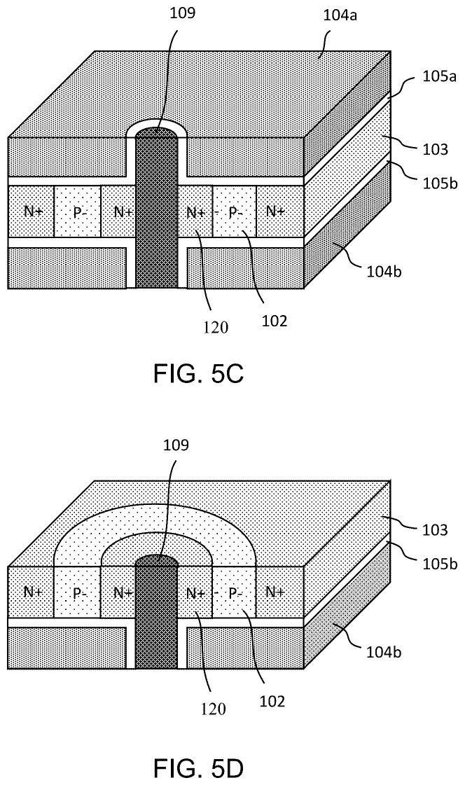

FIGS. 4G-H show additional embodiments of array structures according to the invention to form another embodiment of a cell structure shown in FIG. 5A-B. As illustrated in FIG. 4G, after the process step shown in FIG. 4B are performed, a thin-film deposition or epitaxial thin-film growth process is performed to form a semiconductor layer 133, such as silicon or polysilicon layer, on the sidewall of the vertical holes for the bit lines 101a to 101d. The semiconductor layer 133 is doped with the same type of dopant as the semiconductor source line layers 103a to 103e by using an in-situ doping process or diffusion process through the vertical holes for the bit lines 101a to 101d.

FIG. 4H shows how the vertical holes for the bit lines 101a to 101d are filled with a metal core 134 by using a metal deposition process. This can reduce the resistance of the vertical bit lines to increase the speeds of read and write operations.

FIGS. 4I-J show another embodiment of process steps to form the floating bodies 102a to 102e. After the process steps shown in FIG. 4A are performed, an isotropic etching process, such as wet etch or chemical etch, is performed through the vertical holes for the bit lines 101a to 101d to selectively etch the semiconductor source line layers 103a to 103e to form the recesses as shown.

FIG. 4J shows how the vertical holes for the bit lines 101a to 101e, are filled with a semiconductor material, such as silicon or polysilicon, which is formed by using an epitaxial growth process. In one embodiment, the semiconductor layer in the vertical holes for the bit lines 101a to 101d has the opposite type of impurity of the semiconductor source line layers 103a to 103e. For example, if the semiconductor source line layers 103a to 103e have N+ or P+ type of doping, the semiconductor layer in the vertical holes for the bit lines 101a to 101d have P− or N− type of doping, respectively, which is formed by using an in-situ doping process during the epitaxial growth.

After that, a self-aligned anisotropic etching process, such as dry etch or reactive-ion etch (RIE), is performed using the sacrificial layers 100a to 100d as masks to selectively etch the semiconductor layer in the vertical holes for the bit lines 101a to 101d to form the array structure shown in FIG. 4B. After that, the process steps shown in FIGS. 4C-F are performed to form the array structure shown in FIG. 4F.

FIG. 4K shows an embodiment of the bit line connection of the array structure shown in FIG. 4F. The vertical bit lines, such as 101a to 101d, are connected to horizontal metal bit lines 130a to 130c as shown. Although the embodiment shows the horizontal metal bit lines 130a to 130c located on top of the array, in another embodiment, the metal bit lines 130a to 130c are located in the bottom of the array.

It should be noted that because the vertical bit lines, such as 101c and 101d are connected to the same horizontal metal bit line 130c, the word lines 104a to 104d and word lines 124a to 124d are connected to different decoders' signals to prevent the cells in vertical bit lines to be selected together. This will require many word line decoders and also increase the process challenge to connect so many word lines to the decoders.

FIG. 4L shows another embodiment of the array structure according to the invention to solve the previously mentioned issue with using many word line decoders. In this embodiment, the vertical bit lines, such as 101a to 101e, are all coupled to the same word line layers 104a to 104d. This reduces the number of the word lines need to be connected to the decoders. Therefore, the number of the word line decoders is reduced. The process step of this embodiment is the same as that of the embodiment shown in FIG. 4F, except that the word line processes are performed through the vertical slits 108a and 108c on two sides of the stack.

FIG. 4M shows the bit line connections of the array embodiment shown in FIG. 4L. FIG. 4M illustrates horizontal metal bit lines 130a to 130c. The vertical bit lines, such as 101a to 101c, are connected to the horizontal metal bit lines 130a to 130c through select transistors 131a to 131c. The select transistors, such as 131a to 131c are formed by using any suitable process and technologies, such as vertical transistors, planar transistors, junction-less transistors, and so on. Although the embodiment shows NMOS transistors as an example, the select transistors, such as 131a to 131c, can be formed as PMOS transistors as well. Moreover, although the embodiment shows that the horizontal metal bit lines 130a to 130c and the select transistors, such as 131a to 131c, are located on top of the array, in another embodiment, the bit lines and the select transistors can be located in the bottom of the array as well.

The gates 132a to 132c of the select transistors are connected to different decoders' signals. For example, when the gate 132a is selected, it will turn on the select transistors 131a to 131c to couple the vertical bit lines 101a to 101c to the horizontal metal bit lines 131a to 131c, respectively. The unselected gates 132b and 132c will turn off the associated select transistors. This presents multiple vertical bit lines to be coupled to the same metal bit line.

FIG. 4N shows another embodiment of an array architecture according to the invention. This embodiment is similar to the embodiment shown in FIG. 1D except that the gate dielectric layer 105 is replaced by a charge-trapping layer 160, which traps electric charge such as electrons. When electrons are trapped inside the charge-trapping layer, the threshold voltage of the transistor is increased. This results in lower cell current during read operations. Therefore, the data can be stored in the charge-trapping layer 160 in terms of the number of trapped electrons. Because the trapped electrons remain in the charge-trapping layer after power down, this embodiment can be used as a non-volatile memory, such as 3D NOR flash memory.

In one embodiment, the charge trapping layer 160 is formed as a nitride layer or oxide-nitride layers. Because a nitride layer's electrical barrier is lower than an oxide layer's, this embodiment allows the data to be written in lower gate voltage and shorter time. However, because of the lower electrical barrier, it is easier for the electrons to escape from the charge-trapping layer 160, thus the data retention time is also shorter.

This embodiment is suitable for the application of non-volatile buffer memory. In normal operation, the data is stored in the floating bodies 102a to 102e of the cells, as described in the previous embodiments shown in FIG. 2A to FIG. 3B. When the system becomes idle or during an accidental power loss event, the data stored in the floating bodies 102a to 102e can be quickly written to the charge-trapping layer 160 to preserve the data. Because the electrons stored in the charge-trapping layer 160 may escape after a period of time, a refresh operation with longer duration may still be needed during the system idle. However, since the frequency of the refresh operation is reduced, the power consumption is also reduced. In the case of power loss, a battery or a large capacitor may be utilized to temporarily maintain the power of the system until the data stored in the charge-trapping layer 160 is copied to another non-volatile memory, such as NAND flash memory or hard disk drives.

In another embodiment, the charge-trapping layer 160 comprises a sandwich of oxide-nitride-oxide (ONO) layers. Due to the oxide layer having a higher electrical barrier than the nitride layer, the electrons trapped in the nitride layer are more difficult to escape. Therefore, the data retention time for this embodiment is much longer, like years. This embodiment may be used as a permanent non-volatile memory. However, due to the oxide layer's higher electrical barrier, this embodiment requires higher write voltage, such as 10V to 20V.

FIG. 4O shows an embodiment of a non-volatile program operation to write the data stored in the floating bodies 102a and 102b to the charge-trapping layer 160. Assuming the data stored in the floating bodies 102a and 102b is ‘1’ and ‘0’, respectively. During the non-volatile program operation, the front gate 104b is supplied with a program voltage, such as 3-5V for a nitride layer and 10-20V for ONO layers. The bit line 101 and the source lines 103a and 103b are floating. For the floating body 102a, the holes stored in the floating body 102a reduce the electrical field between the front gate 104b and the floating body 102a to below the threshold of the Fowler-Nordheim (F-N) tunneling mechanism. Therefore, F-N tunneling may not happen. For the floating body 102b, due to the fact there are no holes, the electrical field between the front gate 104b and the floating body 102b is sufficient to induce F-N tunneling, and thus electrons may be injected into the charge-trapping layer 160 and trapped inside the layer to increase the threshold voltage of the cell transistor.

FIG. 4P shows another embodiment of a 3D floating body cell array structure according to the invention. This embodiment is similar to the one shown in FIG. 1D except that the insulating layers 161a and 161b, such as oxide or nitride, are formed in the junctions of the vertical bit lines 101a and 101b and the odd word line layers 104b and 104d. This prevents the channels induced by the even word lines 104b and 104d to reach the vertical bit lines 101a and 101b. In this embodiment, the even word lines 104a and 104c are connected to normal word line (WL) signals, and the odd word lines 104b and 104d are connected to ‘erase word lines (EL)’ signals. The erase word line 104b is activated during write ‘0’ operation to ‘erase’ the data stored in the cells. The array structure allows the cells to perform special write ‘0’ operation shown in FIGS. 4Q-R. For a detailed description of the array structure, please refer to FIG. 1D.

FIG. 4Q shows a write ‘0’ condition of the array structure embodiment shown in FIG. 4P. FIG. 4Q shows the vertical bit line (BL) 101 and floating bodies (FB) 102a and 102b. Also shown are source lines (SL) 103a and 103b, word lines (WL) 104a and 104c, erase word line (EL) 104b, gate dielectric layer 105 and insulating layer 161.

FIG. 4R shows an embodiment of write ‘0’ waveforms. At time T0, the bit line (BL), source line (SL), and erase line (SL) are supplied with a positive voltage. This will couple up the voltage of the floating bodies 102a and 102b as shown at indicator 117. The applied voltage is high enough to couple the floating bodies to a voltage higher than the threshold voltage of the P/N junction, such as 0.5V to 0.7V.

At time T1, the bit line (BL) is supplied with 0V. This will cause forward bias current to flow from the floating bodies 102a and 102b to the bit line 101, and evacuate the holes stored in the floating bodies 102a and 102b to lower their potential, as shown at indicator 118. Due to the insulating layer 161, the channel induced by the erase word line 104b will not reach the bit line 101. This prevents the channel voltage from being discharged by the bit line voltage to reduce the voltage coupling of the floating bodies. The word lines 104a and 104c are supplied with 0V to turn off the channels induced by the word lines to prevent leakage current from the source lines to the bit line.

At time T2, the erase word line 104b and source lines 103a and 103b are supplied with 0V. This will couple down the floating bodies 102a and 102b, as shown at indicator 119, to be lower than its initial voltage. Thus, the threshold voltage of the floating body cells are increased, which represents the state of data ‘0’.

FIG. 4S shows bias conditions of write data ‘1’, write data ‘0’, and read operations for the array embodiment shown in FIG. 4P. The conditions are similar to the ones shown in FIG. 3D except for the write ‘0’ condition. During the write ‘0’ condition, the selected erase word line (EL) and source line (SL) are supplied with a positive voltage Vw0, which shall be high enough to couple up the floating body of the cell to be higher than the threshold voltage of the P/N junction. During read and write ‘1’ operations, the erase word line (EL) is supplied with 0V or any other suitable voltage. Because the channel induced by the erase word line (EL) does not reach the bit line, it will not cause current leakage even when the channel is turned on.

FIGS. 4T-Z show an embodiment of process steps to form the cell array structure shown in FIG. 4P.

FIG. 4T shows how multiple semiconductor source line layers 103a to 103c, such as silicon, and insulating layers 162a and 162b, are alternately deposited to form a stack. The even insulating layers, such as 162a, and odd insulting layers, such as 162b, are different material. For example, in one embodiment, the even insulating layer 162a comprises an oxide layer and the odd insulating layer 162b comprises a nitride layer.

FIG. 4U shows how multiple vertical holes, such as hole 101, is formed by using an anisotropic etching process, such as deep trench or dry etch to etch through the multiple semiconductor source line layers 103a to 103c and the insulating layers 162a and 162b to form the vertical bit line pattern. After that, recessed area for the insulating layer 161 is formed in the odd insulting layers, such as layer 162b by using an isotropic etching process, such as wet etch or chemical etch through the hole for the bit line 101.

FIG. 4V shows how the hole for the bit line 101 is filled with an insulating layer which is different from the insulating layer 162b. For example, if the insulting layer 162b is nitride, the insulator used in filling the hole for the bit line 101 may be oxide. After that, the insulator in the hole for the bit line 101 is etched using an anisotropic etching process, such as dry etch, to remove the insulator in the hole for the bit line 101 except for the residual in the recessed area for the insulating layer 161.

FIG. 4W shows how the floating bodies 102a to 102c are formed by using a diffusion process to diffuse the semiconductor source line layers 103a to 103c with the opposite type of impurity through the hole for the bit line 101. For example, if the semiconductor source line layers 103a to 103c have N+ type or P+ type of doping, the floating bodies 102a to 102c have P− type or N− type of doping, respectively. This step forms ‘donut’ shapes for the floating bodies 102a to 102c.

FIG. 4X shows how the hole for the bit line 101 is filled with semiconductor to form a vertical bit line. The semiconductor may be doped with the opposite type of impurity of the floating bodies 102a to 102c by using an in-situ doping process.

FIG. 4Y shows how even insulting layers, such as 162a, are selectively etched by using an isotropic etching process, such as wet etch or chemical etch. After that, the odd insulating layers, such as 162b, are selectively etched by using an isotropic etching process, such as wet etch or chemical etch. Because the insulating layers 161 and 162b are different materials, the insulating layer 161 will not be etched.

FIG. 4Z shows how a gate dielectric layer 105 is formed on the surface of the array structure by using a thin-film deposition process. After that, the spaces previously occupied by the insulating layers 162a and 162b, as shown in FIG. 4Y, are filled with a control gate material, such as metal or polysilicon, to form the word line 104a and erase word line 104b.

FIG. 5A shows another embodiment of a cell structure according to the invention. This embodiment is similar to the one shown in FIG. 1A except that a metal core is formed in the center of the bit line 101 to form a metal bit line 109 to reduce the bit line resistance.

FIG. 5B shows the cell structure of FIG. 5A with the front gate 104a and gate dielectric layer 105a removed to show the inner structure. The cell structure shown in FIGS. 5A-B is formed by using a similar process to that shown in FIGS. 4A-D except that in FIG. 4D, the silicon or polysilicon layer for bit line 101a is deposited on the surface of the sidewall of the vertical bit line hole instead of filling the bit line hole. Then, the bit line hole is filled with metal to form a metal bit line 109.

FIG. 5C shows another embodiment of a cell structure according to the invention. FIG. 5D shows the cell structure of FIG. 5C with the front gate 104a and the gate dielectric layer 105a removed.

The embodiment shown in FIG. 5C is similar to the embodiment shown in FIG. 5A except that an N+ silicon or polysilicon 120 is formed as a donut shape island for each cell and connected to the metal bit line 109 that is formed by filling the vertical bit line hole with metal. For comparison, the N+ silicon or polysilicon layer for bit line 101 shown in FIG. 5A is a continuous layer formed on the sidewall of the metal bit line 109. Similarly, the cell structure shown in FIGS. 5C-D is formed by a similar process to that shown in FIGS. 4A-D except that in FIG. 4B, after the P− floating body 102 is formed, the N+ region 120 is formed by using an implantation or diffusion through the bit line hole. Then, the bit line hole is filled with the metal to form the metal bit line 109.

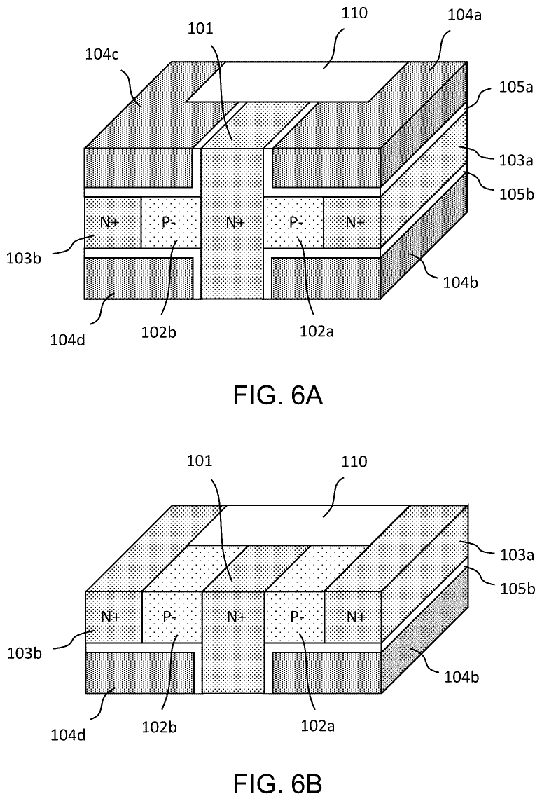

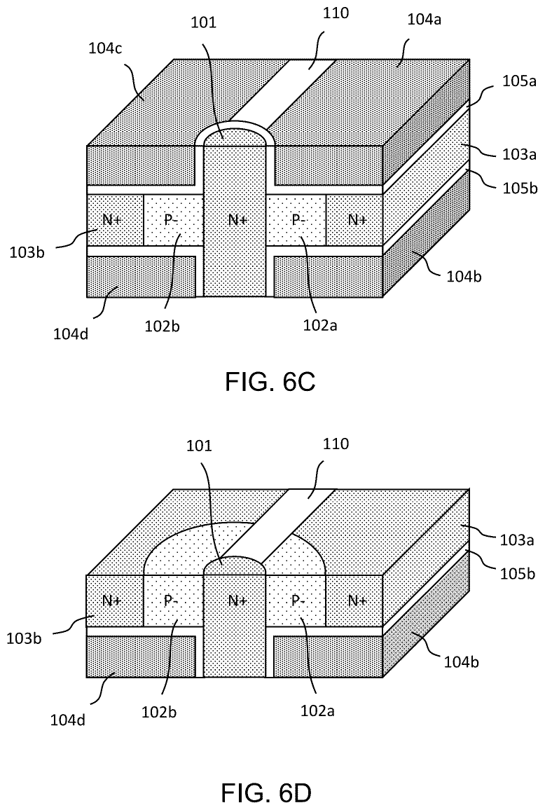

FIG. 6A shows another embodiment of a cell structure according to the invention. FIG. 6B shows the cell structure shown in FIG. 6A with the front gate 104a and gate dielectric layer 105a removed. This embodiment is similar to the embodiment shown in FIG. 1A except that the cell is divided into two cells by an insulating layer 110, such as an oxide. The insulating layer 110 divides the floating body into 102a and 102b, and divides the front gate into 104a and 104c, and divides the back gate into 104b and 104d. In this way, the bit line 101 is connected to two cells, thus the memory array capacity is doubled. Similar to the embodiment shown in FIG. 1A, this cell structure may be formed by using NMOS or PMOS transistors. Besides, the floating bodies 102a and 102b and bit line 101 may be any shape, such as circular.

FIGS. 6C-D show another embodiment of a cell structure according to the invention. This embodiment is similar to the embodiment shown in FIGS. 6A-B except that the floating bodies 102a and 102b and bit line 101 are circular.

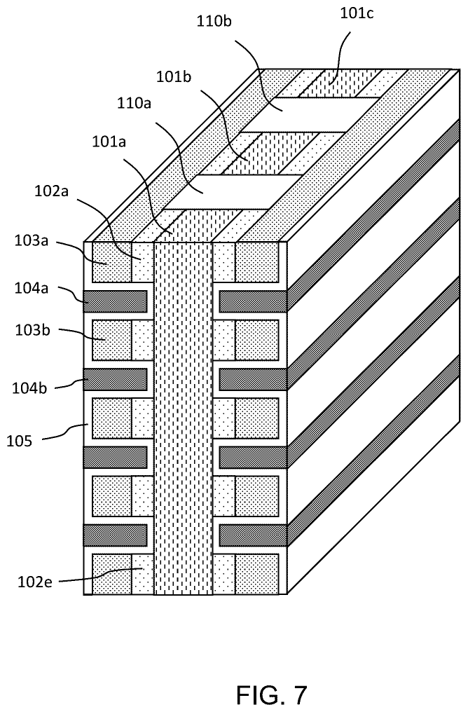

FIG. 7 shows an embodiment of an array structure based on the cell structure shown in FIG. 6A. The array structure of FIG. 7 includes bit lines 101a to 101c, floating bodies 102a to 102e, source lines 103a and 103b, word lines 104a and 104b, gate dielectric layer 105, and insulating layers 110a and 110b that comprise an oxide.

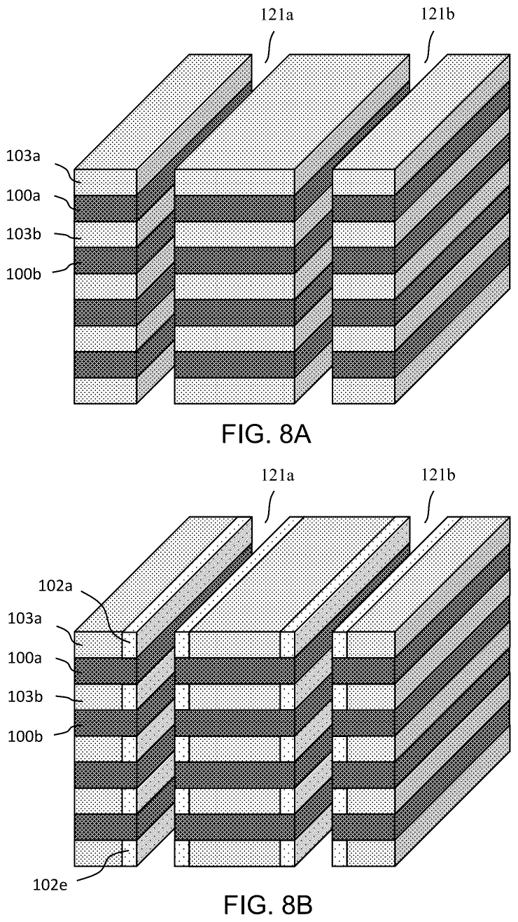

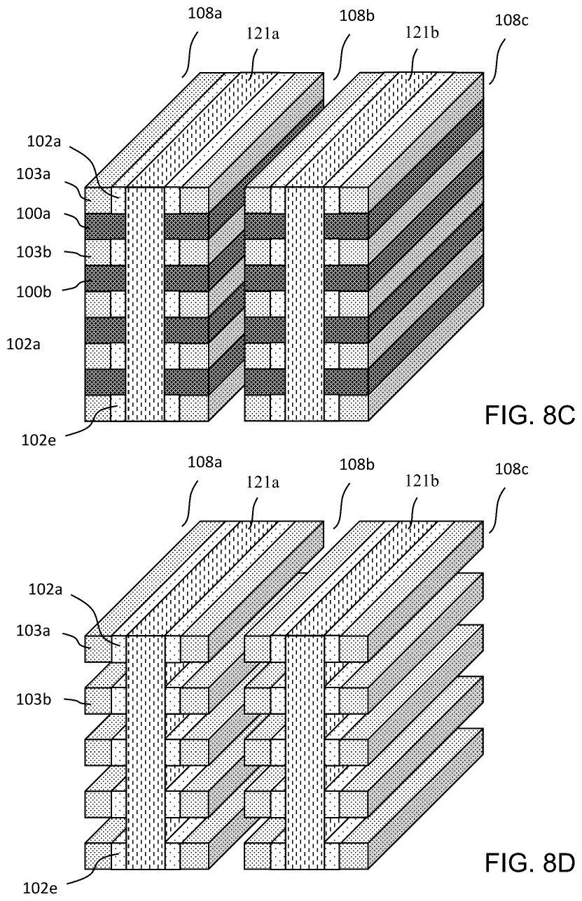

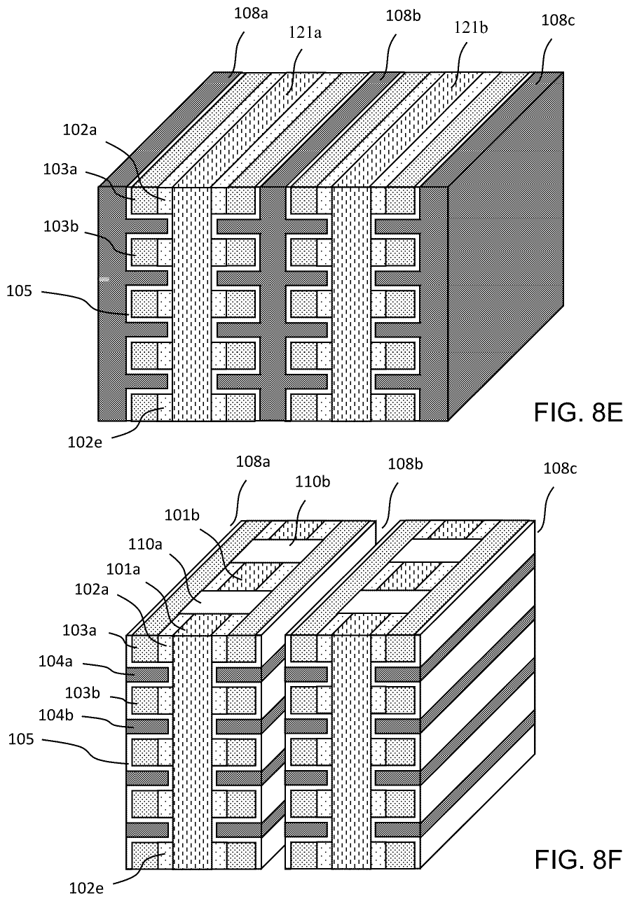

FIGS. 8A-F show simplified process steps for forming the array structure shown in FIG. 7.

FIG. 8A shows how multiple sacrificial layers, such as layers 100a and 100b, and multiple N+ silicon or polysilicon layers, such as layers for bit lines 101a and 101b, are alternatively deposited to form a stack. Then, multiple vertical slits, such as slits 121a and 121b are formed by using a deep trench process to etch through the multiple layers.

FIG. 8B shows how a P− floating body, such as P− floating bodies 102a to 102e are formed by using implantation or diffusion through the slits, such as slits 121a and 121b. This process forms P− silicon or polysilicon strips.

FIG. 8C shows how the slits, such as slits 121a and 121b are filled with N+ silicon or polysilicon. Then, vertical slits, such as vertical slits 108a to 108c are formed by a deep trench process to etch through the stack.

FIG. 8D shows how the sacrificial layers, such as layers 100a and 100b are removed by using an isotropic etch process, such as wet etch or plasma etch, through the slits 108a to 108c.

FIG. 8E shows how a thin dielectric layer 105 is deposited on the surface of the sidewall through the slits 108a to 108c. Then, the material for the front gate and back gate, such as metal or silicon or polysilicon is deposited to fill the slits 108a to 108c and the space between the silicon or polysilicon layers for source lines 103a and 103b, etc.

FIG. 8F shows how vertical bit lines, such as bit lines 101a and 101b are formed by using a deep trench process to etch holes for the bit lines 110a and 110b, etc. and filling the holes with an insulator, such as an oxide. After that, an anisotropic etch process is performed to vertically etch the gate material in the slits 108a to 108c to form the individual word lines, such as word lines 104a and 104b, etc. As a result, the array structure shown in FIG. 7 is realized.

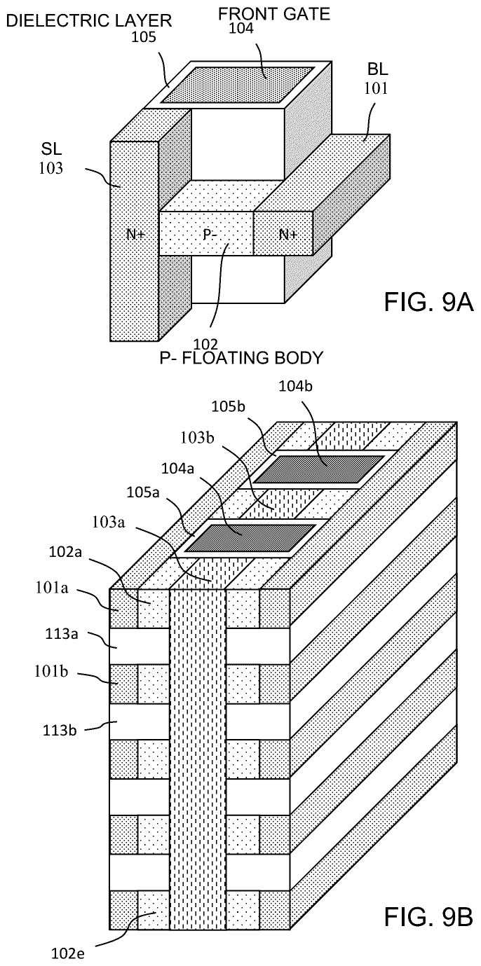

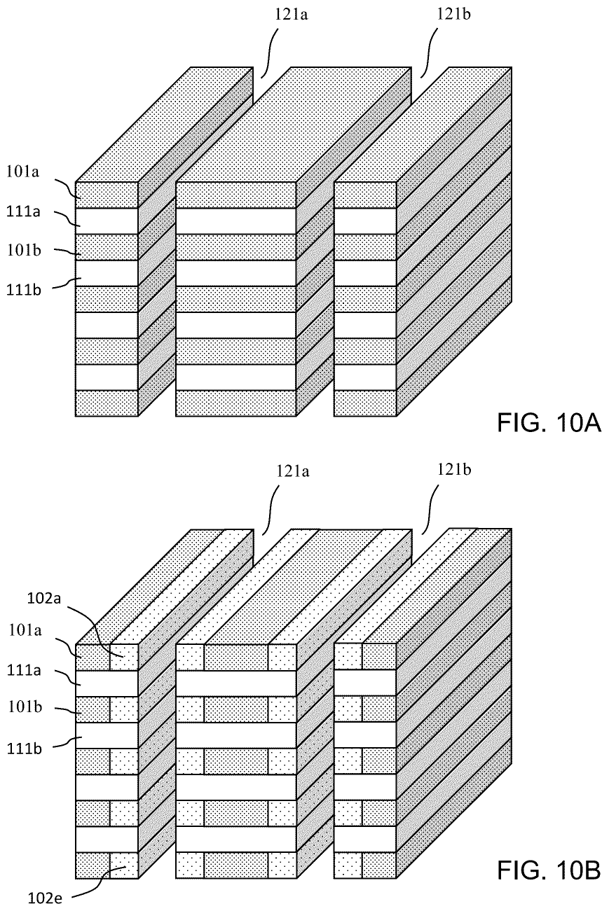

FIG. 9A shows another embodiment of a cell structure according to the invention. The cell structure in FIG. 9A comprises N+ silicon or polysilicon that forms a bit line 101, a P− floating body 102 for charge storage, N+ silicon or polysilicon that forms a source line 103, a front gate 104, and a gate dielectric layer 105. The back gate is not shown to make it easier to illustrate. The front gate 104 of the cells on multiple layers are connected to form a word line (WL). In this embodiment, because the word line 104 runs in a vertical direction, the horizontal N+ silicon or polysilicon line becomes the bit line 101, and the vertical N+ silicon or polysilicon line becomes the source line 103.

It should be noted that when talking about single cell (transistor) structure, the front gate structure is referred to as a gate. If the cell has dual gates, one gate is called the “front gate” and the other gate is called the “back gate.” In an array level structure, the gates of multiple cells are connected to form a word line, so the gate structures are also referred to as word lines.

FIG. 9B shows an embodiment of an array structure based on the cell structure shown in FIG. 9A. The structure of FIG. 9B comprises bit lines 101a and 101b, floating bodies 102a to 102e, source lines 103a and 103b, word lines 104a and 104b, gate dielectric layers 105a and 105b, and insulating layers 113a and 113b, such as oxide layers.

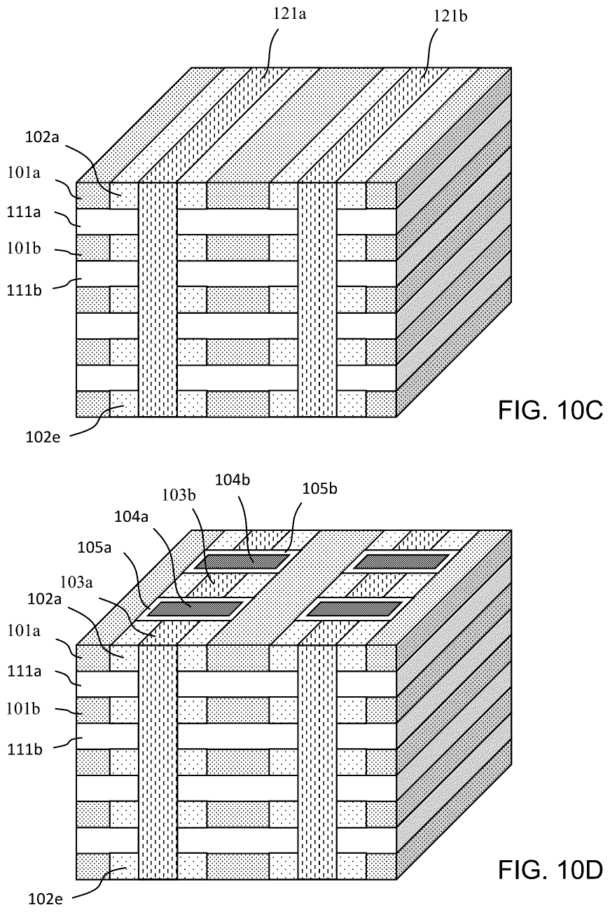

FIGS. 10A-D show simplified process steps for constructing the cell structure shown in FIG. 9A.

FIG. 10A shows how multiple N+ silicon or polysilicon layers, such as layers for bit lines 101a and 101b, and multiple insulating layers, such as layers 111a and 111b are alternatively deposited to form a stack. Then, multiple vertical slits, such as slits 121a and 121b are formed by using a deep trench process to etch through the multiple layers.

FIG. 10B shows how P-bodies, such as P− floating bodies 102a to 102e are formed by using implantation or diffusion through the slits 121a and 121b. This forms P− silicon or polysilicon strips.

FIG. 10C shows how the slits 121a and 121b are filled with N+ silicon or polysilicon.

FIG. 10D shows how multiple holes are formed by a deep trench process and thin gate dielectric layers, such as layers 105a and 105b, are formed on the sidewall of the holes. Then, the holes are filled with the gate material, such as metal or silicon or polysilicon to form vertical word lines, such as word lines 104a and 104b. As a result, the array structure shown in FIG. 9B is realized.

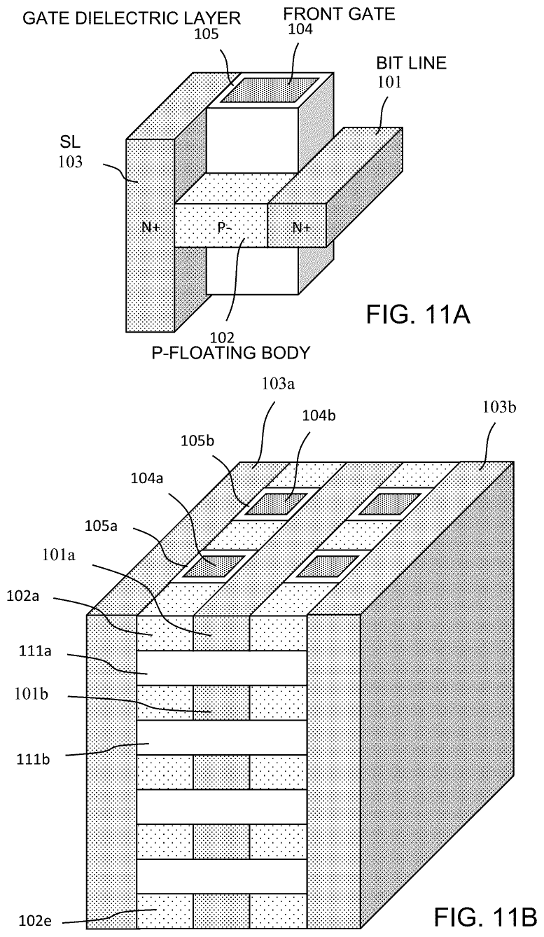

FIG. 11A shows another embodiment of a cell structure according to the invention. The cell structure shown in FIG. 11A comprises a bit line 101 formed from N+ silicon or polysilicon, a P− floating body 102 for charge storage, a source line 103 formed from N+ silicon or polysilicon, a front gate 104, and a gate dielectric layer 105. The back gate is not shown to make it easier to illustrate. The front gate 104 of the cells on multiple layers are connected to form a word line (WL). In this embodiment, because the word line 104 runs in a vertical direction, the horizontal N+ silicon or polysilicon line becomes the bit line 101. The vertical N+ silicon or polysilicon line becomes the source line 103.

FIG. 11B shows an embodiment of an array structure based on the cell structure shown in FIG. 11A. The array structure shown in FIG. 11B comprises bit lines 101a to 101b, floating bodies 102a to 102e, source lines 103a and 103b, word lines 104a and 104b, gate dielectric layers 105a and 105b, and insulating layers 111a and 111b that are formed from a material such as an oxide.

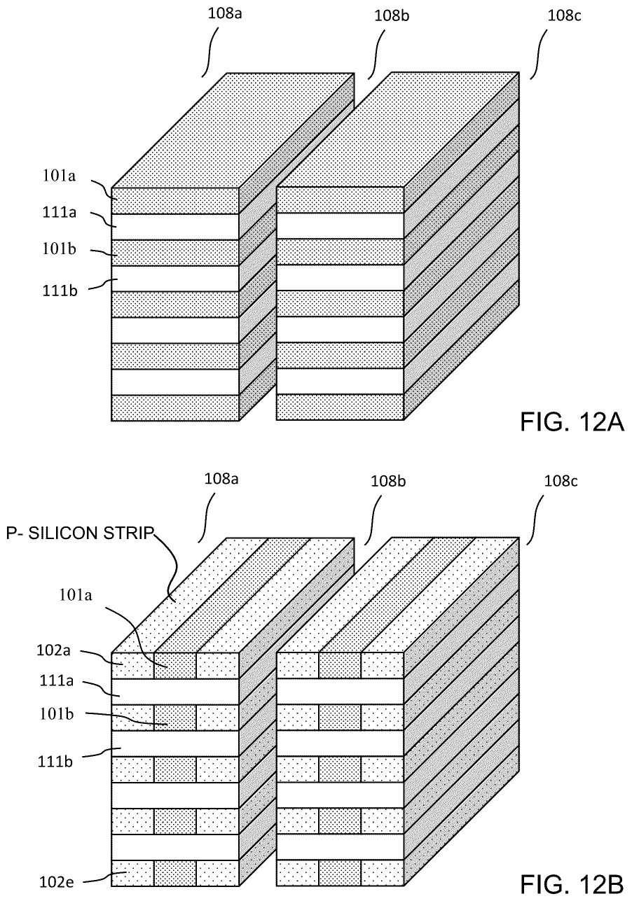

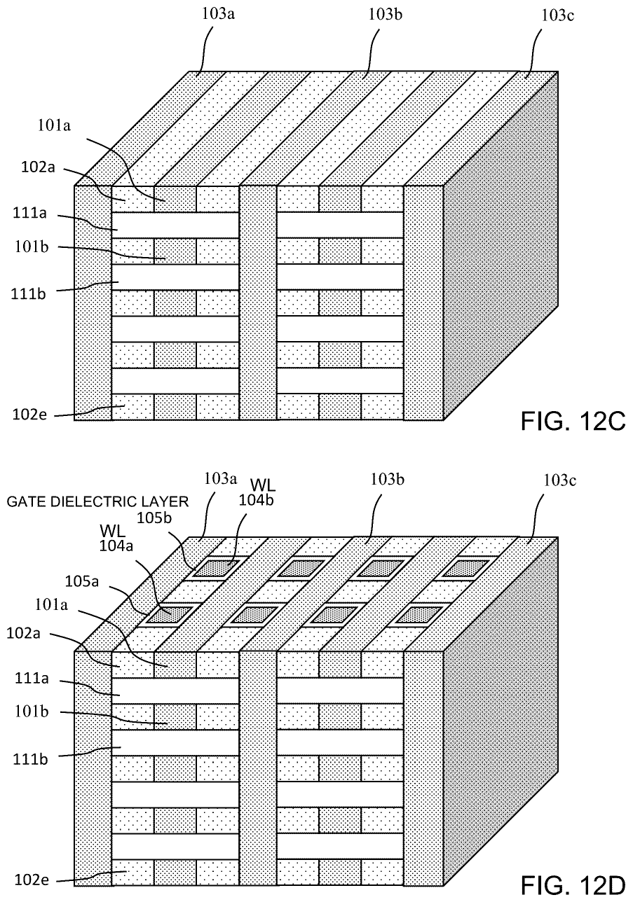

FIGS. 12A-D shows simplified process steps for constructing the cell structure shown in FIG. 11A.

FIG. 12A shows how multiple N+ silicon or polysilicon layers, such as layers for bit lines 101a and 101b, and multiple insulating layers, such as layers 111a and 111b are alternatively deposited to form a stack. Then, multiple vertical slits, such as vertical slits 108a to 108c are formed by using a deep trench process to etch through the multiple layers.

FIG. 12B shows how P− floating bodies, such as P− floating bodies 102a to 102e are formed by using implantation or diffusion through the vertical slits 108a to 108c. This forms P− silicon or polysilicon strips.

FIG. 12C shows how the slits 108a to 108c are filled with N+ silicon or polysilicon to form the source lines 103a to 103c.

FIG. 12D shows how multiple holes are formed by a deep trench process and thin gate dielectric layers 105a and 105b are formed on the sidewall of the holes. Then, the holes are filled with the gate material, such as metal or silicon or polysilicon, to form vertical word lines, such as word lines 104a and 104b. As a result, the array structure shown in FIG. 11B is realized.

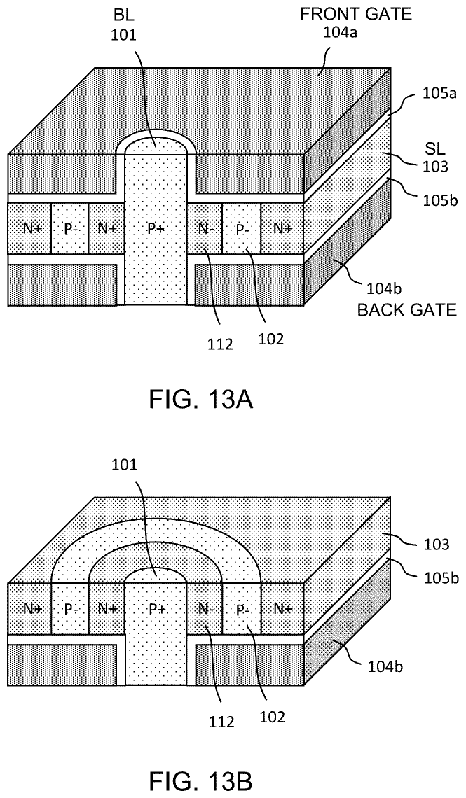

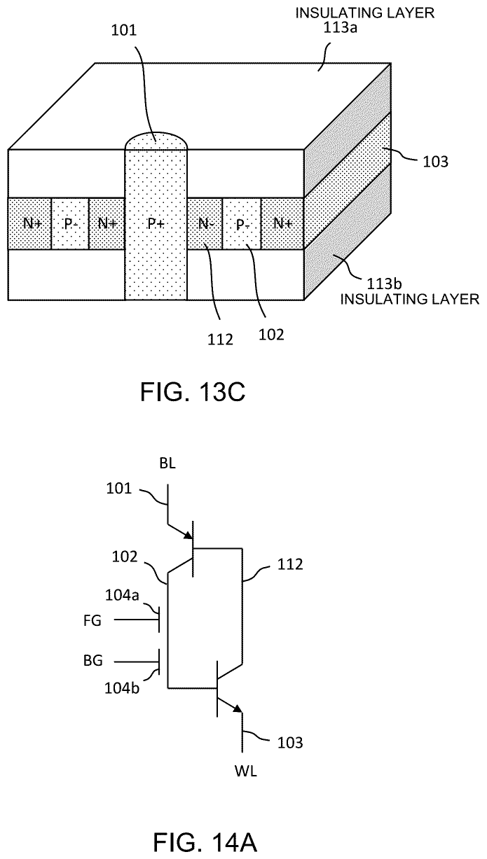

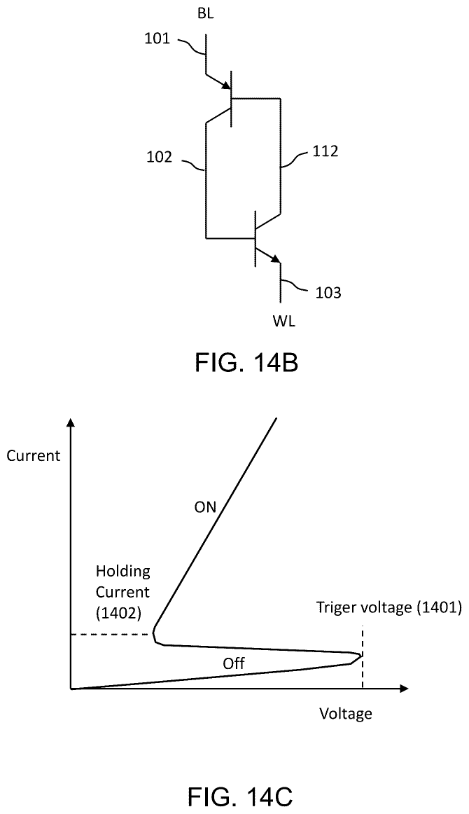

FIG. 13A shows another embodiment of a DRAM-replacement technology according to the invention. This technology uses a 3D thyristor cell and includes P+ silicon or polysilicon for bit line 101, N− silicon or polysilicon 112, P− silicon or polysilicon 102, and N+ silicon or polysilicon for source line 103. The P+ silicon for bit line 101, P− silicon 112, and P− silicon 102 form a PNP bipolar transistor. The N− silicon 112, P− silicon 102, and N+ silicon for source line 103 form an NPN bipolar transistor. The P+ silicon or polysilicon for bit line 101 and N+ silicon or polysilicon for source line 103 are connected to a bit line (BL) and a source line (SL), respectively. Also included are a front gate (FG) 104a and back gate (BG) 104b, respectively, and gate dielectric layers 105a and 105b. The two bipolar transistors form a gate-assisted thyristor cell, as shown in the circuit diagram of FIG. 14A.

FIG. 13B shows the cell structure of FIG. 13A with the front gate 104a and the gate dielectric layer 105a removed. The P− floating body 102 comprises a donut shape as shown.

FIG. 13C shows another embodiment of a 3D thyristor cell structure according to the invention. This embodiment is similar to the embodiment shown in FIG. 13A except that the front gate 104a and back gate 104b are replaced by insulating layers 113a and 113b. This forms a non-gate-assisted thyristor cell as shown in the circuit diagram shown in FIG. 14B.

It should be noted that although the embodiments shown in FIGS. 13A-C show that the shape for the bit line 101 and body 102 is circular, it is obvious that they may have any other shapes, such as square, rectangle, triangle, hexagon, etc. Also, in another embodiment, the materials of 101, 112, 102, and 103 can be reversed to be N+, P−, N−, and P+, respectively. Moreover, similar to FIGS. 5A-D, the cell may have a metal core in the center of bit line 101 to reduce bit line resistance. These variations shall remain in the scope of the invention.

FIG. 14C shows a current to voltage (I-V) curve of the thyristor cell shown in FIG. 13A. When a voltage difference from the BL to WL exceeds a ‘trigger voltage’ 1401, the two bipolar transistors are turned on and cause latch-up to occur. This causes the thyristor cell to conduct current from the BL to the WL, thus it becomes an ‘on-cell’. When the voltage difference from the BL to WL is lowered or reversed to reduce the current to below a ‘holding current’ 1402, the transistors are turned off, thus the cell becomes an ‘off-cell’. By using this process, the thyristor cell functions as a memory cell to store data. Because the cell can be switched between on-cell and off-cell in very short time, such as in the nanosecond range, the cell may be used for high-speed memory, such as for replacement of DRAM or SRAM.

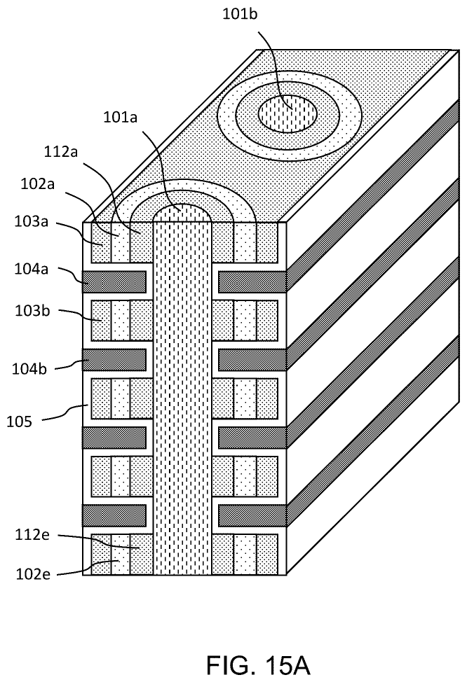

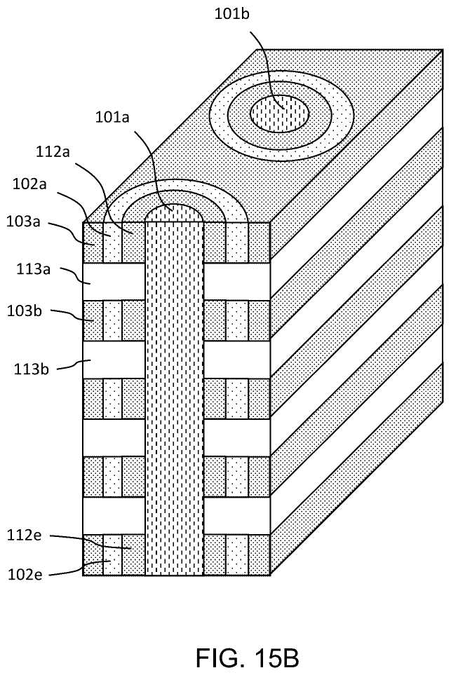

FIG. 15A shows an embodiment of a 3D array structure based on the cell structure shown in FIG. 13A. The 3D array structure shown in FIG. 15A includes P+ silicon or polysilicon bit lines 101a to 101c, N− silicon or polysilicon 112a to 112e, P− silicon or polysilicon 102a to 102e, and N+ silicon or polysilicon word lines 103a and 103b. Also included are front 104a and back 104b gates, and gate dielectric layer 105.

FIG. 15B shows an embodiment of a 3D array structure based on the cell structure shown in FIG. 13C. This embodiment is similar to the embodiment shown in FIG. 15A except that the word line layers 104a and 104b, etc. are replaced with insulating layers 113a and 113b, etc. The 3D array structures shown in FIGS. 15A-B are formed by using similar process steps as shown in FIGS. 4A-F.

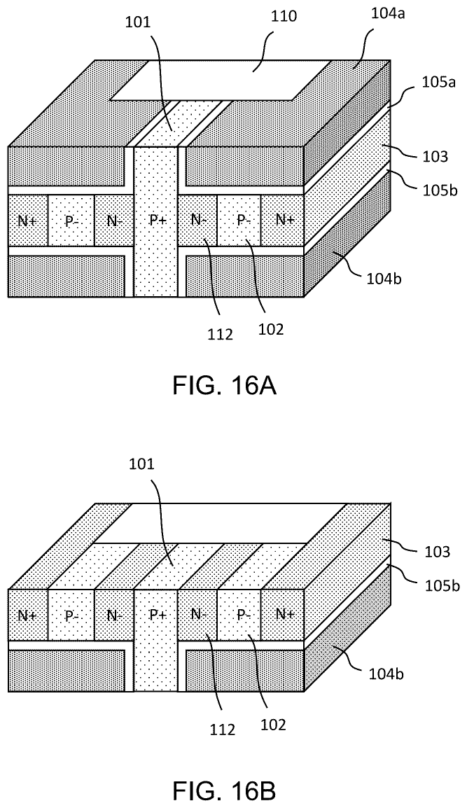

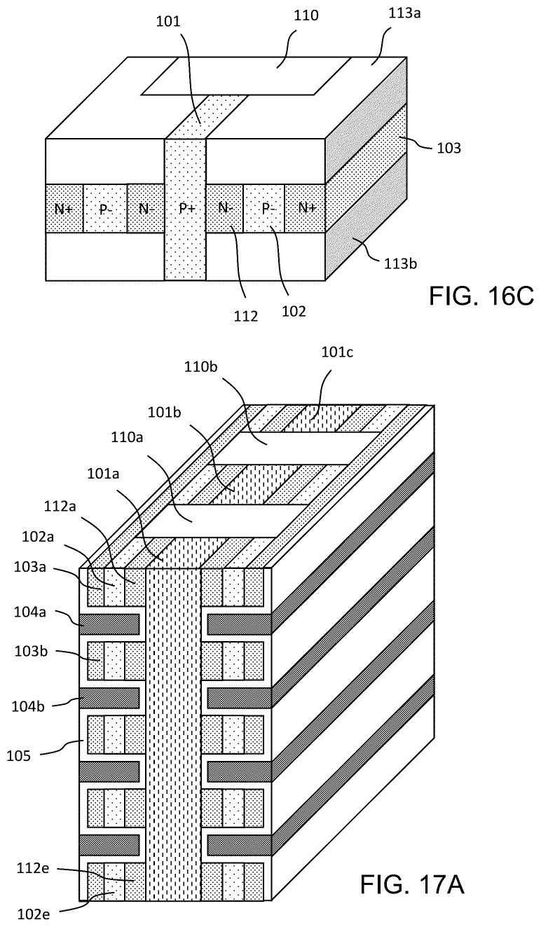

FIG. 16A shows another embodiment of a thyristor cell structure according to the invention. FIG. 16B shows the cell structure shown in FIG. 16A with the front gate 104a and gate dielectric layer 105a removed.

The embodiment shown in FIG. 16A is similar to the embodiment shown in FIG. 13A except that the cell is divided into two cells by an insulating layer 110, such as an oxide material. In this configuration, the memory array capacity is doubled. Similar to FIG. 6C and FIG. 6D, the shapes of the material 101, 112, and 102 can be circular or any other suitable shapes.

FIG. 16C shows another embodiment of a thyristor cell structure according to the invention. This embodiment is similar to the embodiment shown in FIG. 16A except that the front gate 104a and back gate 104b are replaced by insulating layers 113a and 113b. This forms a non-gate-assisted thyristor cell as shown in FIG. 14B.

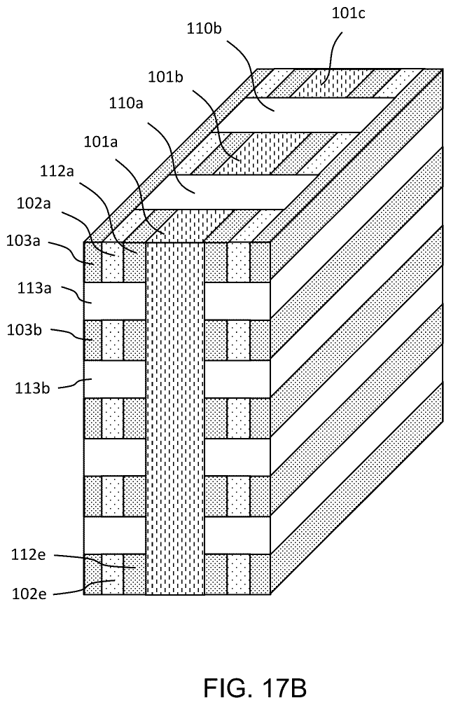

FIG. 17A shows an embodiment of a 3D array structure based on the cell structure shown in FIG. 16A. The embodiment shown in FIG. 17A comprises P+ silicon or polysilicon bit lines 101a to 101c, etc., N− silicon or polysilicon 112a to 112e, etc., P− silicon or polysilicon floating bodies 102a to 102e, etc. N+ silicon or polysilicon source lines 103a and 103b, etc. Also included are front 104a and back 104b gates, gate dielectric layer 105, and insulating layers 110a and 110b.

FIG. 17B shows an embodiment of a 3D array structure based on the cell structure shown in FIG. 16C. This embodiment is similar to the embodiment shown in FIG. 17A except that the word line layers 104a and 104b, etc. are replaced with insulating layers 113a and 113b, etc. The 3D array structures shown in FIG. 17A and FIG. 17B are formed by using similar process steps to those shown and described with reference to FIGS. 8A-F.

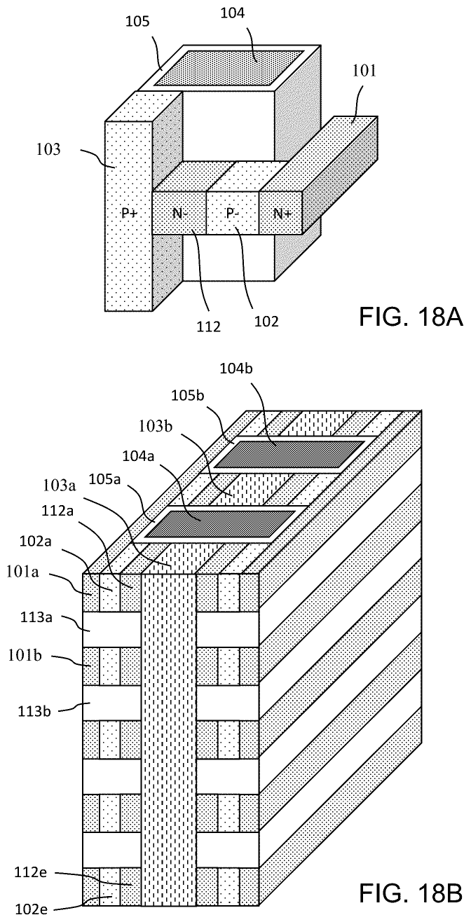

FIG. 18A shows another embodiment of a thyristor cell structure according to the invention. The cell structure shown in FIG. 18A comprises P+ silicon or polysilicon for bit line 101, N− silicon or polysilicon 112, P− silicon or polysilicon 102, and N+ silicon or polysilicon for source line 103. The materials 101 and 103 are connected to a bit line and a source line, respectively. Also shown is a front gate 104 and a gate dielectric layer 105. A back gate is not shown to make it easier to illustrate. In this embodiment, the front gate 104 runs in vertical direction.

FIG. 18B shows an embodiment of a 3D array structure based on the cell structure shown in FIG. 16C. The array structure shown in FIG. 18A comprises P+ silicon or polysilicon bit lines 101a and 101b, etc., N− silicon or polysilicon 112a to 112e, etc., P− silicon or polysilicon 102a to 102e, etc. N+ silicon or polysilicon source lines 103a and 103b, etc., front gate 104a and back gate 104b, gate dielectric layers 105a and 105b, etc., and insulating layers 113a and 113b. This embodiment is formed by using similar process steps as shown and described with respect to FIGS. 10A-D.

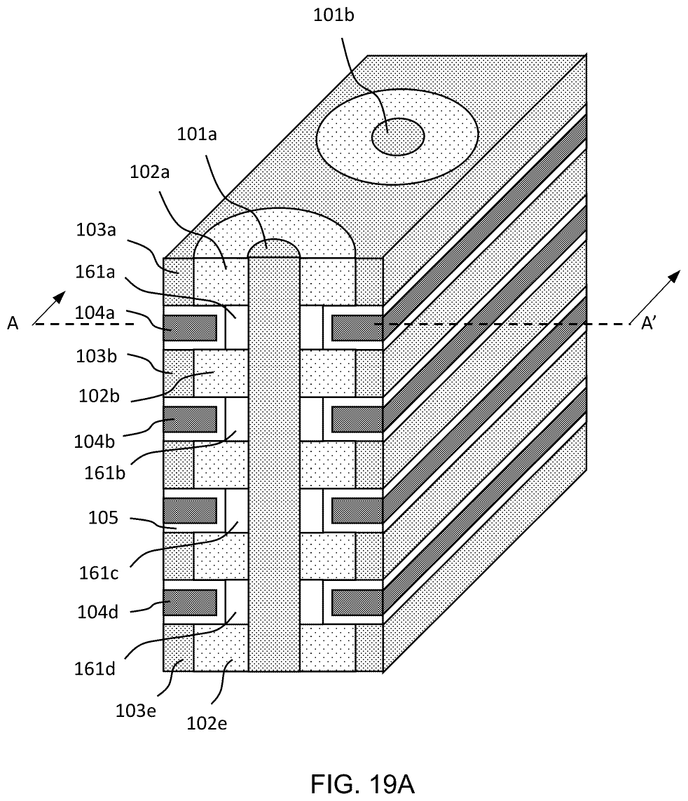

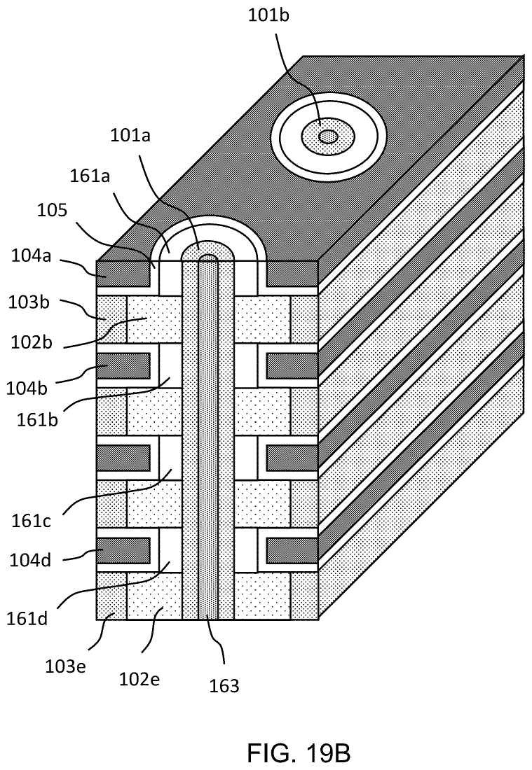

FIG. 19A shows another embodiment of a 3D array structure according to the invention that uses ‘tunnel field-effect transistor (TFET)’ technology. FIG. 19A comprises vertical bit lines 101a and 101b, floating bodies 102a to 102e, and source lines 103a to 103e. In an embodiment, the floating bodies 102a to 102e are formed from an intrinsic semiconductor material, such as silicon.

In an embodiment, the vertical bit lines 101a and 101b and source lines 103a to 103e are formed from P-type or N-type of heavily doped semiconductor material, such as silicon. The vertical bit lines 101a to 101b and the source lines 103a to 103e are material having the opposite type of doping.

In one embodiment, word lines 104a to 104d are formed from conductor material, such as metal or polysilicon. A gate dielectric layer 105 is formed from material, such as gate oxide or high-K material, such as HfO2. Also shown are insulating layers 161a to 161d that are formed from material, such as an oxide or a nitride.

FIG. 19B shows a cross-section of the array structure shown in FIG. 19A that is taken at cross-section indicator A-A′ to reveal the structure of the insulating layer 161a. The structure of the insulating layers 161a to 161d are formed by using an isotropic etching process, such as wet etch, to selectively form recesses through vertical bit line holes, and then forming the insulating layer inside the recesses, as in the process step shown in FIG. 4B.

In another embodiment, a conductor core 163, such as metal or polysilicon, is formed in the center of the vertical bit lines 101a and 101b to reduce the resistance of the vertical bit lines, as shown in FIG. 19B. The conductor core 163 is formed by using a thin-film deposition or a thin-film epitaxial growth process to form a layer of semiconductor for bit line 101a, such as silicon on the sidewall of the vertical hole, and then filling the center of the hole with the conductor core 163.

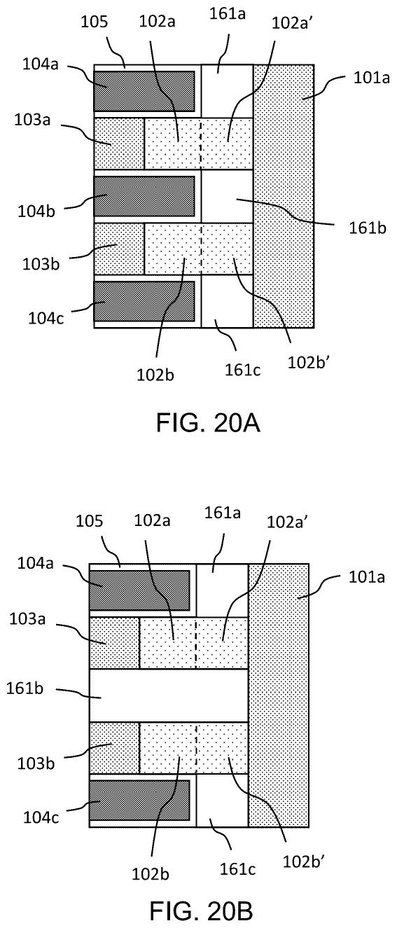

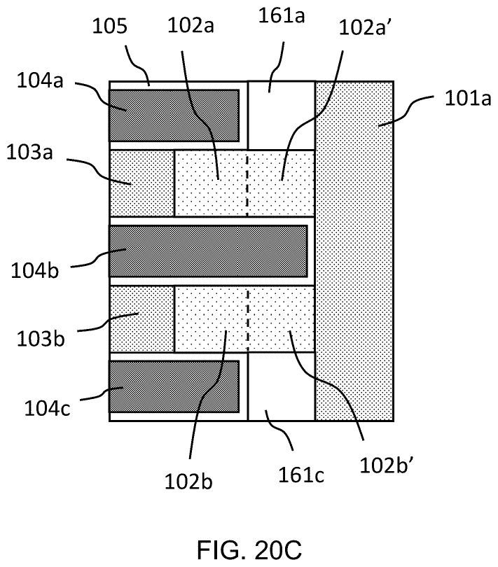

FIG. 20A shows a detailed front view of the 3D array structure shown in FIG. 19A. This view includes vertical bit line 101a, floating bodies 102a, 102a′, 102b, and 102b′, source lines 103a and 103b, word lines 104a to 104c, gate dielectric layer 105, and insulating layers 161a to 161c. It should be noted that the word lines 104a to 104c only partially cover the floating bodies, such as floating bodies 102a and 102b. An electric charge, such as electron holes, can be stored in the portion of the floating bodies 102a and 102b under the word lines 104a to 104c. The number of the stored electron holes can alter the threshold voltage of the cell transistors to represent the data 1 or 0. The portion of the floating bodies 102a′ and 102b′ not being covered by the word lines 104a to 104c form potential wells to isolate the stored electron holes from the bit line 101a.

It should be noticed that the above cell can be operated using dual-gate bias conditions. The even word lines, such as 104a and 104c, are supplied with the front-gate bias condition, and the odd word lines, such as 104b, are supplied with the back-gate bias condition.

In one embodiment, the bit line 101a and the source lines 103a and 103b have N-type and P-type of doping, respectively. During read operations, the bit line 101a is supplied with a positive voltage and the source lines 103a and 103b are supplied with a low voltage, such as 0V. This causes the cells to operate in a reverse bias condition between source and drain.

In another embodiment, the bit line 101a and the source lines 103a and 103b have N-type and P-type of doping, respectively. During read and write operations, the bit line 101a are supplied with low voltage, such as 0V, and the source lines 103a and 103b are supplied with a positive voltage. This causes the cells to operate in a forward bias condition between the source and drain. The word lines 104a and 104b provide controllable injection barriers.

In another embodiment, the bit line 101a and the source lines 103a and 103b have P-type and N-type of doping, respectively. During read operations, the bit line 101a is supplied with a positive voltage and the source lines 103a and 103b are supplied with a low voltage, such as 0V. This causes the cells to operate in a forward bias condition between the source and drain. The word lines 104a and 104b provide controllable injection barriers.

FIG. 20B shows another embodiment of the detailed front view of the 3D array structure according to the invention. This embodiment is similar to the one shown in FIG. 20A except that the word line 104b is replaced with an insulating layer 161b. This forms a single-gate cell structure.

FIG. 20C shows another embodiment of the vertical cross section view of the 3D array structure according to the invention. This embodiment is similar to the one shown in FIG. 20A except that the insulating layer 161b shown in FIG. 20A is removed and the odd word lines, such as 104b cover the entire floating bodies 102a and 102a′.

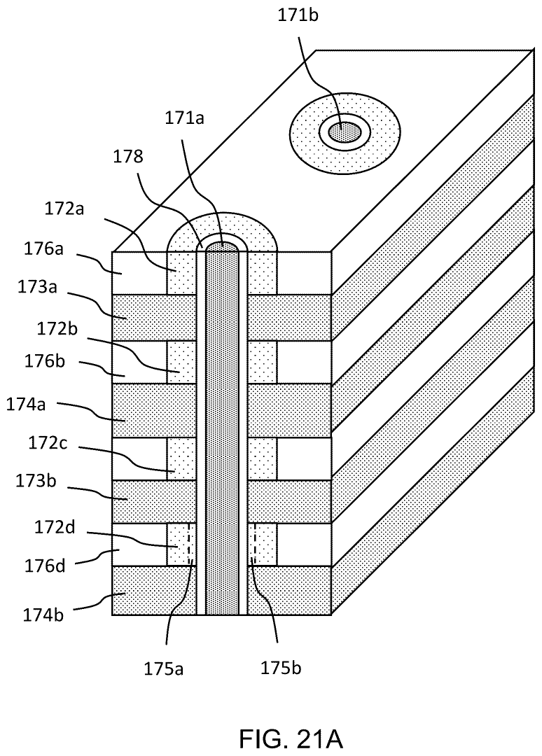

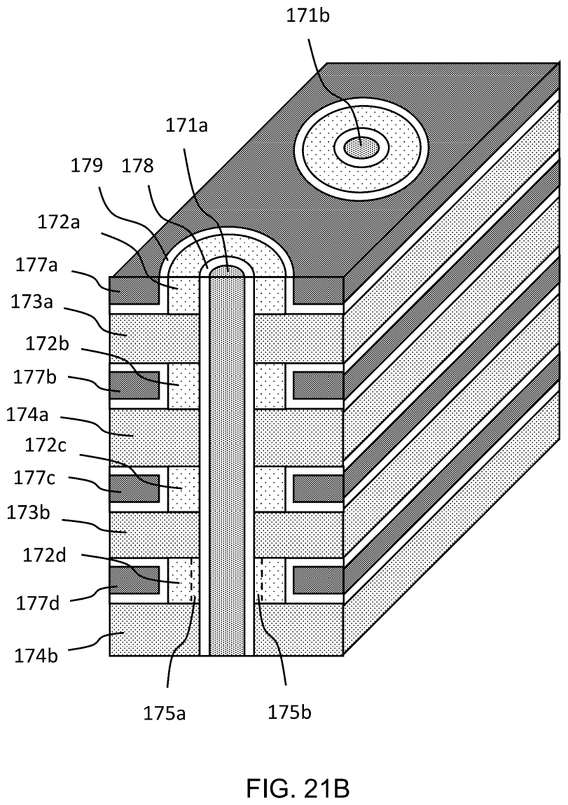

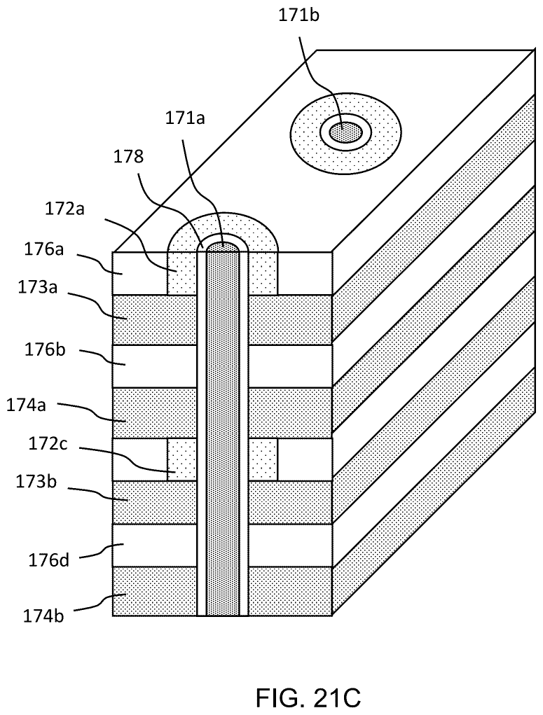

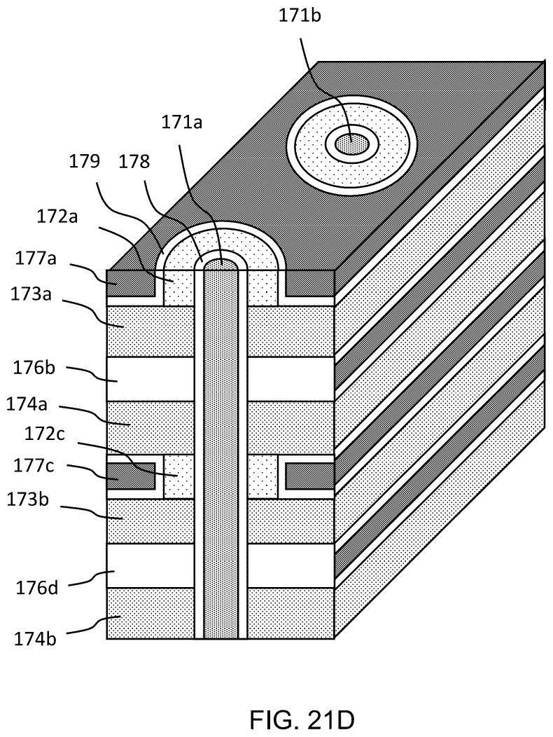

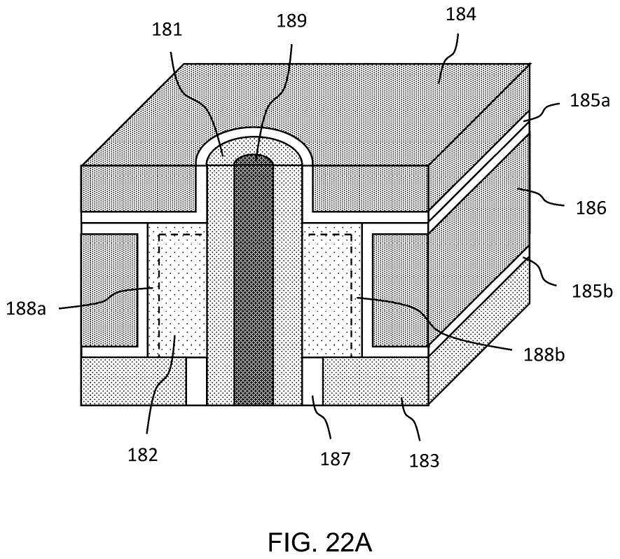

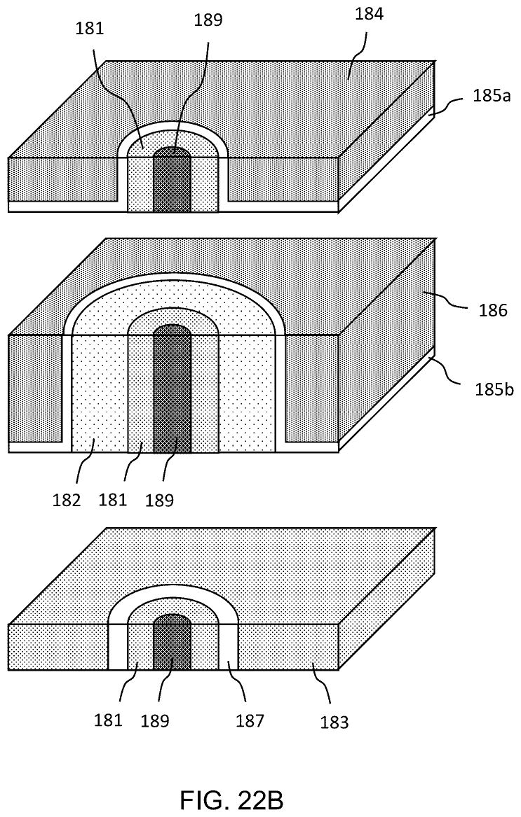

FIG. 21A shows another embodiment of the 3D array structure according to the invention. This embodiment includes vertical word lines 171a and 171b formed of conductor material, such as metal or polysilicon. This embodiment also includes gate dielectric layer 178 made from material, such as gate oxide or high-K material, such as HfO2.

Also shown in FIG. 21A are floating bodies 172a to 172d that are formed by using an isotropic etching process, such as wet etch to selectively form recesses in the insulating layers 176a to 176d through vertical bit line holes, and then forming the silicon layer inside the recesses, as in the process step shown in FIG. 4B.

Also shown in FIG. 21A are bit line layers 173a to 173b and source line layers 174a and 174b. The bit line layers 173a and 173b and the source lines layers 174a and 174b are formed of heavily doped semiconductor, such as silicon. The bit line layers 173a and 173b and the source line layers 174a and 174b have the same type of doping. The floating bodies 172a to 172d are formed of lightly doped semiconductor layers, such as silicon with the opposite type of doping as the bit lines 173a and 173b and the source lines 174a and 174b.

During read operations, the vertical word line 171a is supplied with a read voltage to turn on the vertical channels, such as channels 175a and 175b between the bit lines 173b and the source line 174b to conduct current. Electric charge, such as electron holes, are be stored in the floating bodies 172a to 172d to alter the threshold voltage of the cell transistor to represent data 1 or 0.

FIG. 21B shows another embodiment of the 3D array structure according to the invention. This embodiment is similar to the one shown in FIG. 21A except that the insulating layers 176a to 176d are replaced with conductor layers 177a to 177d, comprising material, such as metal or polysilicon. Also shown is a gate dielectric layer 179 comprising material, such as gate oxide or high-K material, such as HfO2. This forms a dual-gate cell structure which include front gates 171a and 171b and back gates 177a to 177b. During read and write operations, the front gates and back gates are supplied with different bias conditions.

FIG. 21C shows another embodiment of a 3D array structure according to the invention. This embodiment is similar to the embodiment shown in FIG. 21A except that only the even layers of floating bodies 172a and 172c are formed. The odd layers of floating bodies 172b and 172d shown in FIG. 21A are eliminated. For comparison, the structure shown in FIG. 21A shares the bit lines and source lines with adjacent cells. The structure shown in FIG. 21C dedicates one bit line and one source line for each cell.

FIG. 21D shows another embodiment of a 3D array structure according to the invention. This embodiment is similar to the embodiment shown in FIG. 21B except that only the even layers of floating bodies 172a and 172c are formed. The odd layers of floating bodies 172b and 172d shown in FIG. 21A are eliminated. For comparison, the structure shown in FIG. 21B shares the bit lines and source lines with adjacent cells. The structure shown in FIG. 21D dedicates one bit line and one source line for each cell.

FIG. 22A shows another embodiment of a 3D cell structure according to the invention. FIG. 22B shows the cell shown in FIG. 22A separated into three portions (or sections) to show the cell's inner structure. In one embodiment, multiple layers of the cell structure shown in FIG. 22A are stacked to form a high-density cell array.

The materials 181 and 183 are heavily doped semiconductor layers, such as P+ or N+ silicon. The material 181 forms a vertical bit line. The material 183 forms a horizontal source line. The material 182 is a lightly doped semiconductor, such as P− or N− silicon material. The semiconductor layer 182 has the opposite type of doping of the materials 181 and 183. As shown in FIG. 22B, the material 182 forms the floating body of the cell. This forms a floating-body memory cell.

In another embodiment, the material 182 comprises an intrinsic semiconductor, such as silicon. The materials 181 and 183 are heavily doped semiconductor material, such as P+ or N+ silicon material. The materials 181 and 183 have the opposite type of doping. This forms a tunnel field effect transistor (TFET) type of memory cell.

The cell comprises two gates 184 and 186. The gate 184 is connected to a word line. The gate 186 is connected to a read voltage. Gate dielectric layers 185a and 185b comprise gate oxide or high-K material, such as HfO2. Also shown are channel regions 188a and 188b. In one embodiment, the channel length of the gate 186 is longer than that of the gate 184. This reduces the coupling effect of the word line.

Also shown is an insulating layer 187 comprising an oxide to prevent the short of the materials 181 and 183. In one embodiment, a conductor core 189 comprising material, such as a metal, is formed in the center of the vertical bit line 181 to reduce the bit line resistance. The conductor layer 189 can be eliminated without affecting the function of the cell.

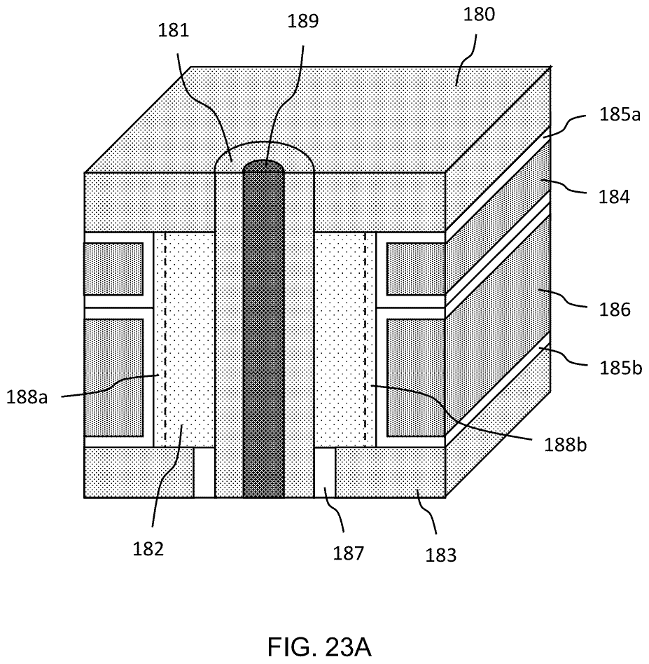

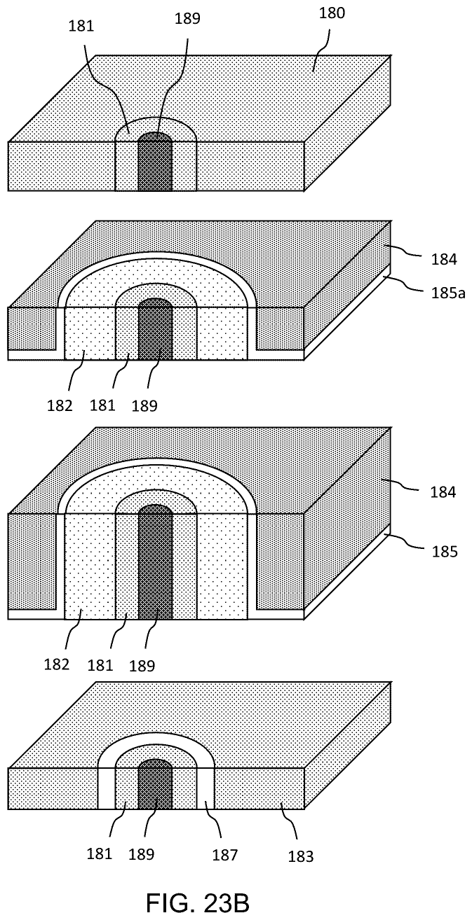

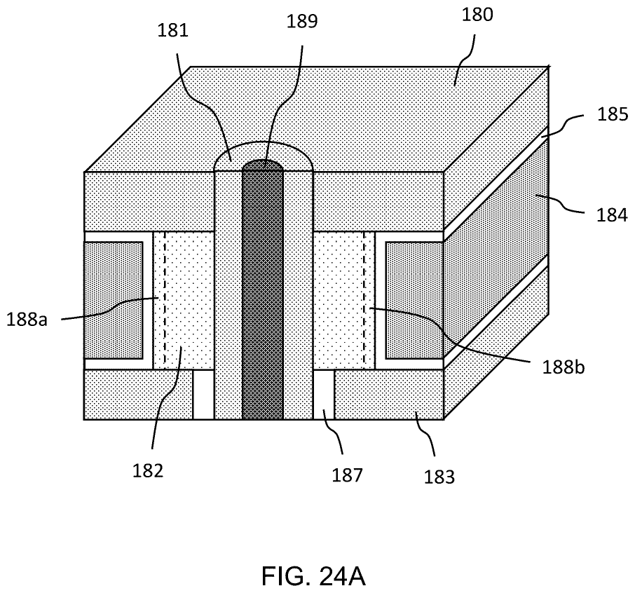

FIG. 23A shows another embodiment of a 3D cell structure according to the invention. FIG. 23B shows the cell shown in FIG. 23A separated into four portions (or sections) to show the cell's inner structure. Multiple layers of the cell structure shown in FIG. 23A are stacked to form a high-density cell array.

The embodiment shown in FIG. 23A is similar to the embodiment shown in FIG. 22A except that an additional layer 180 is added. The layers 180, 181 and 183 are heavily doped semiconductor layers comprising material, such as P+ or N+ silicon. Layer 181 forms a vertical bit line. Layer 183 forms a horizontal source line. The layers 180 and 181 have the same type of doping so that layer 180 becomes an extension of the vertical bit line 181.

The layer 182 is a lightly doped semiconductor, such as P− or N− silicon. The semiconductor layer 182 has the opposite type of doping of the layers 181 and 183. As shown in FIG. 23B, the material 182 forms the floating body of the cell. This results in a floating-body memory cell.

In another embodiment, the material 182 is an intrinsic semiconductor, such as silicon. The material 181 and 183 are heavily doped semiconductors, such as P+ or N+ silicon. The material 181 and 183 have the opposite type of doping. This forms a tunnel field effect transistor (TFET) type of memory cell.

The cell comprises two gates 184 and 186. The gate 184 is connected to a word line. The gate 186 is connected to a read voltage. Gate dielectric layers 185a and 185b comprise material, such as gate oxide or high-K material, such as HfO2. Also shown are channel regions 188a and 188b. In one embodiment, the channel length of the gate 186 is longer than that of the gate 184. This reduces the coupling effect of the word line.

Also shown in an insulating layer 187 comprising material, such as oxide to prevent the short of layers 181 and 183. In one embodiment, a conductor core 189 comprising material, such as metal, is formed in the center of the vertical bit line 181 to reduce the bit line resistance. In one embodiment, the conductor layer 189 can be eliminated without affecting the function of the cell.

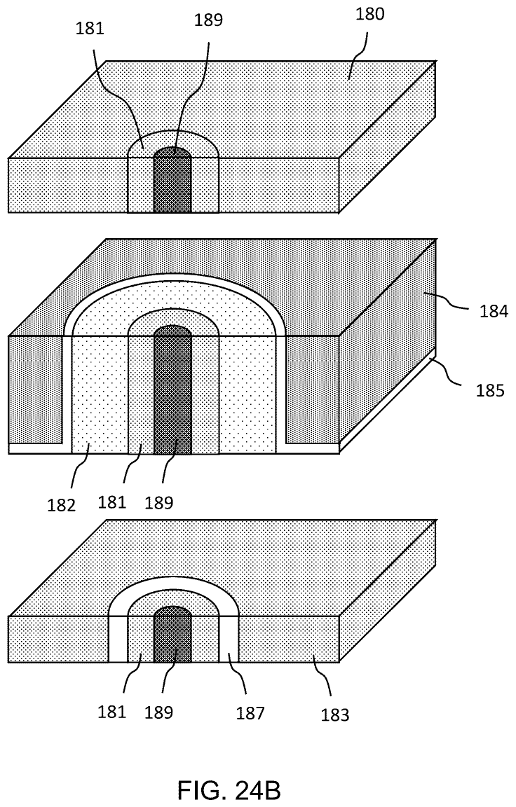

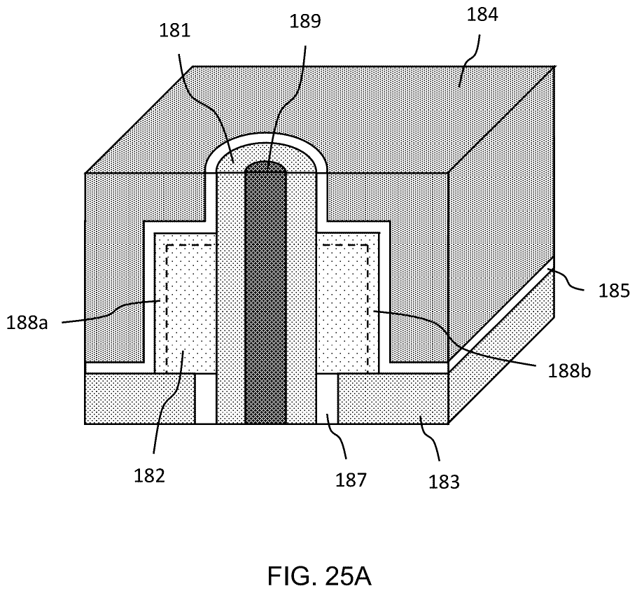

FIG. 24A shows another embodiment of the 3D cell structure according to the invention. FIG. 24B shows the di-section view of the structure shown in FIG. 24A. Multiple layers of the cell structure shown in FIG. 24A are stacked to form a high-density cell array.

The embodiment shown in FIG. 24A is similar to the embodiment shown in FIG. 23A except that the second gate 186 is removed. The materials 180, 181 and 183 are heavily doped semiconductor layers, such as P+ or N+ silicon. The material 181 forms a vertical bit line. The material 183 forms a horizontal source line. The material 180 and 181 have the same type of doping so that the material 180 becomes an extension of the vertical bit line 181.

The material 182 is a lightly doped semiconductor, such as P− or N− silicon. The semiconductor layer 182 has the opposite type of doping of materials 181 and 183. As shown in FIG. 24B, the material 182 forms a floating body of the cell. This results in a floating-body memory cell.

In another embodiment, the material 182 comprises an intrinsic semiconductor, such as silicon. The material 181 and 183 are heavily doped semiconductors, such as P+ or N+ silicon. The materials 181 and 183 have the opposite type of doping. This forms a tunnel field effect transistor (TFET) type of memory cell.

The cell comprises only one gate 184. The gate 184 is connected to a word line. A gate dielectric layer 185 comprises material, such as gate oxide or high-K material, such as HfO2. Also shown are channel regions 188a and 188b.

An insulating layer 187 comprises material, such as oxide to prevent the short of the materials 181 and 183. In one embodiment, a conductor core 189 comprising material, such as metal, is formed in the center of the vertical bit line 181 to reduce the bit line resistance. In one embodiment, the conductor layer 189 is eliminated without affecting the function of the cell.

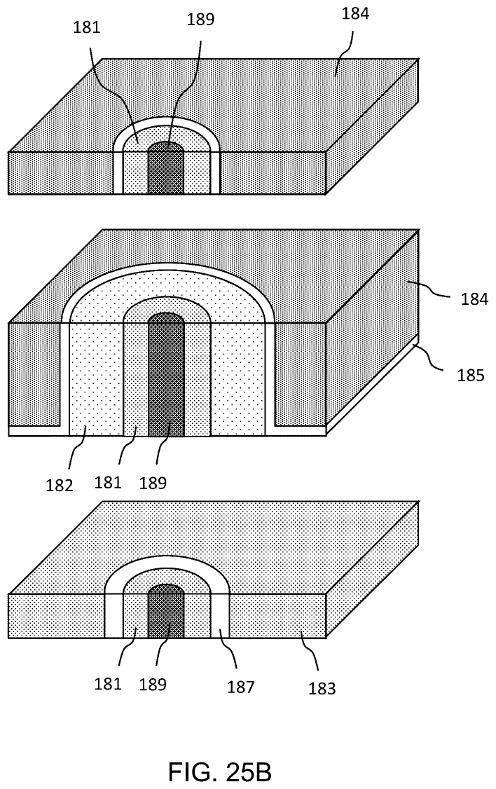

FIG. 25A shows another embodiment of 3D cell structure according to the invention. FIG. 25B shows a di-section view of the structure shown in FIG. 25A. Multiple layers of the cell structure shown in FIG. 25A are stacked to form a high-density cell array.

This embodiment is similar to the embodiment shown in FIG. 24A except that the semiconductor layer extension 180 is removed. The materials 181 and 183 are heavily doped semiconductor layers, comprising P+ or N+ silicon. The material 181 forms a vertical bit line and the material 183 forms a horizontal source line.

The material 182 is a lightly doped semiconductor, comprising material such as P− or N− silicon. The semiconductor layer 182 has the opposite type of doping as the materials 181 and 183. As shown in FIG. 25B, the material 182 forms a floating body of the cell. This results in a floating-body memory cell.

In another embodiment, the material 182 is an intrinsic semiconductor material, such as silicon. The materials 181 and 183 are heavily doped semiconductor materials, such as P+ or N+ silicon. The materials 181 and 183 have the opposite type of doping. This forms a tunnel field effect transistor (TFET) type of memory cell.

The cell comprises only one gate 184. The gate 184 is connected to a word line. Also shown is a gate dielectric layer 185 comprising material, such as gate oxide or high-K material, such as HfO2. Channel regions 188a and 188b are also shown.

An insulating layer 187 comprises material, such as oxide to prevent the short of material 181 and 183. In one embodiment, a conductor core 189 comprising material, such as metal, is formed in the center of the vertical bit line 181 to reduce the bit line resistance. In one embodiment, the conductor layer 189 is eliminated without affecting the function of the cell.

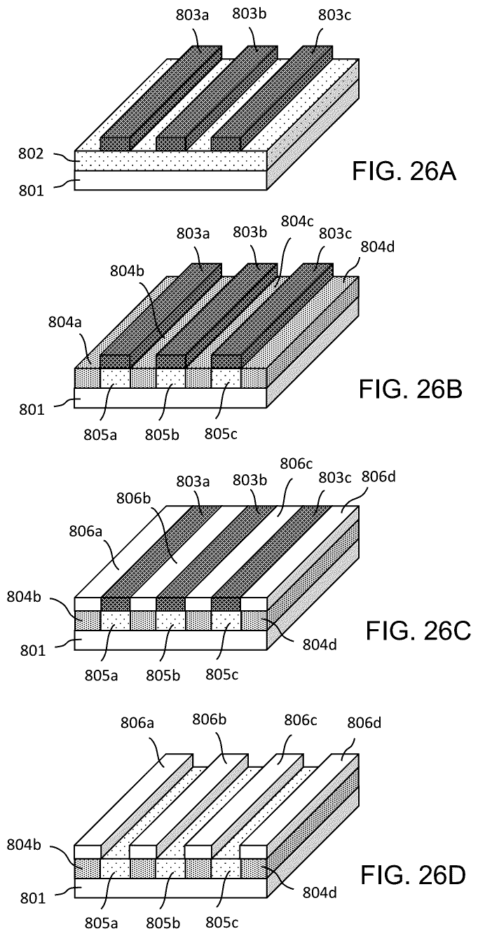

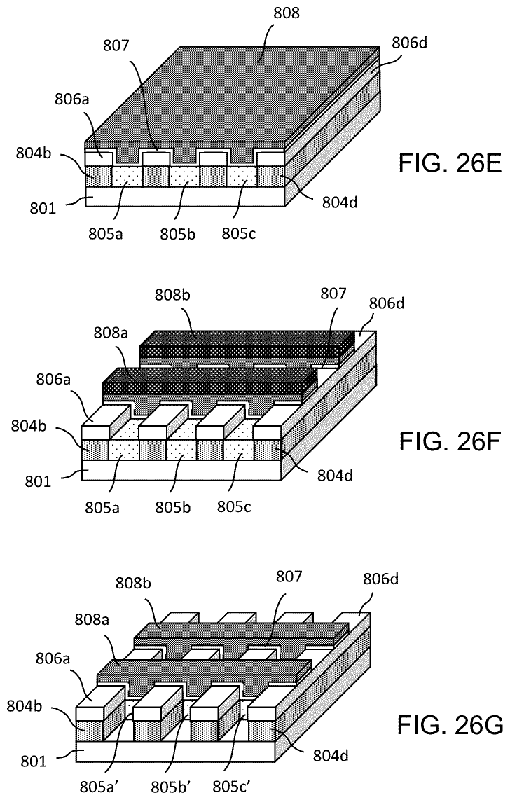

FIGS. 26A-G shows simplified key process steps of another embodiment of a floating body cell “AND” array according to the invention.

FIG. 26A comprises an insulating layer 801, such as oxide, and a P− or N− silicon or polysilicon layer 802. A sacrificial material layer is deposited on top of the silicon or polysilicon layer 802 and pattern-etched to form the pattern features 803a to 803c.

FIG. 26B shows how regions 804a to 804d are implanted or diffused with the opposite type of doping of the silicon or polysilicon layer 802 by using the sacrificial layer features 803a to 803c as masks. This forms N+ or P+ silicon or polysilicon strips 804a to 804d. The even and odd strips are bit lines and source lines, respectively. It should be noted that the junction of the doping shall reach the insulating layer 801, thus it forms isolated P− or N− silicon or polysilicon strips 805a to 805c.

FIG. 26C shows how an insulating layer, such as oxide, is deposited and etched back to form individual strips 806a to 806d. In another embodiment, the insulator strips are formed by using a chemical mechanical planarization (CMP) process to remove the top portion of the insulating layer.

FIG. 26D shows how the sacrificial material layer 803a to 803c are selectively etched.

FIG. 26E shows how a thin gate dielectric layer 807 comprising material, such as oxide, and a gate material layer 808 comprising material, such as metal or polysilicon, are deposited.

FIG. 26F shows how the gate material layer 808 and the gate dielectric layer 807 are pattern-etched to form the word lines. In one embodiment, the materials 808a and 808b are hard masks or photoresists.

FIG. 26G shows how the P− or N− silicon or polysilicon layers 805a to 805c are self-align etched by using the hard masks 808a and 808b. This forms P− or N− silicon or polysilicon floating bodies 805a′ to 805c′.

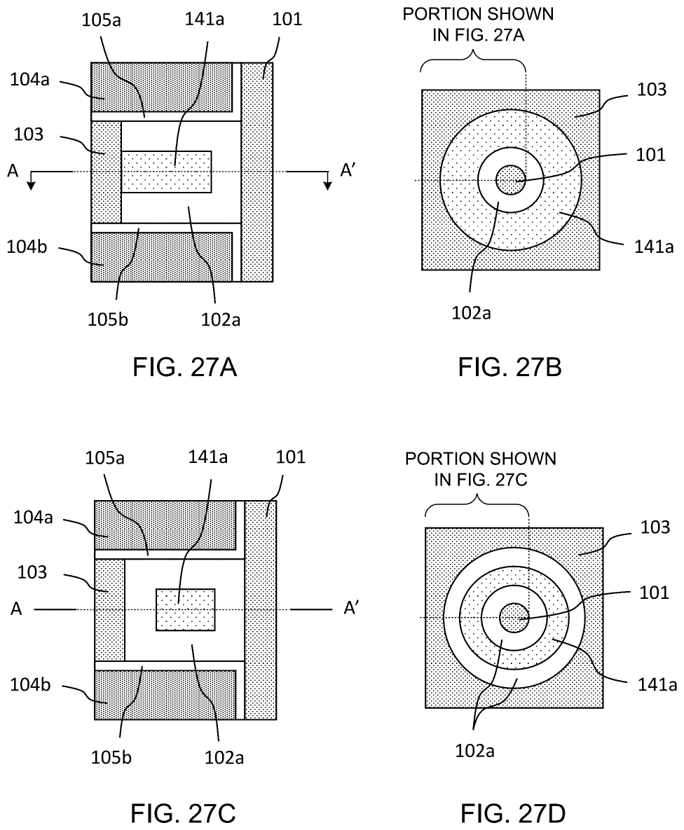

FIG. 27A shows an embodiment of a cell structure in which a second semiconductor material region 141a is formed in the floating body 102a near the source line 103 side. FIG. 27A also shows cross-section indicator line A-A′.

FIG. 27B shows a cross-section view of the cell structure shown in FIG. 27A taken along cross-section indicator line A-A′. It should be noted that many cell embodiments shown herein show only a portion of a symmetrical cell and that corresponding cross-section views show the entire cell around the symmetrical portion.

FIG. 27C shows an embodiment of a cell structure in which a second semiconductor material region 141a is enclosed inside the floating body 102a as shown. FIG. 27C also shows cross-section indicator line A-A′.

FIG. 27D shows a cross-section view of the cell structure shown in FIG. 27C taken alone cross-section indicator line A-A′.

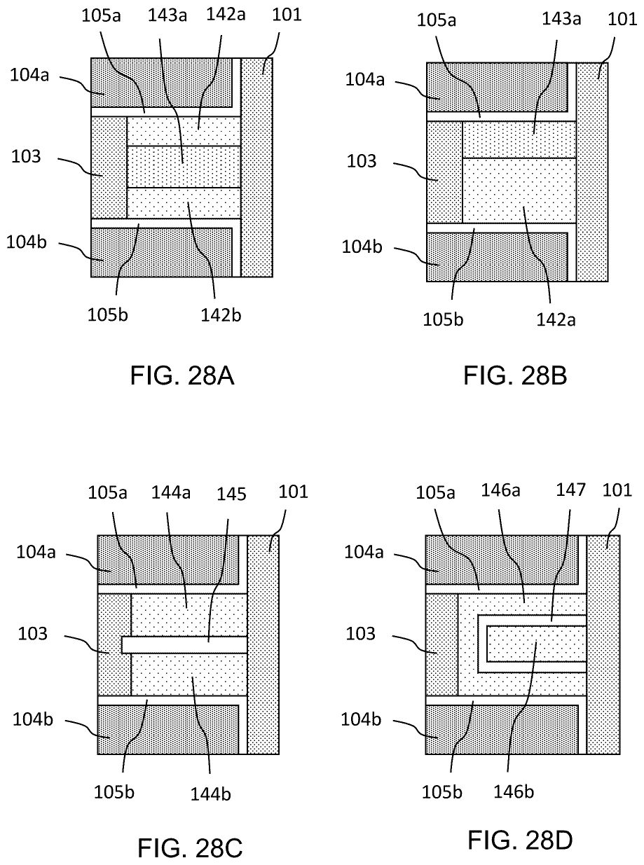

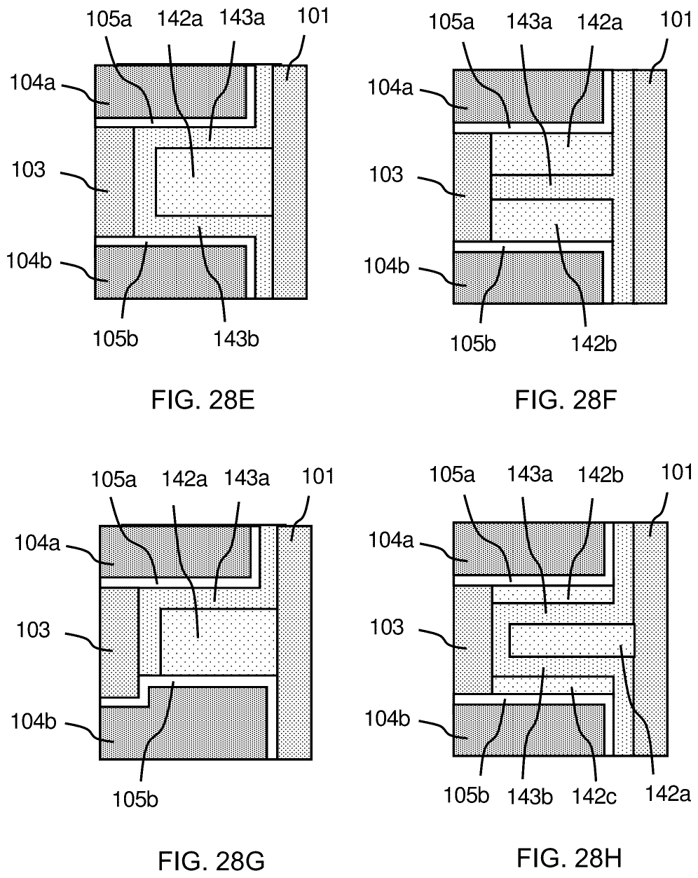

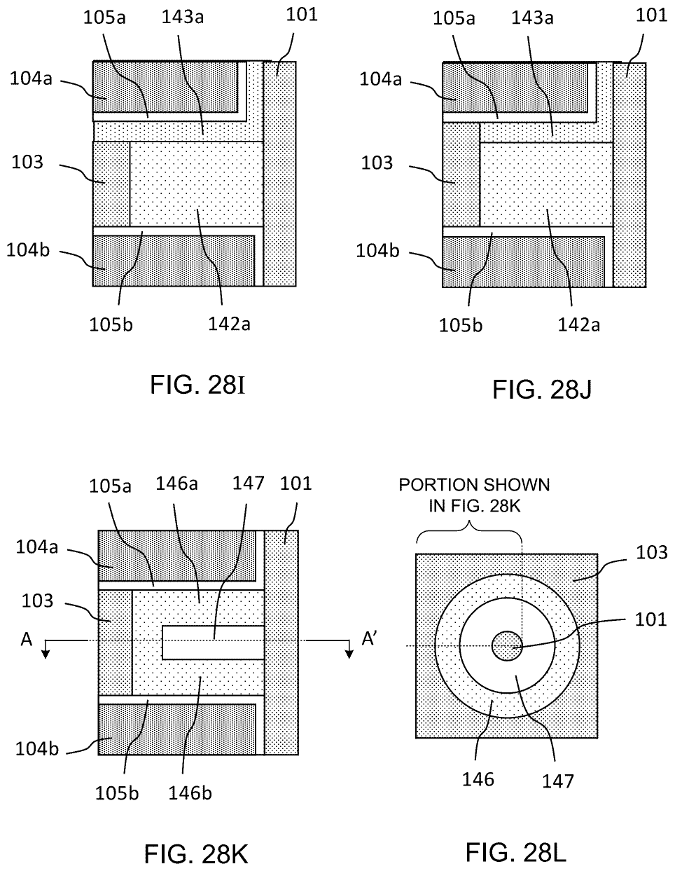

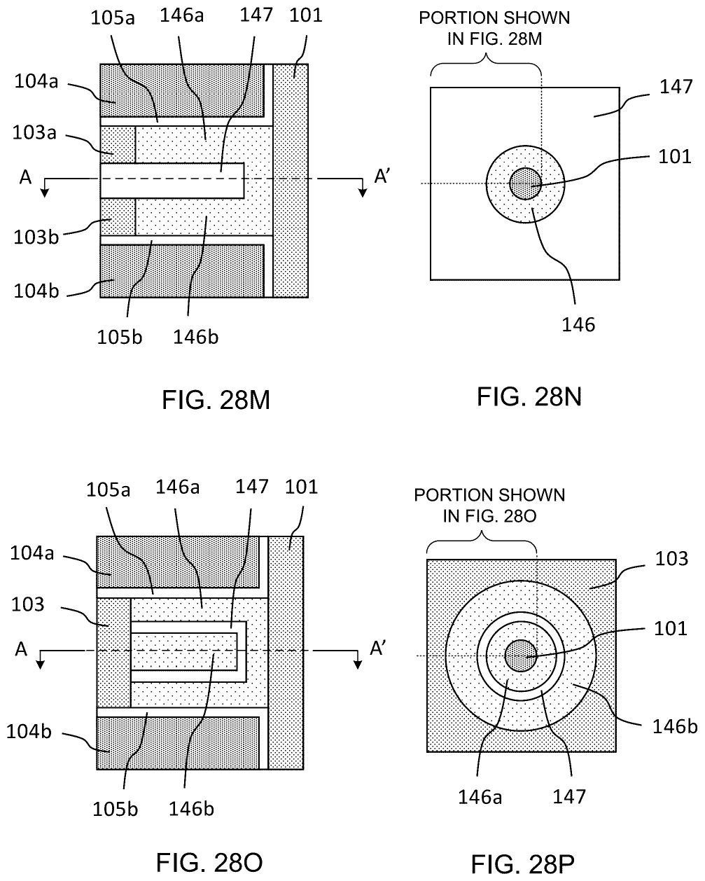

FIGS. 28A-D show embodiments of 3D floating body cell structures according to the invention. The basic structures of these cells are similar to the structures shown in FIGS. 1A-B except that the floating body of the cells comprise multiple semiconductor regions such as silicon or polysilicon regions with different types of doping.

FIG. 28A shows a cell structure in which the floating body comprise two semiconductor regions 142a and 142b having a first type of doping and one semiconductor region 143a having a second type of doping. In one embodiment, the first type of doping is a P− type of lightly doped material and the second type of doping is an N+ type of heavy doping. The regions 142a and 142b with the P− type of doping form potential wells for the storage of electric charge, such as holes. The region 143a with the N+ type of doping forms a channel between an N+ type of bit line 101 and an N+ type of source line 103. The holes stored in the regions 142a and 142b decrease the threshold voltage of the channel region 143a.

In another embodiment, the first type of doping is an N+ type of doping and the second type of doping is a P− type of doping. The regions 142a and 142b with the N+ type of doping form channels between the N+ type of bit line 101 and the N+ type of source line 103. The region 143a with the P− type of doping forms a potential well for the storage of electric charge, such as holes. The holes stored in the region 143a decrease the threshold voltage of the channel regions 142a and 142b.

FIG. 28B shows an embodiment of a cell structure in which the floating body comprises a semiconductor region 142a with a first type of doping and a semiconductor region 143a with a second type of doping. In one embodiment, the first type of doping is a P− type of light doping and the second type of doping is an N+ type of heavy doping. The P− type region 142a forms a potential well for the storage of electric charge, such as holes. The N+ type region 143a forms a channel between the N+ type bit line 101 and the N+ type source line 103. The holes stored in the P− type of region 142a decrease the threshold voltage of the channel region 143a.

FIG. 28C shows an embodiment of a cell structure in which the floating body comprises multiple semiconductor regions, such as regions 144a and 144b. The regions 144a and 144b are isolated by an insulting layer 145 comprising material such as oxide material. In one embodiment, the semiconductor regions 144a and 144b same type of doping. For example, in one embodiment, the semiconductor regions 144a and 144b have a P− type of light doping. The region 144a forms a channel under the front gate 104a. The region 144b is coupled to the back gate 104b and forms a potential well to store electric charge, such as holes. The back gate 104b can be supplied with a negative voltage to attract the holes. The holes stored in the region 144b decrease the threshold voltage of the channel region 144a.

In another embodiment, the semiconductor regions 144a and 144b may have the opposite type of doping. For example, in one embodiment, the semiconductor regions 144a and 144b have N+ type and P− type of doping, respectively. The N+ type region 144a forms a channel under the front gate 104a. The region 144b coupled to the back gate 104b forms a potential well to store electric charge, such as holes. The back gate 104b can be supplied with a negative voltage to attract the holes. The holes stored in the region 144b decrease the threshold voltage of the channel region 144a.

FIG. 28D shows an embodiment of a cell structure in which the floating body comprises multiple semiconductor regions, such as regions 146a and 146b. In one embodiment, the semiconductor region 146b is formed as a pocket shape on the bit line 101 side of the cell structure. The regions 146a and 146b are isolated by an insulting layer 147 comprising material such as oxide material. In one embodiment, the semiconductor regions 146a and 146b have same type of doping. For example, in one embodiment, the semiconductor regions 146a and 146b have P− type of light doping. The region 146a forms a channel under the front gate 104a. The region 146b form a potential well to store the electric charge, such as holes. The holes stored in the region 146b decrease the threshold voltage of the channel region 146a.

FIG. 28E shows an embodiment of a cell structure in which the floating body comprises multiple semiconductor regions, such as regions 142a, 143a, and 143b. The regions 143a and 143b are formed as a semiconductor layer. In one embodiment, the semiconductor regions 143a and 143b have the opposite type of doping from the semiconductor region 142a. For example, in one embodiment, the semiconductor regions 143a and 143b have N+ type of heavy doping and the region 142a has P− type of light doping. The regions 143a and 143b form a channel coupled to the front gate 104a and the back gate 104b. The region 142a forms a potential well to store electric charge, such as holes. The holes stored in the region 142a decrease the threshold voltage of the channel regions 143a and 143b.

FIG. 28F shows an embodiment of a cell structure in which the floating body comprises multiple semiconductor regions, such as regions 142a, 142b, and 143a. In one embodiment, the semiconductor regions 142a and 142b have the opposite type of doping from the semiconductor region 143a. For example, in one embodiment, the semiconductor regions 142a and 142b have P− type of light doping. The region 143a has N+ type of heavy doping. The regions 142a and 142b are formed by using a diffusion process to implant P-type of dopants into the N-type of floating body. The region 143a forms a channel between the bit line 101 and the source line 103. The regions 142a and 142b form potential wells to store electric charge, such as holes. The holes stored in the regions 142a and 142b decrease the threshold voltage of the channel region 143a.

FIG. 28G shows an embodiment of a cell structure. This embodiment is similar to the embodiment shown in FIG. 28E except that the channel 143b is etched by using an isotropic etching process, such as wet etching through the space occupied by the back gate 104b before the back gate 104b and the gate dielectric layer 105b are formed. For this embodiment, the front gate 104a is used in read operations because it is coupled to the channel region 143a. The back gate 104b is used in write operations because it is coupled to the hole storage region 142a.

FIG. 28H shows an embodiment of a cell structure. This embodiment is similar to the embodiment shown in FIG. 28E except that additional semiconductor regions 142b and 142c are formed under the gates 104a and 104b. In one embodiment, the semiconductor regions 142b and 142c have the same type of doping as the semiconductor region 142a. In one embodiment, the semiconductor regions 142a, 142b, and 142c have the opposite type of doping from the semiconductor channel regions 143a and 143b. For example, the semiconductor regions 142a, 142b, and 142c have P− type of light doping and the regions 143a and 143b may have N+ type of heavy doping.

In one embodiment, the regions 142b and 142c are formed by using a diffusion process to implant P− type of dopants into the N− type of floating body. The regions 143a and 143b form channels between the bit line 101 and the source line 103. The regions 142a, 142b, and 142c form potential wells to store electric charge, such as holes. The holes stored in the regions 142a, 142b, and 142c decrease the threshold voltage of the channel regions 143a and 143b.

FIG. 28I shows an embodiment of a cell structure. This embodiment is similar to the embodiment shown in FIG. 28B except that the semiconductor region 143a is formed by using a thin-film deposition process to deposit a semiconductor layer on the surface of the space occupied by the front gate 104a before the front gate 104a and the gate dielectric layer 105a are formed. In one embodiment, the semiconductor region 143a has the opposite type of doping from the semiconductor region 142a. For example, in on embodiment, the semiconductor region 142a has N+ type of heavy doping and the region 142a has P− type of light doping. The region 143a forms a channel under the front gate 104a and the region 142a forms a potential well to store electric charge, such as holes. The holes stored in the region 142a decrease the threshold voltage of the channel region 143a.

FIG. 28J shows another embodiment of the cell structure. This embodiment is similar to the embodiment shown in FIG. 28I except that the semiconductor region 143a is formed by using a diffusion process to implant the opposite type of heavy dopants, such as N+ type of dopants, into the P− type of floating body 142a.

FIG. 28K shows an embodiment of a cell structure. This embodiment is similar to the embodiment shown in FIG. 28C except that insulating layer 147 is formed in the floating body 102 near the bit line 101 side. The insulting layer 147 divides the floating body into two regions 146a and 146b. During read operations, the front gate 104a is supplied with a read voltage to turn on a channel in the region 146a. During hold operations, the back gate 146b is supplied with a negative voltage to attract holes in the region 146b for storage. The insulating layer 147 prevents the recombination of the electrons flowing though the channel in the region 146a with the holes stored in the region 146b. This increases the data retention time of the cell. FIG. 28K also shows a cross-section indicator line A-A′.

FIG. 28L shows a cross-section view of the cell structure shown in FIG. 28K taken along the cross-section indicator line A-A′.

FIG. 28M shows an embodiment of a cell structure. This embodiment is similar to the embodiment shown in FIG. 28K except that insulating layer 147 is located in the floating body 102 near the source line 103 side. The insulting layer 147 divides the floating body into two regions 146a and 146b. During read operations, the front gate 104a is supplied with a read voltage to turn on a channel in the region 146a. During hold operations, the back gate 146b is supplied with a negative voltage to attract holes in the region 146b for storage. The insulating layer 147 prevents the recombination of the electrons flowing though the channel in the region 146a with the holes stored in the region 146b. This increases the data retention time of the cell. FIG. 28M also shows cross-section indicator line A-A′.

FIG. 28N shows a cross-section view of the cell structure shown in FIG. 28M taken along cross-section indicator line A-A′.

FIG. 28O shows an embodiment of a cell structure. This embodiment is similar to the embodiment shown in FIG. 28D except that the second semiconductor region 146b is located near the source line 103 side. The regions 146a and 146b are isolated by an insulting layer 147 comprising material such as oxide material. In one embodiment, the semiconductor regions 146a and 146b have same type of doping. For example, in on embodiment, the semiconductor regions 146a and 146b have P− type of light doping. The region 146a forms a channel under the front gate 104a. The region 146b forms a potential well to store the electric charge such as holes. The holes stored in the region 146b decrease the threshold voltage of the channel region 146a. FIG. 28O also shows cross-section indicator line A-A′.

FIG. 28P shows a cross-section view of the cell shown in FIG. 28O taken along the cross-section indicator line A-A′.

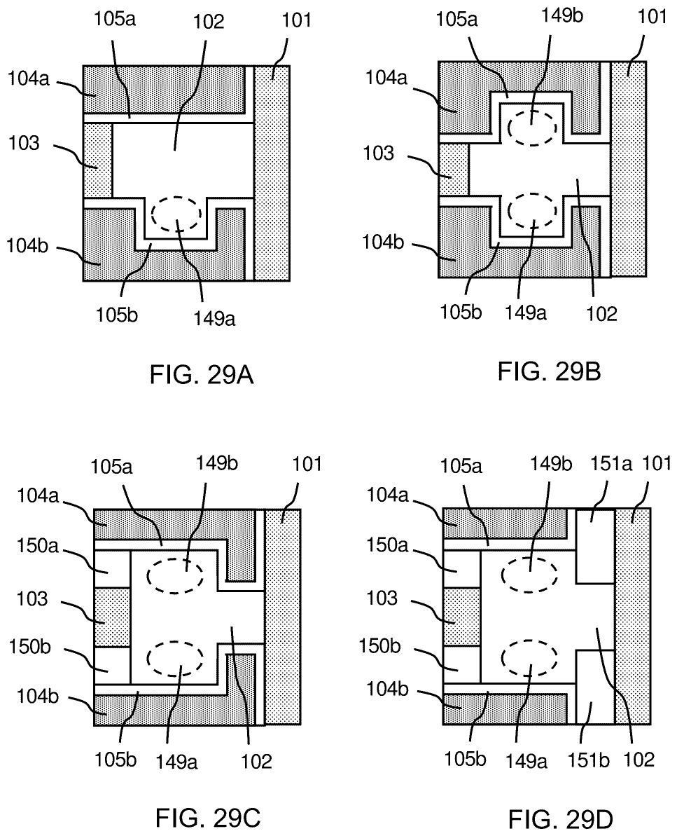

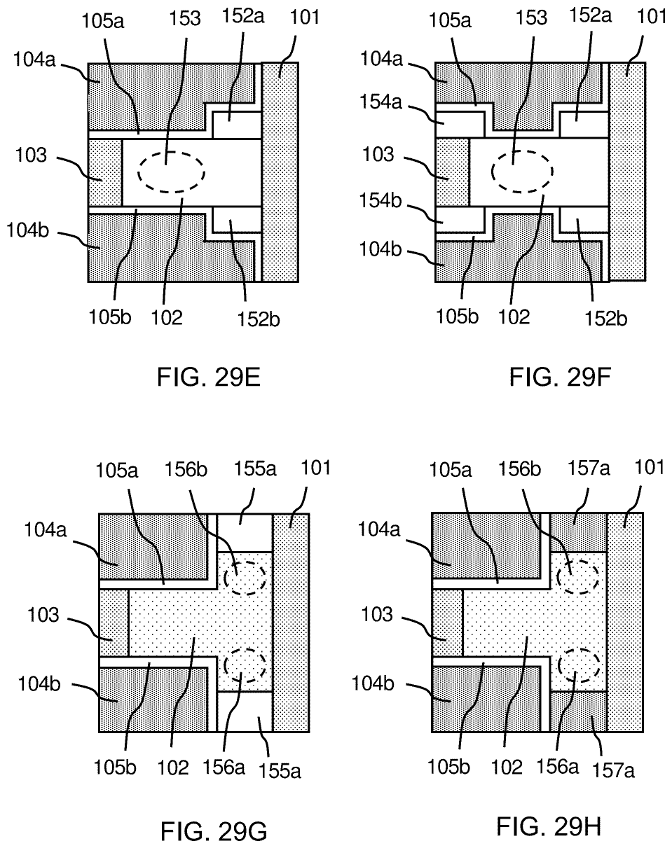

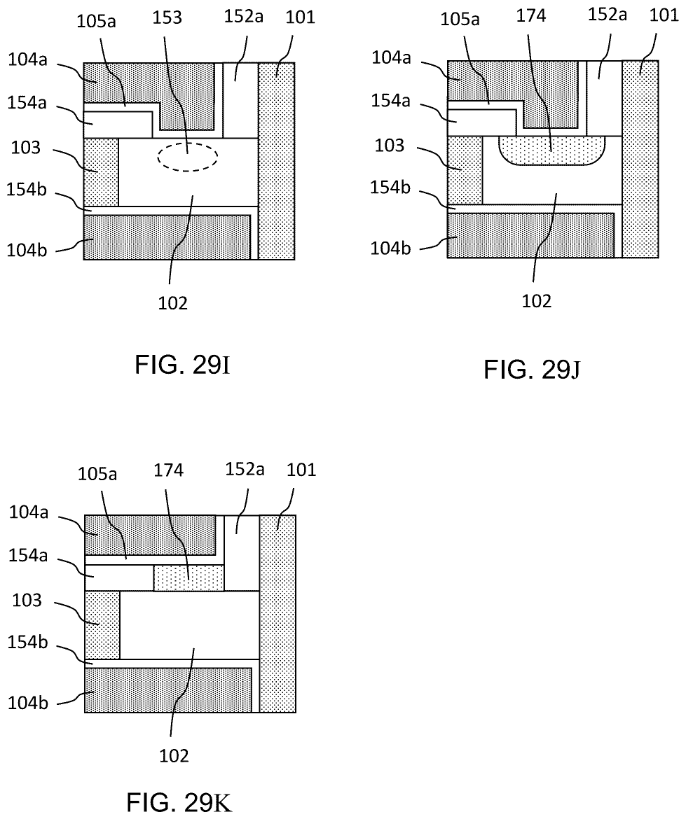

FIGS. 29A-K show embodiments of 3D floating body cell structures according to the invention. The basic structures of these cells are similar to the embodiments shown in FIGS. 1A-B except that the cell structures are formed in specific shapes or sizes or have special structures to create physical barriers to prevent holes stored in the cell from escaping. These configurations enhance the data retention time of the cell.

In one embodiment shown in FIG. 29A, the back gate 104b has a recess area 149a for the storage of the electric charge such as holes. The back gate 104b is supplied with a negative voltage to attract holes in the recess area 149a to enhance the data retention time. The holes stored in the recess area 149a are isolated from the junctions of the bit line 101 and source line 103. This configuration reduces the possibility of the holes escaping from the recess area 149a due to bias conditions applied to the bit line 101 and source line 103 during read operations, which further increases the data retention time of the cell.

FIG. 29B shows an embodiment of a cell structure that has recess areas 149a and 149b in both the front gate 104a and back gate 104b, respectively. This configuration allows electric charges, such as holes, to be stored in the recess areas 149a and 149b.

FIG. 29C shows an embodiment of a cell structure. This cell structure is similar to the embodiment shown in FIG. 29B except that additional insulators 150a and 150b comprising material such as oxide or nitride material are formed in the source line 103 side of the cell as shown. The insulators 150a and 150b form physical barriers to prevent holes stored in the recess areas 149a and 149b from escaping to the source line 103 when the bias condition of the read operation is applied to the source line 103.

FIG. 29D shows an embodiment of a cell structure. This cell structure is similar to the embodiment shown in FIG. 29C except that additional insulators 151a and 151b comprising material such as oxide or nitride material are formed on the bit line 101 side of the cell as shown. The insulators 151a and 151b form physical barriers to prevent holes stored in the areas 149a and 149b from escaping to the bit line 101 when the bias conditions of the read operation are applied to the bit line 101.

FIG. 29E shows an embodiment of a cell structure. This cell structure is similar to the embodiment shown in FIGS. 1A-B except that additional insulators 152a and 152b comprising material such as oxide or nitride material are formed on the bit line 101 side of the cell as shown. The insulators 152a and 152b form physical barriers to prevent holes stored in the areas 153 from escaping to the bit line 101 when the bias conditions of the read operations are applied to the bit line 101.

FIG. 29F shows an embodiment of a cell structure. This cell structure is similar to the embodiment shown in FIG. 21E except that additional insulators 154a and 154b comprising material such as oxide or nitride material are formed on the source line 103 side of the cell as shown. The insulators 154a and 154b form physical barriers to prevent holes stored in the areas 153 from escaping to the source line 103 when the bias conditions of read operations are applied to the source line 103.

FIG. 29G shows an embodiment of a cell structure. This cell structure is similar to the structure shown in FIGS. 1A-B except that additional insulators 155a and 155b comprising material such as oxide material are formed on the bit line 101 side of the cell as shown. This configuration forms recess areas 156a and 156b for the storage of the electric charge such as holes. During hold operations, the front gate 104a and back gate 104b are supplied with negative voltages to attract holes stored in the recess areas 156a and 156b to enhance the data retention time of the cell.

FIG. 29H shows an embodiment of a cell structure. This cell structure is similar to the embodiment shown in FIG. 29G except that charge-trapping layers 157a and 157b comprising material such nitride material are formed on the bit line 101 side of the cell as shown. This configuration forms recess areas 156a and 156b for the storage of the electric charge such as holes. The charge-trapping layers 157a and 157b trap negative electric charge such as electrons. The electrons trapped in the charge-trapping layers 157a and 157b attract holes in the recess areas 156a and 156b. This configuration enhances the data retention time of the cell.

FIG. 29I shows an embodiment of a cell structure. This cell structure is similar to the embodiment shown in FIG. 29F except that the additional insulators 152a and 154a are formed near the front gate 104a. The insulators 152a and 154a form physical barriers to further prevent holes stored in the areas 153 under the front gate 104a from escaping to the bit line 101 and the source line 103. Therefore, during hold operations, the front gate 104a is supplied with negative voltage to attract holes stored in the area 153 to increase the data retention time. During read operations, the back gate 104b is supplied with a read voltage to perform the read operation.

FIG. 29J shows an embodiment of a cell structure. This cell structure is similar to the embodiment shown in FIG. 29I except that a semiconductor region 174 is formed under the front gate 104a as shown. The semiconductor layer 174 is formed of different material from the floating body 102. In one embodiment, the floating body 102 is formed of silicon Si or polysilicon material, and the semiconductor region 174 is formed of silicon germanium SiGe or silicon carbide SiC material. This configuration forms a heterostructure junction between the two materials Si and SiGe or SiC and forms a quantum well inside the SiGe or SiC material to store electric charge such as holes. This configuration increases the data retention time of the cell.

FIG. 29K shows an embodiment of a cell structure. This cell structure is similar to the embodiment shown in FIG. 29J except that the semiconductor region 174 is formed at different locations and shapes. In FIG. 29J, the semiconductor region 174 is formed inside the floating body 102. In FIG. 29K, the semiconductor region 174 is formed outside the floating body 102 as shown.

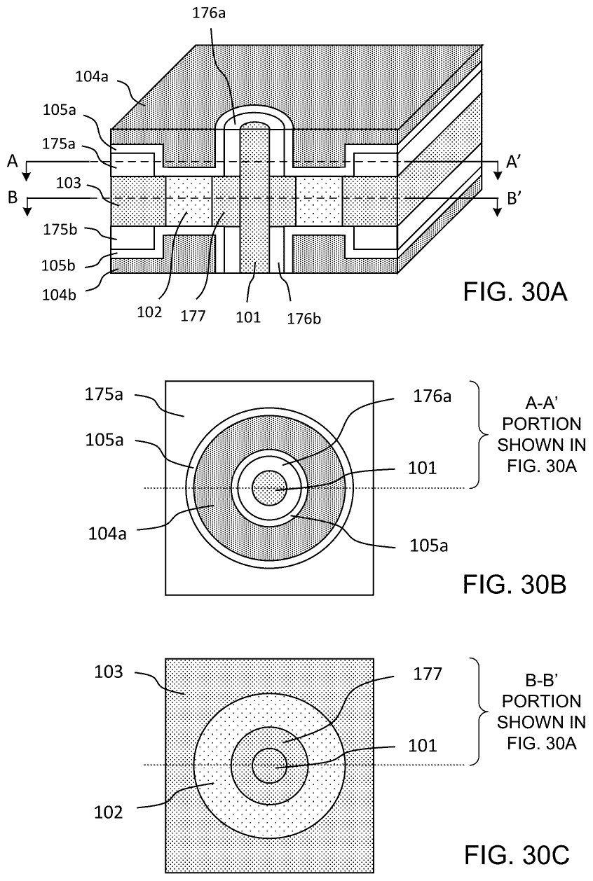

FIGS. 30A-C shows embodiments of cell structures according to the invention. These embodiments are similar to the embodiments shown in FIGS. 1A-B except that additional insulating layers 175a, 175b, 176a, and 176b comprising material such as oxide or nitride material are added.

FIG. 30A shows insulating layers 175a and 175b that reduce the parasitic capacitance between the gates 104a and 104b and the source line 103. The insulating layers 176a and 176b reduce the parasitic capacitance between the gates 104a and 104b and the bit line 101. This configuration reduces the RC delay of the gates 104a and 104b. It also reduces the coupling noise from the gates 104a and 104b to the bit line 101 and the source line 103.

A drain region 177 formed of semiconductor material such as silicon or polysilicon material is formed to avoid a gap between the gates 104a and 104b and the bit line 101 caused by the insulating layers 176a and 176b. The drain region 177 is doped with the opposite type of dopants from the floating body 102. The drain region 177 is formed by using silicon epitaxial growth, a polysilicon deposition process, or using plasma doping or gas-phase doping to form a diffusion region in the floating body 102. In another embodiment, the drain region 177 is formed as an extension of the bit line 101.

Although the cell embodiment shown in FIG. 30A has four insulating layers 175a, 175b, 176a, and 176b, in other embodiments, the cell may have only the insulating layers 175a and 175b, or only the insulating layers 176a and 176b.

FIGS. 30B-C show cross-section views of the cell structure shown in FIG. 30A taken along line A-A′ and line B-B′, respectively.

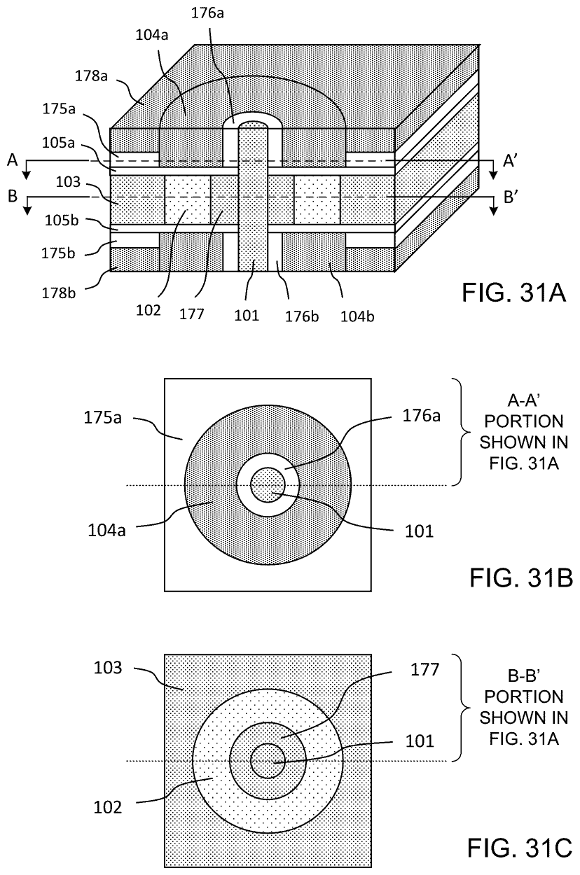

FIGS. 31A-C show embodiments of a cell structure according to the invention. These embodiments are similar to the embodiments shown in FIGS. 30A-C except that the gates 104a and 104b are formed in different shapes or patterns. In this embodiment, the gates 104a and 104b are formed as donut-shapes as shown. The gates 104a and 104b are connected to the word lines 178a and 178b formed of conductor material such as metal or polysilicon material. The gates 104a and 104b are isolated from the bit line 101 by the insulating layers 176a and 176b.

In one embodiment, the gates 104a and 104b are formed by using an isotropic etching process, such as wet etching, to selectively etch the insulating layers 175a and 175b and the word line layers 178a and 178b or the sacrificial layers before the word line layers 178a and 178b are formed. This forms recesses in the locations of the gates 104a and 104b. Next, the gates 104a and 104b are formed by using a deposition and etch-back process through the bit line hole. After that, the insulating layers 176a and 176b are deposited and then the bit line hole is filled with a conductor material to form the bit line 101.

FIGS. 31B-C show cross-section views of the cell structure shown in FIG. 31A taken along line A-A′ and line B-B′, respectively.

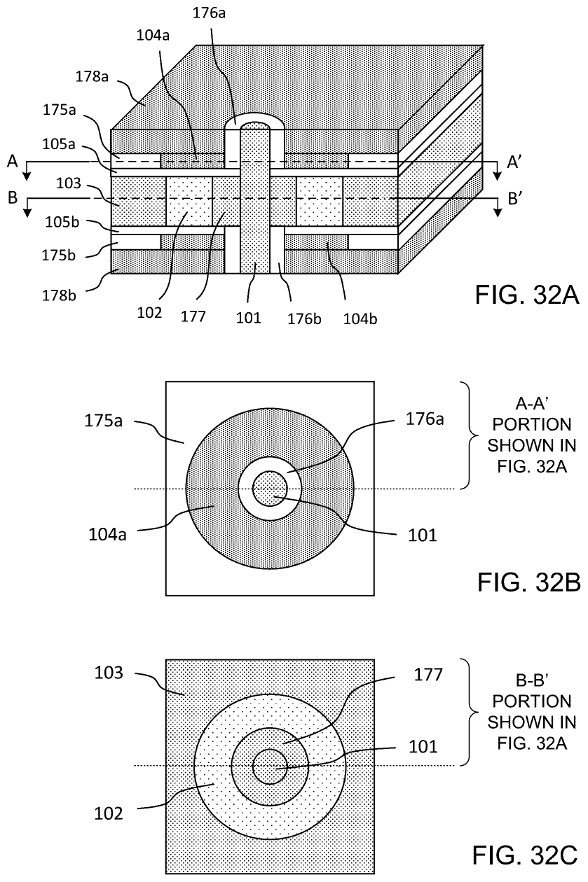

FIGS. 32A-C shows embodiments of a cell structure according to the invention. These embodiments are similar to the embodiments shown in FIGS. 31A-C except that the gates 104a and 104b are formed in different shapes. In these embodiments, the gates 104a and 104b are formed as donut-shapes as shown in FIG. 32B and connected to the word lines layers 178a and 178b located on top and bottom of the gates 104a and 104b, respectively. The gates 104a and 104b are isolated from the bit line 101 by the insulating layers 176a and 176b.

In one embodiment, the gates 104a and 104b are formed by using an isotropic etching process, such as wet etching, to selectively etch the insulating layers 175a and 175b to form recesses in the locations of the gates 104a and 104b. Next, the gates 104a and 104b are formed by using a deposition and etch-back process through the bit line hole. After that, the insulating layers 176a and 176b are deposited and then the bit line hole is filled with a conductor material to form the bit line 101.

FIGS. 32B-C show cross-section views of the cell structure shown in FIG. 32A taken along line A-A′ and line B-B′, respectively.

It should be noted that the insulating layers 175a, 175b, 176a, and 176b of the embodiments shown in FIG. 30A through FIG. 32C may be also applied to all the other embodiments of cell structures according to the invention.

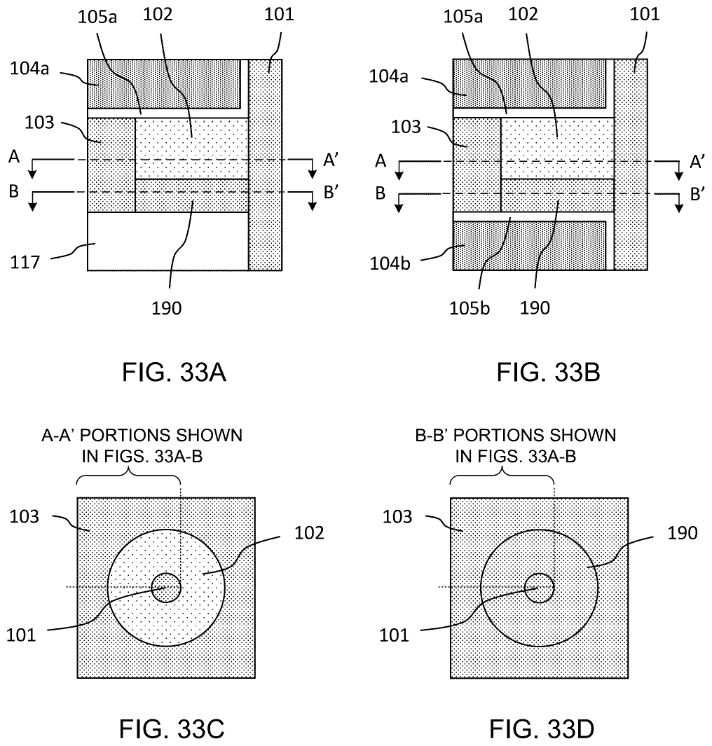

FIG. 33A shows an embodiment of a cell structure according to the invention. This embodiment is similar to the embodiment shown in FIG. 1C except that a semiconductor layer that forms a channel 190 is formed to connect the bit line 101 and the source line 103 as shown. The bit line 101, source line 103, channel 190, and floating body 102 are formed of semiconductor materials, such as silicon or polysilicon or any other suitable semiconductor materials. The channel 190 has the same type of doping as the bit line 101 and the source line 103. For example, in one embodiment, the bit line 101, source line 103, and the channel 190 have N+ type of doping, and the floating body 102 has P− type of doping. An insulating layer 117 is also provided that comprises material such as oxide or nitride material.

In one embodiment, the cell is written data ‘1’ by using impact ionization and data ‘0’ by using P-N forward bias current as the conditions described and shown in FIGS. 1A-B. The reader is referred to the description of FIGS. 1A-B for additional information. During hold operations, the gate 104a is supplied with a negative voltage to attract holes in the floating body 102. When the floating body 102 stores holes, the holes attract electrons in the channel 190 to ‘turn on’ the channel 190. Therefore, during read operations, when different voltages are applied to the bit line 101 and the source line 103, current flows through the channel 190. This condition represents data ‘1’. When the floating body 102 stores no holes, the channel 190 is depleted and thus no current flows through the channel 190. This condition represents data ‘0’.

In one embodiment, the channel 190 is formed by using the following process steps. First, the cell structure shown in FIG. 1C is formed. Second, the insulating layer 117 is removed by using an isotropic etching process such as wet etching. Third, an isotropic doping process, such as plasma doping or gas-phase doping, is applied through the space previously occupied by the insulating layer 117 with the opposite type of dopants from the floating body 102 to reverse the doping type to form the channel 190.

FIG. 33B shows an embodiment of a cell structure according to the invention. This embodiment is similar to the embodiment shown in FIG. 33A except that a back gate 104b formed of conductor material such as metal or polysilicon material and a gate dielectric layer 105b comprising material such as oxide or high-K material such as hafnium oxide HfO2 are formed as shown. The back gate 104b is coupled to the channel 190. During read operations, the back gate 104b is supplied with a read voltage to turn on or off the channel 190 according to whether the floating body 102 stores holes or not.

FIGS. 33C-D shows cross-section views of the cell structures shown in FIGS. 33A-B taken along line A-A′ and line B-B′, respectively. For example, FIG. 33C shows a cross-section view of FIGS. 33A-B taken along line A-A′, and FIG. 33D shows a cross-section view of FIGS. 33A-B taken along ling B-B′.

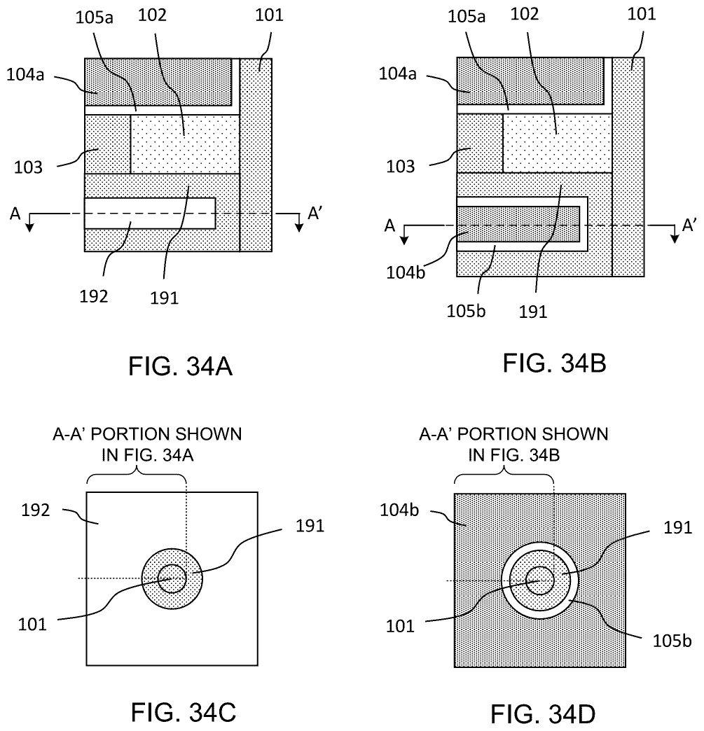

FIG. 34A shows an embodiment of a cell structure according to the invention.

This embodiment is similar to the embodiment shown in FIG. 33A except that the channel 191 is formed using different processes. In this embodiment, after the cell structure shown in FIG. 1C is formed, the insulating layer 117 are removed by using an isotropic etching process such as wet etching. After that, a semiconductor layer 191 comprising material such as silicon or polysilicon material is formed on the surface of the space previously occupied by the insulating layer 117. Then, an insulator 192 comprising material such as oxide or nitride material is deposited to fill the space.

FIG. 34B shows an embodiment of a cell structure according to the invention. This embodiment is similar to the embodiment shown in FIG. 34A except that the insulating layer 192 is replaced with a back gate 104b formed of conductor material, such as metal or heavily doped polysilicon material and a gate dielectric layer 105b comprising material such as oxide or high-K material such as hafnium oxide (HfO2). The back gate 104b is coupled to the channel 191. During read operations, the back gate 104b is supplied with a read voltage to turn on or off the channel 191 according to whether the floating body 102 stores holes or not.

FIG. 34C shows a cross-section view of the cell structure shown in FIG. 34A taken along line A-A′. FIG. 34D shows a cross-section view of the cell structure shown in FIG. 34B taken along line A-A′.

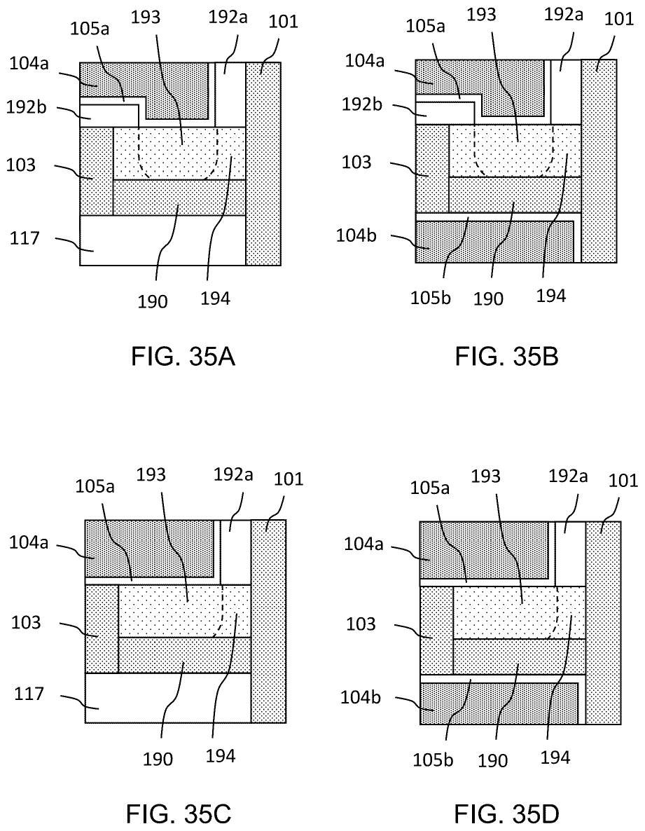

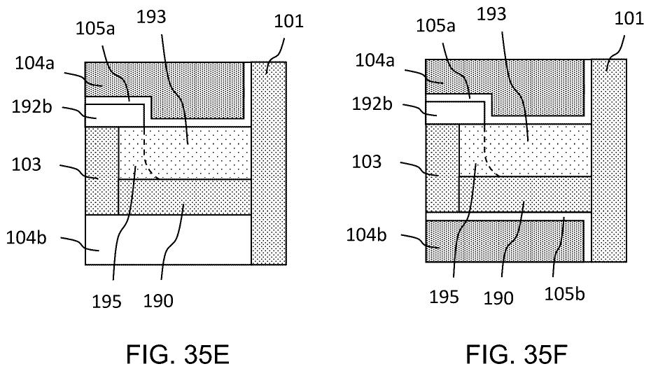

FIG. 35A shows an embodiment of a cell structure according to the invention. This embodiment is similar to the embodiment shown in FIG. 33A except that additional insulators 192a and 192b comprising material such as oxide or nitride material are formed to isolate the gate 104a from the bit line 101 and the source line 103.

When writing data ‘1’, the gate 104a is supplied with a positive voltage higher than the threshold voltage of the cell, such as 0.7V to 1V. The gate voltage induces a depletion in region 193. The bit line 101 is supplied with a positive voltage, such as 2V to 2.5V. The source line 103 is supplied with 0V. This condition turns on the channel under the gate 104a in saturation mode and causes impact ionization to occur in the drain junction of the bit line 101. This configuration generates electron-hole pairs and inject holes into the region 194 of the floating body. The holes stored in the region 194 decrease the threshold voltage of the channel 190 to increase the cell current during read operations. This condition represents data ‘1’.

When writing data ‘0’, the gate 104a is supplied with a positive voltage, such as 1V to 2V. The bit line 101 is supplied with a negative voltage, such as −1V. This causes P-N forward current to flow from the floating body to the bit line 101 to evacuate the holes stored in the region 194. This configuration increases the threshold voltage of the channel 190 to reduce the cell current during read operations. This condition represents data ‘0’.

FIG. 35B shows an embodiment of a cell structure according to the invention. This embodiment is similar to the embodiment shown in FIG. 35A except that the insulating layer 117 is replaced with a back gate 104b formed of conductor material such as metal or heavily doped polysilicon material and a gate dielectric layer 105b comprising material such as oxide or high-K material such as hafnium oxide (HfO2). The back gate 104b is coupled to the channel 190. During read operations, the back gate 104b is supplied with a read voltage to turn on or off the channel 190 according to whether the region 194 stores holes or not.

FIGS. 35C-D show embodiments of cell structures according to the invention. These embodiments are similar to the embodiments shown in FIGS. 35A-B, respectively, except that the insulating layer 192b is eliminated. Therefore, during write operations, the depletion region 193 reaches the source line 103. This condition may not affect the write operation because the impact ionization and the forward bias occur in the region 194. The reader is referred to the description of the embodiments shown in FIGS. 35A-B for detailed descriptions.

FIGS. 35E-F show embodiments of cell structures according to the invention. These embodiments are similar to the embodiments shown in FIGS. 35A-B, respectively, except that the insulating layer 192a is eliminated. The holes are stored in the area 195 under the insulator 192b. The operations of these embodiments are similar to the embodiments shown in FIGS. 35A-B except that the bias conditions for the bit line 101 and the source line 103 are swapped. When writing data ‘1’, the gate 104a is supplied with a positive voltage higher than the threshold voltage of the cell, such as 0.7V to 1V. The gate voltage induced a depletion in region 193. The source line 103 is supplied with a positive voltage, such as 2V to 2.5V. The bit line 101 is supplied with 0V. This condition turns on the channel under the gate 104a in saturation mode and causes impact ionization to occur in the source junction of the source line 103. This generates electron-hole pairs and injects holes into the region 195 of the floating body. The holes stored in the region 195 decrease the threshold voltage of the channel 190. This condition represents data ‘1’.

When writing data ‘0’, the gate 104a is supplied with a positive voltage, such as 1V to 2V. The source line 103 is supplied with a negative voltage, such as −1V. This configuration causes P-N forward current to flow from the floating body to the source line 103 to evacuate the holes stored in the region 195. This condition increases the threshold voltage of the channel 190 to represent data ‘0’.

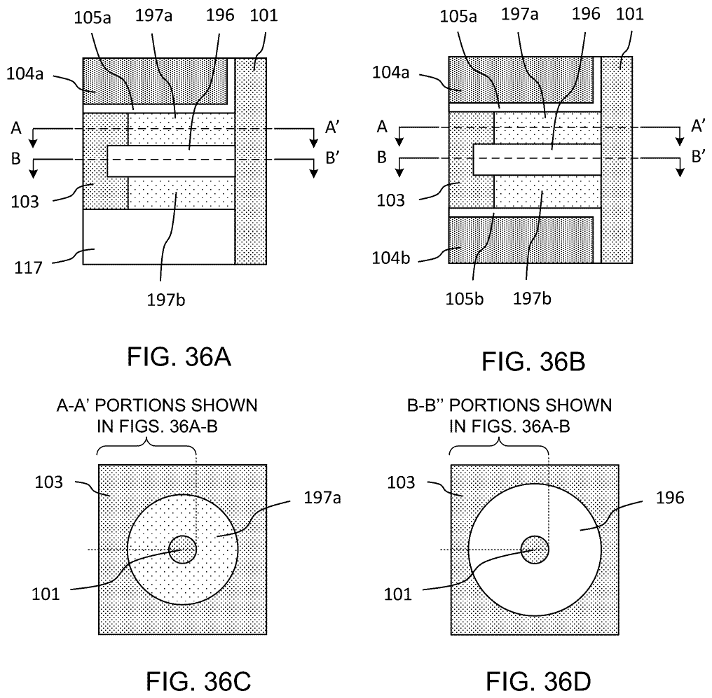

FIG. 36A shows an embodiment of a cell structure according to the invention. This embodiment is similar to the embodiment shown in FIG. 1C except that a thin insulating layer 196 is formed in the floating body to divide the floating body 102 into two portions 197a and 197b. The portion 197a is used to store holes to represent the data. The portion 197b is used as a channel for read operations.

When there are holes stored in the portion 197a, the holes attract electrons to the channel 197b and reduce the threshold voltage of the channel. Therefore, during read operations, when different voltages are applied to the bit line 101 and the source line 103, current flows through the channel 197b. This condition represents data ‘1’. When the portion 197a stores no holes, the channel 197b is depleted thus no current flows through the channel 197b. This condition represents data ‘0’.

FIG. 36B shows an embodiment of a cell structure according to the invention. This embodiment is similar to the embodiment shown in FIG. 36A except that the insulating layer 117 is replaced with a back gate 104b formed of conductor material such as metal or heavily doped polysilicon material and a gate dielectric layer 105b comprising material such as oxide or high-K material such as hafnium oxide (HfO2). The back gate 104b is coupled to the channel portion 102b. During read operations, the back gate 104b is supplied with a read voltage to turn on or off the channel 197b according to whether the portion 197a stores holes or not.

FIGS. 36C-D show cross-section views of the cell structures shown in FIGS. 35A-B taken along line A-A′ and line B-B′, respectively.

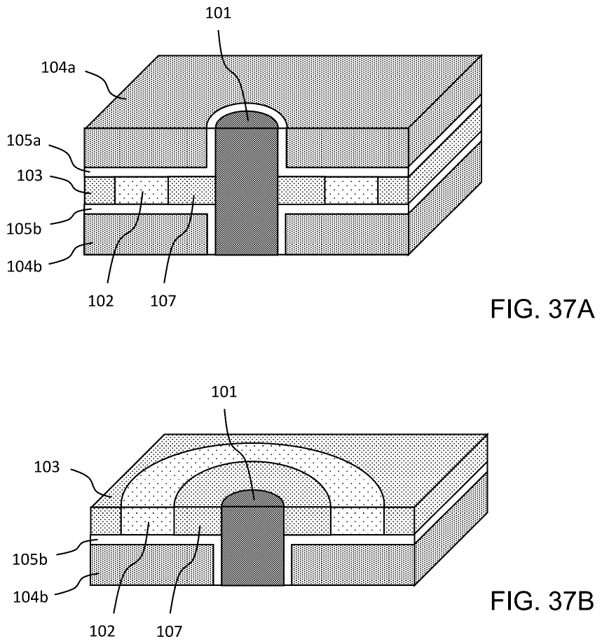

FIG. 37A shows an embodiment of a cell structure according to the invention. This embodiment is similar to the embodiment shown in FIG. 4A except that the semiconductor region 107 has a relatively lower doping concentration. For example, in one embodiment, the doping concentration for the semiconductor region 107 in FIG. 4A is 10²⁰/cm³ and for the region 107 in FIG. 37A the concentration is 10¹⁸/cm³. This configuration enables the semiconductor region 107 in FIG. 37A to be used as a channel of a ‘junction-less’ transistor. The cell structure becomes two serially connected transistors. One is the junction-less transistor using the semiconductor region 107 as a channel. The other one is the junction transistor using the floating body 102 as a channel.

In one embodiment, the semiconductor region 107 has the opposite type of doping from the floating body 102. For example, if the floating body 102 has P− or N− type of light doping, the semiconductor region 107 has N+ or P+ type of heavy doping, respectively. The semiconductor region 107 is formed of any suitable semiconductor materials as described with reference to FIG. 1A.

FIG. 37B shows the inner structure of the cell shown in FIG. 37A with the front gate 104a and gate dielectric layer 105a removed.

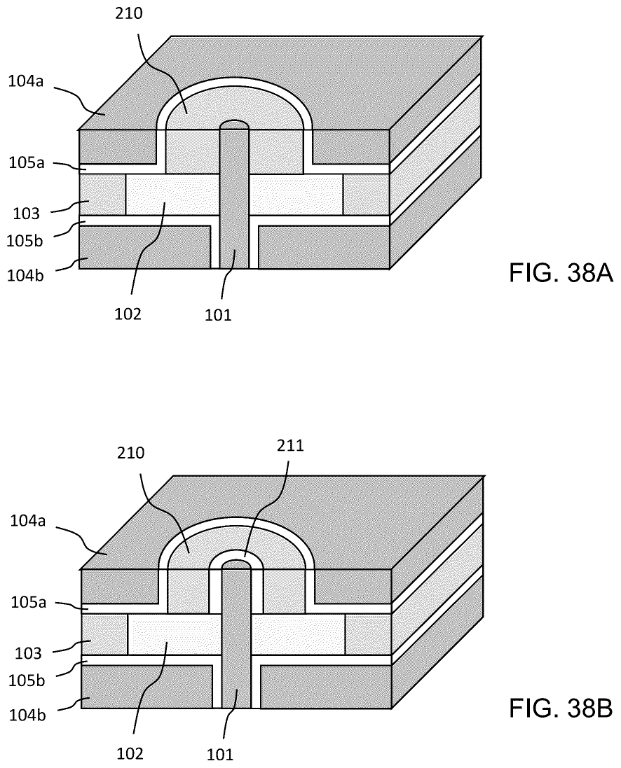

FIG. 38A shows an embodiment of a cell structure according to the invention. This embodiment is similar to the embodiment shown in FIG. 1A except that a semiconductor region 210 is formed as shown. The semiconductor region 210 is formed of silicon, polysilicon, silicon germanium (SiGe), indium gallium zinc oxide (IGZO), tungsten-doped indium oxide semiconductor, or any other suitable semiconductor materials.

In one embodiment, the semiconductor region 210 comprises material that is different from the floating body 102. For example, in one embodiment, the floating body 102 is formed of silicon or polysilicon material, and the semiconductor region 210 is formed of silicon germanium (SiGe) or silicon carbide (SiC) material. This configuration forms a heterostructure junction between the two materials and forms a quantum well inside the semiconductor region 210 for the storage of electric charges such as holes. This configuration increases the data retention time of the cell.

In this embodiment, the gate 104a is used for data storage. The gate 104a is supplied with a negative voltage during the hold conditions to attract the holes in the semiconductor region 210 to increase the data retention time. The gate 104b is used for reading operations. In another embodiment, the semiconductor region 210 is formed of the same material as the floating body 102. In this embodiment, the semiconductor region 210 has the opposite type of doping from the floating body 102. For example, if the floating body 102 has P− or N− type of doping, the semiconductor region 210 has N+ or P+ type of doping, respectively.

FIG. 38B shows an embodiment of a cell structure according to the invention. This embodiment is similar to the embodiment shown in FIG. 1A except that it has an additional insulating layer 211 comprising material such as oxide or nitride material between the semiconductor region 210 and the bit line 101. The insulating layer 211 prevents the semiconductor region 210 from direct contact with the bit line 101. This configuration reduces the chance of the holes escaping from the semiconductor region 210 to the bit line 101. Thus, this configuration increases the data retention time of the cell.

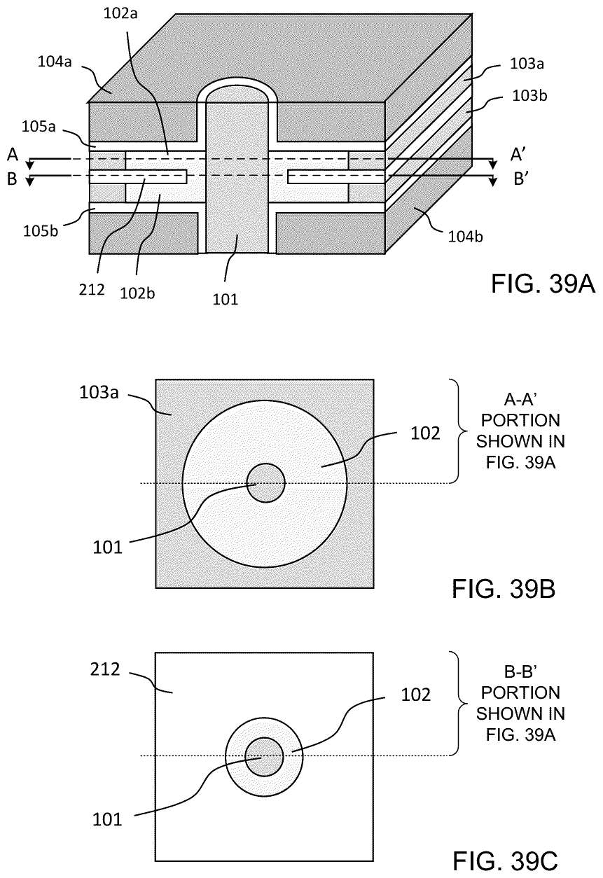

FIG. 39A shows an embodiment of a cell structure according to the invention. This embodiment is similar to the embodiment shown in FIG. 1A except that an insulating layer 212 comprising material such as oxide or nitride material is formed as shown. The insulating layer 212 divides the floating body into two portions 102a and 102b and the source line into two layers 103a and 103b. The floating body portions 102a and 102b are coupled to the front gate 104a and the back gate 104b through the gate dielectric layers 105a and 105b, respectively.

It will be assumed that the front gate 104a is used to perform read operations. The first floating body portion 102a is used as a channel. The front gate 104a is supplied with a read voltage to allow current flowing from the bit line 101 to the source line 103a through the first floating body portion 102a. The second floating body portion 102b is used as a storage region. The back gate 104b is supplied with a negative voltage to attract electric holes in the second floating body portion 102b. The insulating layer 212 prevents the recombination of the holes stored in the second floating body portion 102b with the electrons flowing through the channel of the first floating body portion 102a. This configuration increases the data retention time of the cell.

FIGS. 39B-C shows cross-section views of the cell structure shown in FIG. 39A taken along line A-A′ and line B-B′, respectively.

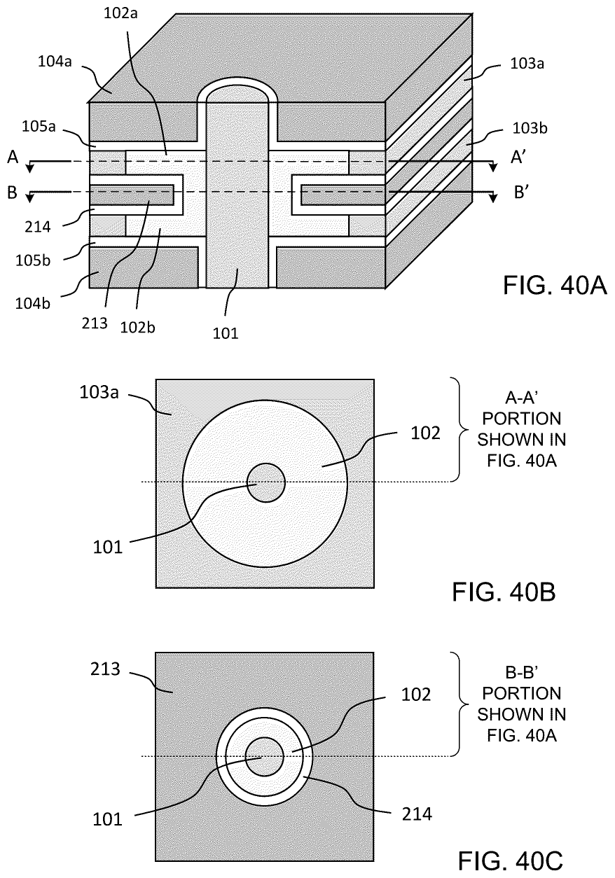

FIG. 40A shows an embodiment of a cell structure according to the invention. This embodiment is similar to the embodiment shown in FIG. 39A except that the insulating layer 212 is replaced with a back gate 213. The back gate 213 is formed of conductor material such as metal or polysilicon material. A gate dielectric layer 214 is provided that comprises material such as oxide or high-K material such as hafnium oxide (HfO2). The back gate 213 is supplied with a negative voltage to attract holes in the floating bodies 102a and 102b to increase the data retention time of the cell.

FIGS. 40B-C show cross-section views of the cell structure shown in FIG. 40A taken along line A-A′ and line B-B′, respectively.

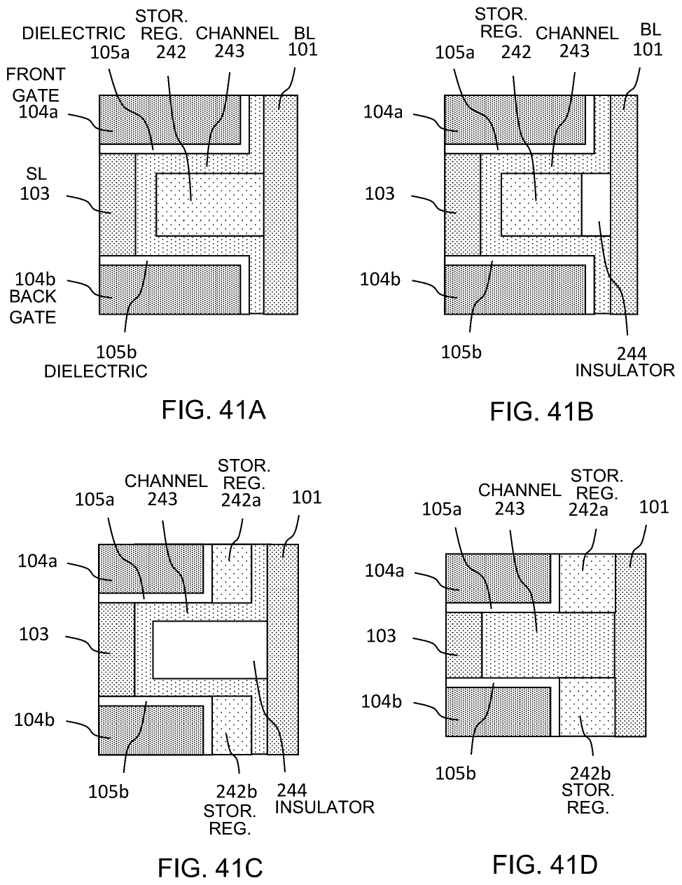

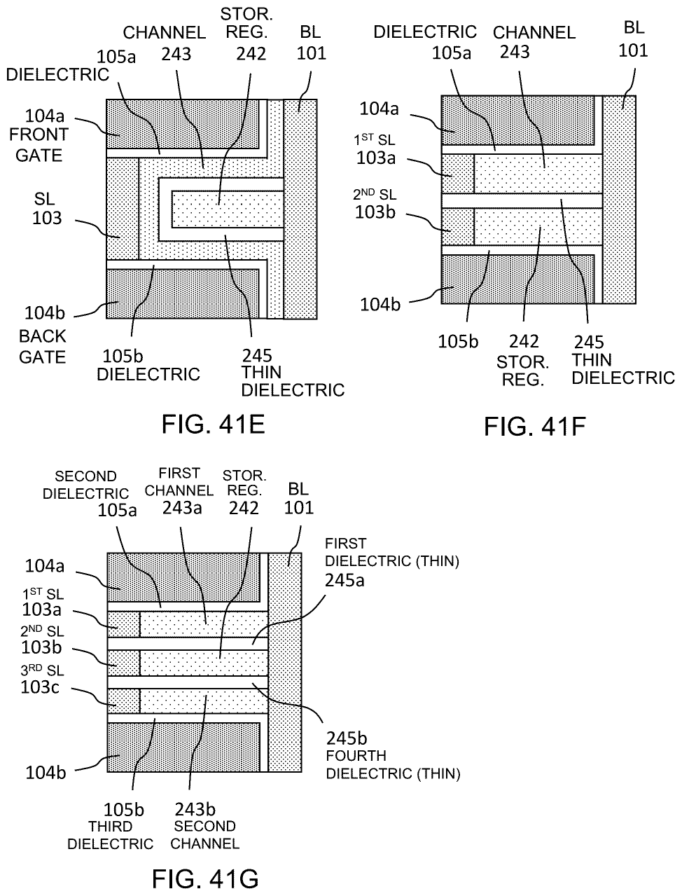

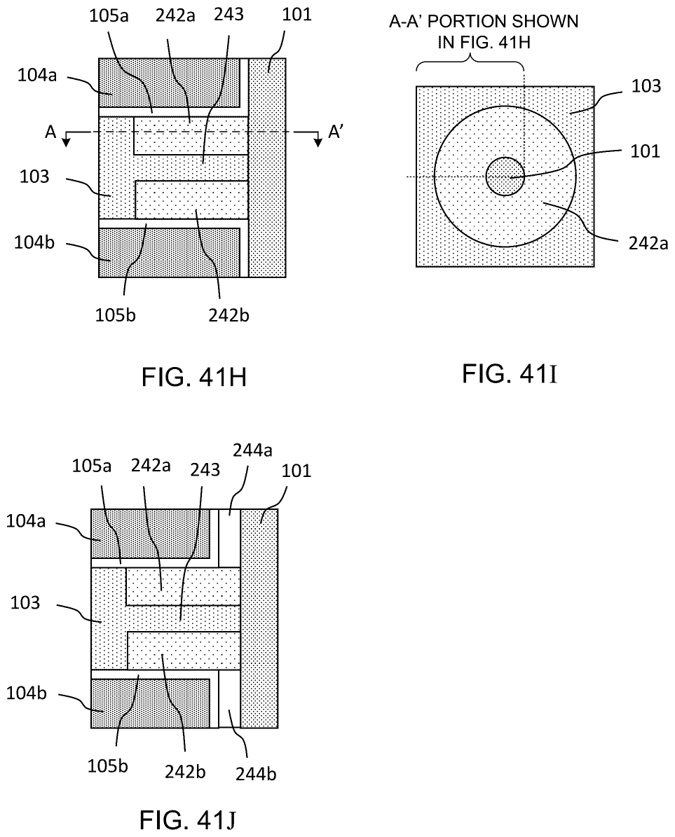

FIG. 41A shows an embodiment of a cell structure according to the invention. This embodiment is similar to the embodiment shown in FIG. 1A except that the floating body 102 is replaced with a channel region 243 and the storage region 242. The channel region 243 and the storage region 242 are formed of any suitable semiconductor materials as described in FIG. 1A. The channel region 243 has the opposite type of doping from the storage region 242. For example, if the storage region 242 has P type or N type of light doping, the channel region 243 has N type or P type of doping, respectively.

FIG. 41B shows an embodiment of a cell structure according to the invention. This embodiment is similar to the embodiment shown in FIG. 41A except that an additional insulator 244 comprising material such as oxide or nitride material is formed between the storage region 242 and the bit line 101 to isolate the storage region 242 from the bit line 101. This configuration reduces the leakage of the electric charge from the storage region 242 to the bit line 101 to increase the data retention time of the cell.

FIG. 41C shows an embodiment of a cell structure according to the invention. This embodiment is similar to the embodiment shown in FIG. 41A except that the storage regions 242a and 242b are located in different positions. In this embodiment, the storage regions 242a and 242b are located between the channel region 243 and the gates 104a and 104b. The electric charges stored in the storage regions 242a and 242b affects the current flowing through the channel region 243 adjacent to the storage regions 242a and 242b.

FIG. 41D shows an embodiment of a cell structure according to the invention. This embodiment is similar to the embodiment shown in FIG. 41C except that the insulator 244 is eliminated. This changes the cell structure from a thin-film transistor as shown in FIG. 41C to a junction transistor as shown in FIG. 41D. In this embodiment, the channel is formed of an inversion layer on the surface of the channel region 143 under the gates 104a and 104b and the storage regions 242a and 242b.

FIG. 41E shows an embodiment of a cell structure according to the invention. This embodiment is similar to the embodiment shown in FIG. 41A except that a thin dielectric layer 245 comprising material such as oxide or nitride material is formed between the channel region 243 and the storage region 242. In various embodiments, the thin dielectric layer 245 has a thickness in the range of 1 to 20 nanometers (nm). This thickness also applies to the thin dielectric layers 245a and 245b shown in FIG. 41G. The thin dielectric layer 245 enables electric charge stored in the storage region 242 to affect the current flowing through the channel region 243, while it reduces the leakage of the electric charge from the storage region 242 to the channel region 243. This configuration increases the data retention time of the cell. In this embodiment, due to the addition of the dielectric layer 245, the storage region 242 and the channel region 243 have either the same type of doping or the opposite types of doping.

FIG. 41F shows an embodiment of a cell structure according to the invention. This embodiment is similar to the embodiment shown in FIG. 1A except that a thin dielectric layer 245 comprising material such as oxide or nitride material is formed to divide the floating body into a channel region 243 and a storage region 242. The thin dielectric layer 245 enables electric charge stored in the storage region 242 to affect the current flowing through the channel region 243, while it reduces the leakage of the electric charge from the storage region 242 to the channel region 243. This configuration increases the data retention time of the cell. In this embodiment, the change region 243 and the storage region 242 are formed by using any suitable doping process through the vertical bit line hole before forming the bit line 101.

FIG. 41G shows an embodiment of a cell structure according to the invention. This embodiment is similar to the embodiment shown in FIG. 1A except that multiple thin dielectric layers 245a and 245b comprising material such as oxide or nitride material are formed to divide the floating body into channel regions 243a and 243b and a storage region 242. The thin dielectric layers 245a and 245b enable electric charge stored in the storage region 242 to affect the current flowing through the channel regions 243a and 243b, while they reduce the leakage of the electric charge from the storage region 242 to the channel regions 243a and 243b. This configuration increases the data retention time of the cell. In this embodiment, the change regions 243a 243b and the storage region 242 are formed by using any suitable doping process through the vertical bit line hole before forming the bit line 101.

FIG. 41H shows an embodiment of a cell structure according to the invention. In this embodiment, the storage regions 242a and 242b are located between the channel region 243 and the gate dielectric layers 105a and 105b. The storage regions 242a and 242b have the opposite type of dopants from the channel region 243. For example, if the channel region 243 has N type or P type of doping, the storage regions 242a and 242b have P type or N type of doping, respectively. The electric charge stored in the storage regions 242a and 242b affects the current flowing through the channel region 243.

FIG. 41I shows a cross-section view of the cell structure shown in FIG. 41H taken along line A-A′.

FIG. 41J shows an embodiment of a cell structure according to the invention. This embodiment is similar to the embodiment shown in FIG. 41H except that additional insulators 244a and 244b comprising material such as oxide or nitride material are formed between the bit line 101 and the gates 104a and 104b. The insulators 244a and 244b form physical barriers to reduce the leakage of electric charges from the storage regions 242a and 242b to the bit line 101. This configuration increases the data retention time of the cell.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A cell structure, comprising:
a first material forming a bit line;
a second material forming a storage region that is coupled to a first portion of the bit line;
a third material forming a channel that is connected to the storage region and to second and third portions of the bit line;
a fourth material forming a source line that is connected to the channel;
a fifth material forming a front gate coupled to a first portion of the channel and a first portion of the source line; and
a sixth material forming a back gate coupled to a second portion of the channel and a second portion of the source line.

2. The cell structure of claim 1, further comprising a first dielectric layer connected between the front gate and the first portion of the channel and the first portion of the source line.

3. The cell structure of claim 2, further comprising a second dielectric layer connected between the back gate and the second portion of the channel and the second portion of the source line.

4. The cell structure of claim 1, wherein the second material and the third material have opposite doping types.

5. The cell structure of claim 4, wherein the second material has a P− doping type and the third material has an N+ doping type.

6. The cell structure of claim 1, further comprising insulator material connected between the storage region and the first portion of the bit line.

7. The cell structure of claim 1, further comprising a dielectric layer connected between the storage region and the channel.

8. A cell structure, comprising:
a first material forming a bit line;
an insulator connected to a first portion of the bit line;
a second material forming a channel that is connected to the insulator and to second and third portions of the bit line;
a third material forming a first storage region that is coupled to a first portion of the channel;
a fourth material forming a second storage region that is coupled to a second portion of the channel;
a fifth material forming a source line that is connected to the channel;
a sixth material forming a front gate coupled to the channel and a first portion of the source line; and
a seventh material forming a back gate coupled to the channel and a second portion of the source line.

9. The cell structure of claim 8, wherein the channel and the first and second storage regions comprise semiconductor materials.

10. The cell structure of claim 9, wherein the channel has opposite doping type from the first and second storage regions.

11. A cell structure, comprising:
a first material forming a bit line;
a second material forming a channel that is connected to a first portion of the bit line;
a third material forming a first storage region that is coupled to a first portion of the channel and a second portion of the bit line;
a fourth material forming a second storage region that is coupled to a second portion of the channel and a third portion of the bit line;
a fifth material forming a source line that is connected to the channel;
a sixth material forming a front gate coupled to the channel and a first portion of the source line; and
a seventh material forming a back gate coupled to the channel and a second portion of the source line.

12. The cell structure of claim 11, wherein the channel and the first and second storage regions comprise semiconductor materials.

13. The cell structure of claim 12, wherein the channel has opposite doping type from the first and second storage regions.

14. A cell structure, comprising:
a first material forming a bit line;
a first dielectric layer connected to a first portion of the bit line;
a second material forming a storage region that is connected to a first portion of the first dielectric layer and a second portion of the bit line;
a third material forming a channel that is connected to a second portion of the first dielectric layer and a third portion of the bit line;
a fourth material forming a first source line that is connected to the channel;
a fifth material forming a second source line that is connected to the storage region;
a sixth material forming a front gate coupled to the channel and the first source line; and
a seventh material forming a back gate coupled to the storage region and the second source line.

15. The memory cell structure of claim 14, further comprising a second dielectric layer connected between the front gate and the channel and the first source line.

16. The memory cell structure of claim 14, further comprising a third dielectric layer connected between the back gate and the storage region and the second source line.

17. The memory cell structure of claim 14, wherein the second material and the third material have opposite or identical doping types.

18. The memory cell structure of claim 14, further comprising a fourth dielectric layer, a second channel and a third source line coupled between the third dielectric layer and the storage region, the second source line, and the third dielectric layer, wherein the fourth dielectric layer is coupled to the bit line, the second channel is connected to the bit line and between the third and fourth dielectric layers, and the third source line is connected to the second channel.
